(19) United States
(12) Patent Application Publication
(10) Pub. No.: US 2011/0287316 A1
(43) Pub. Date: Nov. 24, 2011

(54) HIGH PERFORMANCE CARBON NANO-TUBE COMPOSITES FOR ELECTROCHEMICAL ENERGY STORAGE DEVICES

(75) Inventors: Wen Lu, Littleton, CO (US); Joshua Buettner-Garrett, Fort Collins, CO (US); Michael Krysiak, Conifer, CO (US)

(73) Assignee: ADA TECHNOLOGIES, INC., Littleton, CO (US)

(21) Appl. No.: 13/113,971

(22) Filed: May 23, 2011

Related U.S. Application Data
(60) Provisional application No. 61/347,195, filed on May 21, 2010.
(60) Provisional application No. 61/355,738, filed on Jun. 17, 2010.

(51) Int. Cl. H01M 4/62; H01B 1/24; H01M 4/505; H01M 4/525; H01M 4/583; H01M 4/131; B05D 5/12; B05D 3/02; B05D 3/06; H01L 39/24; H01L 39/12; H01B 5/00; H01G 9/00; H01G 9/155; H01G 9/035; B82Y 99/00

(52) U.S. Cl. 429/215; 252/62.2; 252/511; 252/506; 252/507; 252/508; 252/509; 429/232; 429/219; 429/220; 429/221; 429/222; 429/223; 429/224; 429/225; 429/229; 429/231.1; 429/231.5; 429/231.6; 429/217; 427/532; 427/122; 505/470; 505/233; 174/126.1; 361/500; 361/502; 977/753; 977/742

(57) ABSTRACT

The invention relates generally to carbon nano-tube composites and particularly to carbon nano-tube compositions for electrochemical energy storage devices and a method for making the same.

### CROSS REFERENCE TO RELATED APPLICATIONS

The present application claims the benefits of U.S. Provisional Application Ser. Nos. 61/347,195 “Nanostructured High Voltage Materials for Advanced Lithium-Ion Batteries” filed May 21, 2010 and 61/355,738 entitled “High Energy, High Density Lithium-Polymer Batteries for MAVs” filed Jun. 17, 2010, each of which are incorporated herein by this reference in their entirety.

### STATEMENT REGARDING FEDERALLY SPONSORED RESEARCH AND DEVELOPMENT

The U.S. Government has a paid-up license in this invention and the right in limited circumstances to require the patent owner to license others on reasonable terms as provided for by the terms of Contract Nos. FA9453-10-M-0114 and FA8615-10-M-0223 awarded by the United States Air Force.

### FIELD OF INVENTION

This invention relates generally to carbon nano-tube composites and particularly to carbon nano-tube compositions for electrochemical energy storage devices and to a method for making the same.

### BACKGROUND OF THE INVENTION

New electrode materials with increased performance, safe operation, and long storage and cycle life are needed for electrical devices. For example, new electrode materials are needed in the area of advanced transportation devices (such as, electric vehicles, hybrid electric vehicles, and plug-in vehicles) and consumer electronics (such as, notebook computes, cellular telephones, pagers, video cameras, tablet computers, and other hand-held tools and devices to name a few). Furthermore, new electrode materials are needed for medical electronics (such as, portable defibrillators, drug delivery units, and neurological stimulators to name a few) and in mobile power applications (such as unmanned aerial vehicles, spacecraft probes and missile systems to name a few).

### SUMMARY OF THE INVENTION

These and other needs are addressed by the various embodiments and configurations of the present invention. This disclosure relates generally relates to new composite compositions for energy storage devices.

These and other advantages will be apparent from the disclosure of the invention(s) contained herein.

Some embodiments include a composition having a polymeric material containing a plurality of active material particles and a plurality of graphene material particles. The plurality of graphene material particles form a graphene network that one or both interconnects and coats at least some, if not most, of the plurality of active material particles. The graphene material particles forming the graphene network have been un-tangled and/or un-aggregated by one or both of a first ionic liquid or ultrasonic energy.

Some embodiments include a method for making the composition by providing an active material, contacting the active material with a polymer binder and graphene material to form a slurry having at least some of the graphene material is in an aggregated and/or tangled form and contacting the slurry with at least one of an ionic liquid and ultrasonic energy to form a substantially homogeneous suspension of graphene and active materials. The contacting of the slurry with the at least one of an ionic liquid and ultrasonic energy un-aggregates and/or untangles at some of the aggregated or tangeled graphene material. When the slurry is contacted with the ionic liquid, but not with ultrasonic energy, the slurry can be mechanically mixed. In some embodiments, the method can further include contacting the homogenous suspension with a substrate to form a film on the substrate. One or both of thermal and electromagnetic energy can be applied to the film to from the composite film on the substrate. Applying the one or both of thermal and electromagnetic energy removes any solvent and/or carrier fluid contained in the film. Moreover, the thermal and/or electromagnetic energy may substantially cross-link and/or gel the polymeric binder. The electromagnetic energy is one of infrared energy, ultra-violet energy, electron beam energy, and x-ray energy. When thermal energy is applied to the film, the film temperature ranges from about 10 to about 200 degrees Celsius. The substrate can be a glass material, a metal alloy, a polymeric material, an electrically conductive material, a superconductive material, copper, a copper alloy, aluminum, an aluminum alloy, nickel, a nickel alloy, stainless steel, graphite, a superconductive ceramic, or combination thereof.

Some embodiments include an apparatus having a composite having a polymer binder containing a plurality of graphene particles in physical contact with a plurality of active material particles, the plurality of graphene particles forms a conductive network that one or both interconnects and coats at least some, if not most, of the plurality of active material particles. The composite is positioned on at least one surface of an electrically conductive material. One or both of an ionic liquid or ultrasonic energy untangled and/or un-aggregated at least some of the graphene material particles forming the graphene network.

Preferably, the active material substantially reversibly intercalates one of lithium, sodium or potassium. More preferably, the active material comprises one or more of an ordered olivine composition, a rhombohedral super-ionic conductor, an oxide, a nitride, a phosphide, a hydride, a spinel, and a substituted spinel.

Non-limiting examples of active material include MPO₄, YMPO₄, MPO₄F_{q}, YMPO₄F_{q}, M₂(XO₄)r, YM₂(XO₄)ᵣ, M₂(XO₄)ᵣF_{q}, YM₂(XO₄)ᵣF_{q}, MO_{z}, YMO_{z}, MO_{z}F_{q}, YMO_{z}F_{q}, MNⱼ, YMNⱼ, MPⱼ, YMPⱼ, MHₜ, YMHₜ and combinations thereof and where 0<q<6, where 0<r≦3, where 0<z≦12, where 0<j≦4, where 1<t≦6, where Y is selected from the group consisting of Li, Na, K, Rb, Cs, Be, Mg, Ca, Sr, Ba, Ra, Fr and combinations thereof, and where M is selected from the group consisting of Sc, Ti, B, Cr, Mn, Fe, Co, Ni, Cu, Zn, Y, Sr, Nb, Mo, Tc, Ru, Rh, Pd, Ag, Cd, La, Ce, Pr, Nd, Sm, Eu, Gd, Tb, Dy, Ho, Er, Tm, Yb, Lu, Hf, Ta, W, Re, Os, Ir, Pt, Au, Hg, B, Al, Ga, In, Tl, Si, Ge, Sn, Pb, and combinations thereof, and where X is selected from the group consisting of B, Al, Ga, In, Tl, Si, Ge, Sn, Pb and combinations thereof. Preferably, the active includes one of LiFePO₄, LiMnPO₄, LiCoPO₄, LiNiPO₄, LiCoO₂, LiNi_{0.5}Mn_{1.5}O₄, V₂O₅, LiCo_{1/3}Ni_{1/3}O₂, Li(Li₀₋₁Ni₀₋₁Mn₀₋₁Co₀₋₁)O₂, LiMn₂O₄, MnO₂, LiNiO₂, LiMn₂₋ᵣNiᵣO₄, LiMn₂₋ᵣFeᵣO₄, and combinations thereof.

The ionic liquid may be any ionic liquid. Preferably, the ionic liquid is one of EDMMEA, EMIIM or mixture thereof.

The polymer binder may be homopolymer or co-polymer. Preferred polymer binders include polyolefins, polystyrenes, polyvinyls, polyacrylics, polyhalo-olefins, polydienes, polyoxides/esthers/acetals, polysulfides, polyesters/thioesters, polyamides/thioamides, polyurethanes/thiourethanes, polyureas/thioureas, polyimides/thioimides, polyanhydrides/thianhydrides, polycarbonates/thiocarbonates, polyimines, polysiloxanes/silanes, polyphosphazenes, polyketones/thioketones, polysulfones/sulfoxides/sulfonates/sulfoamides, polyphylenes, and mixtures thereof. Poly vinylidene fluoride-co-hexafluoropropylene is a non-limiting example of a more preferred polymer binder.

In some embodiments, the graphene material particles comprise carbon nano-tubes. Examples of carbon nano-tubes are single walled carbon nano-tubes, multi-walled carbon nano-tubes and a mixture of single- and multi-walled carbon nano-tubes.

In some embodiments, the composition has one or both of a charge and discharge capacity retention at least about equal or greater than a similar composition prepared without either one or both of the ionic liquid and sonication.

In some embodiments, the composition has one or both of a specific energy and power on cycling at least about equal or greater than a similar composition prepared without either one or both of the ionic liquid and sonication.

In some embodiments, the composition prepared with one or both of the ionic liquid or sonication has more of the graphene network in contact with more of a circumferential value of the active material particle than a similar composition prepared without either one of the ionic liquid or sonication.

In some embodiments, the graphene network comprises one or more aggregates of graphene particles on the surface of the active material particle. Each graphene particle has a graphene particle thickness and each graphene aggregate on the surface of the active material particle has a surface contact length. Preferably, the surface contact length is about equal to or greater than the graphene particle thickness.

As used herein, the term “a” or an entity refers to one or more of that entity. As such, the terms “a” (or “an”), “one or more” and “at least one” can be used interchangeably herein. It is also to be noted that the terms “comprising”, “including”, and “having” can be used interchangeably.

As used herein, “at least one”, “one or more”, and “and/or” are open-ended expressions that are both conjunctive and disjunctive in operation. For example, each of the expressions “at least one of A, B and C”, “at least one of A, B, or C”, “one or more of A, B, and C”, “one or more of A, B, or C” and “A, B, and/or C” means A alone, B alone, C alone, A and B together, A and C together, B and C together, or A, B and C together.

The preceding is a simplified summary of the invention to provide an understanding of some aspects of the invention. This summary is neither an extensive nor exhaustive overview of the invention and its various embodiments. It is intended neither to identify key or critical elements of the invention nor to delineate the scope of the invention but to present selected concepts of the invention in a simplified form as an introduction to the more detailed description presented below. As will be appreciated, some embodiments of the invention are possible utilizing, alone or in combination, one or more of the features set forth above or described in detail below.

### BRIEF DESCRIPTION OF THE DRAWINGS

The accompanying drawings are incorporated into and form a part of the specification to illustrate several examples of the present invention(s). These drawings, together with the description, explain the principles of the invention(s). The drawings simply illustrate preferred and alternative examples of how the invention(s) can be made and used and are not to be construed as limiting the invention(s) to only the illustrated and described examples.

Further features and advantages will become apparent from the following, more detailed, description of the various embodiments of the invention(s), as illustrated by the drawings referenced below.

FIG. 1 depicts a SEM image of a composite according to an embodiment;

FIGS. 2A-2E depict graphene materials according to some embodiments;

FIGS. 3A-3B depict cross-sections of multi-walled carbon nano-tubes according to some embodiments;

FIG. 4 shows examples of ionic liquids based on various monocations;

FIG. 5 shows examples of ionic liquids based on various polycations;

FIG. 6 shows examples of polymer binders;

FIGS. 7A-7G show examples of composites according to some embodiments;

FIG. 8 depicts a SEM image of a LNMO/CB/PV dF (80/15/5) electrode prepared by mechanical stirring procedure and devoid of an ionic liquid;

FIG. 9 is a flowchart for a method for making a composite according to some embodiments;

FIG. 10 depicts a battery according to an embodiment;

FIG. 11 depicts examples of active materials;

FIG. 12 depicts cyclic voltammograms for a of 80 wt % lithium nickel manganese oxide, 15 wt % carbon black, 5wt % PVdF baseline electrode obtained at 0.1 mV/s (vs. Li/Li⁺) in a conventional nonaqueous electrolyte of 0.5 M LiPF₆/ethylene carbonate-dimethyl carbonate (1:1 by wt.);

FIG. 13 depicts the charge/discharge profiles obtained for the same electrode system of FIG. 10, with a cut-off voltage: 3.0/5.0V, the left charge/discharge profile was: charged at 0.25 C and discharged at 0.25 C, 0.5 C, 1 C, 2 C, and 4 C, respectively, and the right charge/discharge was charged and discharged at 0.25 C, 1 C, 2 C, and 4 C, respectively;

FIGS. 14A-14D depict cyclic voltammograms for a of 80 wt % lithium nickel manganese oxide, 15 wt % carbon black, 5wt % PVdF baseline electrode obtained at 0.1 mV/s (vs. Li/Li⁺) in a 0.5 M LiPF₆/[EDMMEA][Tf₂N] electrolyte containing ethylene carbonate at different concentrations (wt. %) of (a): 20%, (b): 40%, (c): 50%, (d): 57.2%;

FIGS. 15A-15D depict cyclic voltammograms of different electrodes obtained at 0.1 mV/s (vs. Li/Li⁺) in an electrolyte having 0.5 M LiPF₆/[EDMMEA][Tf₂N] with 50 wt % ethylene carbonate electrolyte, the electrodes comprising (a) 80 wt % lithium nickel manganese oxide, 15 wt % carbon back and 5 wt % PVdF, prepared by mechanical stirring procedure, (b) 80 wt % lithium nickel manganese oxide, 15 wt % carbon nano-tubes, and 5 wt % PVdF prepared by mechanical stirring procedure, (c) 80 wt % lithium nickel manganese oxide, 15 wt % carbon nano-tubes, and 5 wt % PVdF prepared by sonication procedure, and (d) 71.6 wt % lithium nickel manganese oxide, 13.4 wt % carbon nano-tubes, 5 wt % PVdF, and 10 wt % ionic liquid prepared by sonication procedure;

FIGS. 16A-16D depict asymmetric charge/discharge profiles obtained for different electrodes in an electrolyte having 0.5 M LiPF₆/[EDMMEA][TF₂N] with 50 wt % ethylene carbonate, with a cut-off voltage of 3.0/5.0V, charged to 0.25 C, and discharged at 0.25 C, 0.5 C, 1 C, 2 C, and 4 C, respectively, for electrodes comprising (a) 80 wt % lithium nickel manganese oxide, 15 wt % carbon back and 5 wt % PVdF, prepared by mechanical stirring procedure, (b) 80 wt % lithium nickel manganese oxide, 15 wt % carbon nano-tubes, and 5 wt % PVdF prepared by mechanical stirring procedure, (c) 80 wt % lithium nickel manganese oxide, 15 wt % carbon nano-tubes, and 5 wt % PVdF prepared by sonication procedure, and (d) 71.6 wt % lithium nickel manganese oxide, 13.4 wt % carbon nano-tubes, 5 wt % PVdF, and 10 wt % ionic liquid prepared by sonication procedure;

FIGS. 17A-17D depicts symmetric charge/discharge profiles obtained for different electrodes in an electrolyte having 0.5 M LiPF₆/[Tf₂N] with 50 wt % ethylene carbonate, with a cut-off voltage: 3.0/5.0, charged and discharged at 0.25 C, 1 C, 2 C, and 4 C, respectively, for electrodes comprising (a) 80 wt % lithium nickel manganese oxide, 15 wt % carbon back and 5 wt % PVdF, prepared by mechanical stirring procedure, (b) 80 wt % lithium nickel manganese oxide, 15 wt % carbon nano-tubes, and 5 wt % PVdF prepared by mechanical stirring procedure, (c) 80 wt % lithium nickel manganese oxide, 15 wt % carbon nano-tubes, and 5 wt % PVdF prepared by sonication procedure, and (d) 71.6 wt % lithium nickel manganese oxide, 13.4 wt % carbon nano-tubes, 5 wt % PVdF, and 10 wt % ionic liquid prepared by sonication procedure;

FIG. 18 depicts discharge capacity retentions for a lithium nickel manganese oxide carbon nano-tube electrode (1602) and lithium nickel manganese oxide carbon black electrode (1601);

FIG. 19 depicts charge and discharge capacities for a lithium nickel manganese oxide carbon nano-tube electrode during charge and discharge cycling at 1 C between 3 V and 5 V in an electrolyte having 1 M LiPF₆ in EDMMEA ionic liquid with 50 wt % ethylene carbonate;

FIG. 20 depicts cyclic voltammograms collected at a scan rate of 1 mV/s for various electrolytes obtained at an aluminum foil electrode (1 cm²) versus a lithium foil electrode (1.23 cm²), the electrolytes are, respectively, (a) 1M LiPF₆ in EDMMEA ionic liquid having 50 wt % ethylene carbonate, (b) EDMMEA ionic liquid, (c) 1 M LiTFSI in EDMMEA ionic liquid, and (d) 1 M LiTFSI in EDMMEA ionic liquid having 20 wt % ethylene carbonateEC in EDMMEA;

FIG. 21 depicts active material-levels of specific energy and specific power versus cycle number for a half-cell undergoing 100% depth of discharge;

FIG. 22 depicts a cyclic voltammogram of CR3032 coin cell haging a V₂O₅ composite cathode and lithium anode with an ionic liquid gel polymer electrolyte;

FIG. 23 depicts a rate capability comprising of a graphite/carbon black/PVdF anode and a graphite/carbon nano-tube/PVdF anode; and

FIG. 24 depicts discharge capacity retention for a graphite/carbon nano-tube/PVdF electrode.

### DETAILED DESCRIPTION OF THE INVENTION

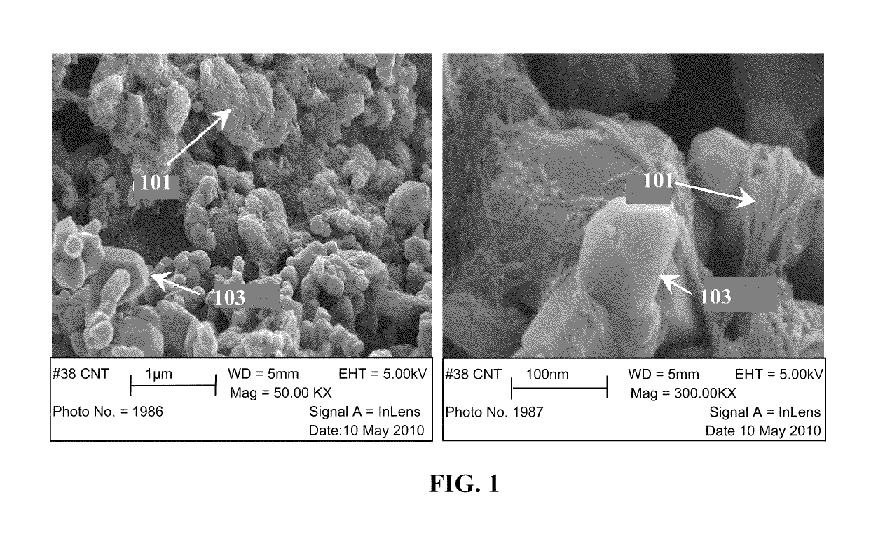

Some embodiments include a composite composition. The composite can comprise a graphene material, an active material, an ionic liquid and a polymer binder. Preferably, the graphene and active materials have an average particle size less than about 1,000 nm. More preferably, the average particle size of one or both of graphene and active materials is less than about 500 nm. Furthermore, the graphene and active materials are typically substantially homogeneously distributed in the polymer binder. Moreover, at least some, if not most, of the graphene and active materials are in physical contact with one another. The ionic liquid and graphene forms an electrically conductive network interconnecting the active material contained within the polymeric binder. The graphene material substantially forms a graphene material network covering and/or blanketing the active material. Furthermore, the graphene material network covering and/or blanketing the active material has about a substantially uniform thickness (FIG. 1). FIG. 1 is a micrograph of the composite according to some embodiments, the micrograph shows the graphene material 101 forms a graphene material network covering and/or blanketing active material 103. The micrograph further shows that the garphene material network has a substantially uniform thickness and substantially uniformly blankets and/or covers the active material 103.

Some embodiments include a method for making the composite. The method can comprise contacting an active material with a graphene material and a polymer binder to form a graphene/active material slurry. Preferably, the polymer binder may be dissolved and/or dispersed in a suitable solvent and/or carrier fluid. Furthermore, the polymer binder may include a cross-linking entity. The graphene and active materials can be substantially homogeneously dispersed in the polymer binder by contacting the graphene and active materials with one or both of an ionic liquid and ultrasound energy. The substantially homogeneously dispersed grapheme/active material slurry can be coated on a substrate to form a slurry film on the substrate. Energy can be applied to the slurry film to form a composite film on the current collector. The energy can be in the form of thermal energy, to remove the solvent and/or carrier solution or to chemically cross-link the polymer binder, or the energy can be another energy form, such as electromagnetic energy, x-ray, electron-bean, or ultra-violet to cross-link the polymer binder. The substrate can be current collector comprising, without limitation, any highly electrically conductive and/or superconductive material. Suitable examples of the current collector include, without limitation, conductive metals (e.g. copper, aluminum, nickel, and stainless steel), graphite, superconductive ceramics, and the like. Preferably, the composite film comprises a conductive film on the current collector.

Some embodiments include an electrochemical device. The electrochemical device may be an electrode, or one or both electrodes of a capacitor, such as an ultra-capacitor, or a battery, such as a lithium-ion battery. The electrode(s) includes a composite comprising a graphene material, an active material, and a polymer binder. At least some of the graphene material is untangled and/or un-aggregaed by contacting with one or both of an ionic liquid and ultrasonic energy. The graphene and active materials are substantially homogeneously distributed in the polymer binder. The graphene material forms an electrically conductive network physically and/or electrically interconnecting the active material in the polymeric binder. The electrochemical device typically comprises first and second electrodes having an electrolyte positioned between the first and second electrodes. The electrolyte is in electrical contact with the composite film. Preferably, the electrochemical device comprises an electrochemical battery or a capacitor. More preferably, the electrochemical device comprises a lithium-ion battery or an ultra-capacitor.

### Graphene Material

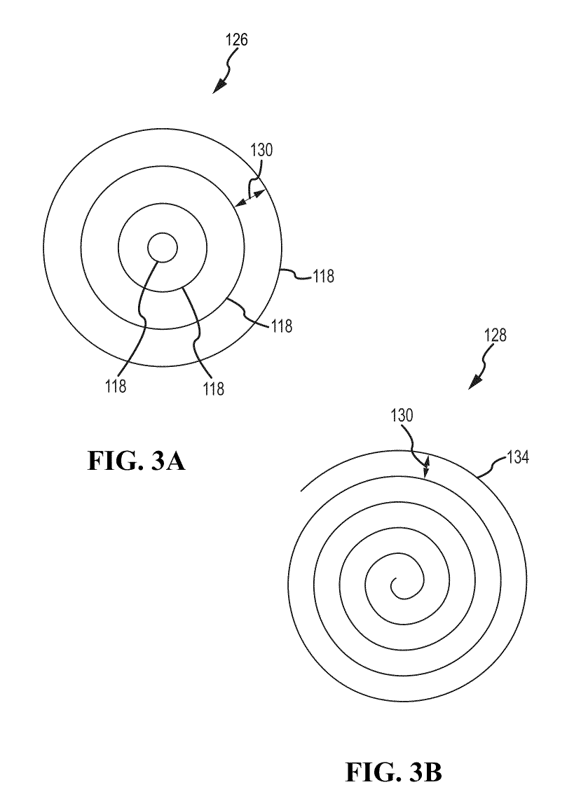

The graphene material 101 can comprise a graphene nano-ribbon, a carbon nano-tube or mixture thereof. Graphene materials are generally preferred due to one or more of their high electrical conductivity, high charge transport capability, high surface area, high meso-porosity, and high electrolyte accessibility. Graphene materials according some embodiments are depicted in FIGS. 3A-3D.

The graphene material 101 can comprise a planar-shaped graphene nano-ribbon 114 (FIG. 3A), a non-planar shaped graphene nano-ribbon 116 (FIG. 3B), a cylindrically-shaped graphene nano-ribbon, also known within the art and referred to herein as a carbon nano-tube 118 (FIG. 3C), and any geometrically shaped graphene nano-ribbon (such as, those known within the art as bucky balls or buskmisterfullerenes), which are not depicted.

The graphene material 101 can comprise a plurality of interconnected sp²-hybrized carbon atoms. The sp²-hybrized carbon atoms are typically interconnected to form one-of a graphene nano-ribbon or carbon nano-tube.

A carbon nano-tube 118 can be thought of as a graphene ribbon 134 rolled up into a tubular or cylindrical form. The carbon nano-tube 118 can be in the form of a single walled carbon nano-tube or multi-walled nano-tube.

Single walled carbon nano-tubes typically comprise a single graphene ribbon configured as a tube. The single walled carbon nano-tubes have extraordinary properties, including high electrical and thermal conductivity, as well as high strength and stiffness. Structurally, the single walled carbon nano-tube comprises a seamless hollow tube having a one-atom thick graphene wall 180 and a chiral vector 124 (FIG. 3E). In some embodiments, the single walled carbon nano-tube can have a graphene cap at one or both ends of the single walled carbon nano-tube. That is, the carbon nano-tube can have opened, closed, or a mixture of opened and closed ends. In some embodiments, the single walled carbon nano-tube can lack a graphene cap, that is one or both ends can be substantially opened. The carbon nano-tube ends (either opened or closed) can be substantially free of other chemical entities, such as carbon radical groups) or can have carbon radical groups attached thereto.

The chiral vector 124 comprises a pair of indices (n,m), which denote unit vectors along two directions of the lattice of the graphene ribbon. While not wanting to be bound by any theory, the chiral vector 124 affects the single walled carbon nano-tube electrical properties. Preferably, the single walled carbon nano-tubes have a chiral vector 124 where n=m or (n−m)/3 is an integer. FIG. 3D depicts single-wall carbon nano-tubes 118 having chiral vectors of (0,10), (7,10) and (10, 10), respectively, denoted in FIG. 3D as carbon nano-tubes 198, 200, and 202.

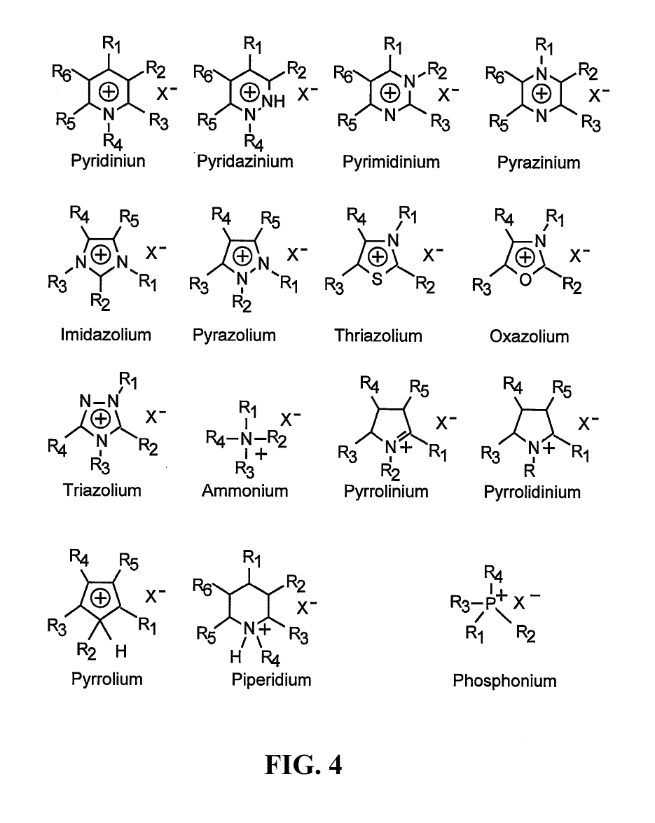

Multi-walled carbon nano-tubes typically comprise one or more graphene nano-ribbons 134 rolled up around a single walled carbon nano-tube core, the one or more graphene nano-ribbons 134 forming multiple graphene walls 180 (FIGS. 4A-4B). While not wanting to be bound by any theory, the multi-walled carbon nano-tube can comprise one of: a) a series of seamless single walled carbon nano-tubes arranged as concentric cylinders one inside of another (126) or b) a single graphene nano-ribbon 134 rolled spirally around itself (128). The annular space between the inner and outer carbon nano-tube walls, or difference between the outer carbon nano-tube diameter and inner carbon nano-tube diameter, preferably is larger than the molecular size(s) of the cations and anions comprising the ionic liquid electrolyte 110. The interlay distance 130 between graphene layers ranges from about 1 Å to about 10 Å, preferably from about 2 Å to about 4 Å.

Unless specified otherwise, the term “carbon nano-tube” as used herein can refer to a graphene ribbon, a single walled carbon nano-tube, a multi-walled carbon nano-tube, or a mixture thereof. Moreover, as used herein graphene material particles can refer to one or more of a plurality of graphene ribbons, a plurality of single-walled carbon nano-tubes, a polarity of multi-walled carbon nano-tubes, or a mixture thereof. Furthermore, the term “carbon nano-tube”, unless specified otherwise, can refer to carbon nano-tubes having open-ends, closed ends or carbon nano-tubes having a mixture open and closed ends.

In some embodiments, the carbon nano-tubes can comprise a mixture of single- and multi-walled carbon nano-tubes. In some configurations, the mixture of single- and multi-walled carbon nano-tubes, comprises from about 0 wt % single walled carbon nano-tubes, about 10 wt % single walled carbon nano-tubes, about 20 wt % single walled carbon nano-tubes, about 30 wt % single walled carbon nano-tubes, about 40 wt % single walled carbon nano-tubes, about 50 wt % single walled carbon nano-tubes, about 60 wt % single walled carbon nano-tubes, about 70 wt % single walled carbon nano-tubes, about 80 wt % single walled carbon nano-tubes, about 90 wt % single walled carbon nano-tubes, or about 100 wt % single walled carbon nano-tubes, to about about 100 wt % mulit-walled carbon nano-tubes, about 90 wt % mulit-walled carbon nano-tubes, about 80 wt % mulit-walled carbon nano-tubes, about 70 wt % mulit-walled carbon nano-tubes, to about 60 wt % mulit-walled carbon nano-tubes, about 50 wt % mulit-walled carbon nano-tubes, about 40 wt % mulit-walled carbon nano-tubes, about 30 wt % mulit-walled carbon nano-tubes, about 30 wt % mulit-walled carbon nano-tubes, about 20 wt % mulit-walled carbon nano-tubes, or 0 wt % mulit-walled carbon nano-tubes.

The carbon nano-tubes can be used as synthesized or after purification. For example, the carbon nano-tubes may be etched, such as, in an oxygen atmosphere to remove any residual metal catalyst used in the preparation of the carbon nano-tubes. Moreover, the carbon nano-tubes may be further processed to open at least some, or at least most, of any closed nano-tube ends.

The carbon nano-tubes can have one or more of high electrical conductivity, high surface area, high mesoporosity, and high electrolyte accessibility. As will be appreciated, the carbon nano-tube mesopores are accessible by electrolytes (especially organic electrolytes) and contribute to capacitance in an electrical double layer capacitor. The mesopores typically can be from about 1 nm to about 80 nm, more typically from about 1 nm to about 70 nm, even more typically from about 2 nm to about 60 nm and yet even more typically from about 2 nm to about 50 nm. The high mesoporosity can provide for faster charge and/or discharge rates than other materials, such as activated carbon. In other words, carbon nano-tubes can support greater current densities than other materials. The fast charge and/or discharge rate for carbon nano-tubes provide high capacitance at high frequencies. The carbon nano-tube composites can support charging and/or discharging rates at frequencies as high at about 100 Hz. Furthermore, the high frequency response for carbon nano-tubes composites support applications requiring high power performance.

The carbon nano-tubes can commonly have a surface area from about 100 m²/g to about 1,000 m²/g, more commonly from about 200 m²/g to about 800 m²/g, even more commonly form about 300 m²/g to about m²/g, or even more commonly from about 350 m2/g to about 450 m²/g. Furthermore, the carbon nano-tubes can have diameters ranging from about a few Ångstroms to about tens of nanometers and lengths from about a few nanometers to about 1 centimeter. The carbon nano-tube length is preferably at least about 1 micron and more preferably range from about 10 to about 100 microns. Commonly, the electron mobility of the carbon nano-tube is at least about 5,000 cm²V⁻¹s⁻¹, more commonly the electron mobility the carbon nano-tube is at least about 10,000 cm²V⁻s⁻¹, or even more commonly the electron mobility is at least about 15,000 cm²V⁻¹s⁻¹. The carbon nano-tubes can commonly have an electrical conductivity of at least about 5,000 S/cm, more commonly have an electrical conductivity of at least about 8,000 S/cm, even more commonly have an electrical conductivity of at least about 9,000 S/cm, or yet even more commonly have an electrical conductivity of at least about 10,000 S/cm. Preferably, the carbon nano-tubes commonly have an intercalation capacity for lithium cations from about 100 to about 1,000 mAh/g, more commonly an intercalation capacity for lithium cations from about 200 to about 800 mAh/g, even more commonly an intercalation capacity for lithium cations from about 300 to about 700 mAh/g, or yet even more commonly an intercalation capacity for lithium cations from about 400 to about 500 mAh/g.

### Ionic Liquid Composition

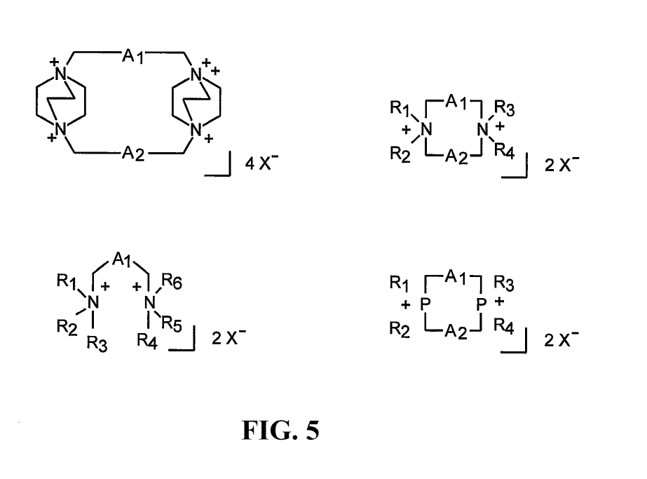

Non-limiting examples of suitable ionic liquids based on various mono-cations are shown in FIG. 5 and non-limiting examples of suitable ionic liquids based on polycations are shown in FIG. 6. The R₁, R₂, R₃, R₄, R₅, and R₆ of the cationic components are identical or different and are preferably selected from the group consisting essentially of:
(a) hydrogen (—H)
(b) a halogen (—Cl, —Br, —I, or —F)
(c) a hydroxyl (—OH)
(d) an amine (—NH₂)
(e) a thiol (—SH)
(f) a C₁ to C₂₅ straight-chain, branched aliphatic hydrocarbon radical
(g) a C₅ to C₃₀ cycloaliphatic hydrocarbon radical
(h) a C₆ to C₃₀ aromatic hydrocarbon radical
(i) a C₇ to C₄₀ alkylaryl radical
(j) a C₂ to C₂₅ linear or branched aliphatic hydrocarbon radical having interruption by one or more heteroatoms, such as, oxygen, nitrogen or sulfur
(k) a C₂ to C₂₅ linear or branched aliphatic hydrocarbon radical having interruption by one or more functionalities selected from the group consisting essentially of:
   a. a carbonyl (—C(O)—)
   b. an ester (—C(O)O—)
   c. an amide (—C(O)NR′—), where R′ selected from the group consisting essentially of hydrogen, C₁-C₁₂ straight-chain, branched or cyclic alkane or alkene
   d. a sulfonate (—S(O)₂O—)
   e. a sulfonamide (—S(O)₂NR′—), where R′ selected from the group consisting essentially of hydrogen, C₁-C₁₂ straight-chain, branched or cyclic alkane or alkene
(l) a C₂ to C₂₅ linear or branched aliphatic hydrocarbon radical terminally functionalized by Cl, Br, F, I, NH, OH, NH₂, NHCH₃ or SH
(m) a C₅ to C₃₀ cycloaliphatic hydrocarbon radical having at least one heteroatom selected from the group consisting essentially of O, N, S, and optionally substituted with at least one of the following Cl, Br, F, I, NH, OH, NH₂, NHCH₃ or SH
(n) a C₇ to C₄₀ alkylaryl radical heteroatom selected from the group consisting essentially of O, N, S, and optionally substituted with at least one of the following
   a. a C₂ to C₂₅ straight-chain, branched hydrocarbon radical substituted with at least one of the following Cl, Br, F, I, NH, OH, NH₂, NHCH₃ or SH
   b. a C₅ to C₃₀ cycloaliphatic hydrocarbon radical substituted with at least one of the following Cl, Br, F, I, NH, OH, NH₂, NHCH₃ or SH
   c. a hydroxyl
   d. an amine
   e. a thiol
(o) a polyether of the type —O—(—R₇—O—)ₙ—R₈ or block or random type —O—(—R₇—O—)ₙ—(—R_{7′}—O—)ₘ—R₈ where
   a. R₇ is a linear or branched hydrocarbon radical having from 2 to 4 carbon atoms
   b. R_{7′} is a linear or branched hydrocarbon radical having from 2 to 4 carbon atoms
   c. n is from 1 to 40
   d. R₈ is hydrogen, or a C₅ to C₃₀ straight-chain or branched hydrocarbon radical, or a C₅ to C₃₀ cycloaliphatic hydrocarbon radical, or a C₆ to C₃₀ aromatic hydrocarbon radical, or a C₇ to C₄₀ alkylaryl radical
(p) a polyether of the type —O—(—R₇—O—)ₙ—C(O)—R₈ or block or random type —O—(—R₇—O—)ₙ—(—R_{7′}—O—)ₘ—C(O)—R₈ where
   a. R₇ is a linear or branched hydrocarbon radical having from 2 to 4 carbon atoms
   b. R_{7′} is a linear or branched hydrocarbon radical having from 2 to 4 carbon atoms
   c. n is from 1 to 40
   d. R₈ is hydrogen, or a C₅ to C₃₀ straight-chain or branched hydrocarbon radical, or a C₅ to C₃₀ cycloaliphatic hydrocarbon radical, or a C₆ to C₃₀ aromatic hydrocarbon radical, or a C₇ to C₄₀ alkylaryl radical.
      The anionic component is preferably selected from the group consisting essentially of:
(a) halides, i.e., chloride, bromide, and iodide, preferably iodide
(b) phosphates
(c) halophosphates, preferably hexafluorophosphate
(d) alkylated phosphates
(e) nitrate
(f) sulfates, i.e., hydrogen-sulfate
(g) alkyl sulfates, preferably octyl sulfate
(h) aryl sulfates
(i) perfluorinated alkyl sulfates
(j) perflorinated alkyl ether sulfates
(k) halogenated alkyl sulfates
(l) perfluorinated aryl sulfates
(m) perflorianted aryl ether sulfates
(n) sulfonates
(o) alkylsulfonates
(p) arylsulfonates
(q) perfluorinated alkyl- and arylsulfonates, preferably triflate (or trifluoromethan sulfonate)
(r) perfluorinated alkyl ether and aryl ether sulfonates
(s) halogenate alkyl- and arylsulfonates,
(t) perchlorate
(u) tetrachloroaluminate
(v) tetrafluoroborate
(w) alkylated borates, preferably B(C₂H₅)₃C₆H₁₃—
(x) tosylate
(y) saccharinate
(z) alkyl carboxylates, and
(aa) bis(perfluoroalkylsulfonyl)amide anions, preferably the bis(trifluoromethylsulfonyl)amide anion, or is
(bb) a mixture of two or more of these anionic species.

In one preferred embodiment, the ionic liquid has halogen-free anions selected from the group consisting essentially of phosphate, alkyl phosphates, nitrate, sulfate, alkyl sulfates, aryl sulfates, sulfonate, alkylsulfonates, arylsulfonates, alkyl borates, tosylate, saccharinate, and alkyl carboxylates, particular preference being given to alkyl sulfates, in particular octyl sulfate, and to tosylate.

In some embodiments, the ionic liquid has various anions and/or cations. The ionic liquids used by way of example as plasticizers may therefore be used individually or in a mixture in the polymer composition of the invention.

Ionic liquids based on polycations are formed when monocations are joined together; FIG. 6 shows monocations joined to form polycationic ring structures, where A₁and A₂ are alkylene groups and substituted alkylene groups. The anion X⁻ includes, without limitation, but is not limited to, F⁻; Cl⁻, Br⁻; I⁻; NO₃⁻; BF₄⁻; N(CN)₂⁻; BF₄⁻; ClO₄⁻; PF₆⁻; RSO₃⁻; RCOO⁻, where R is an alkyl group; substituted alkyl group; phenyl group; (CF₃)₂PF₄⁻, (CF₃)₃PF₃⁻, (CF₃)₄PF₂⁻, (CF₃)₅PF⁻, (CF₃)₆P⁻, (CF₂SO₃⁻)₂, (CF₂CF₂SO₃⁻)₂, (CF₃SO₂⁻)₂N⁻, CF₃CF₂(CF₃)₂CO⁻, (CF₃SO₂⁻)₂CH⁻, (SF₅)₃C⁻, (CF₃SO₂SO₂)₃C⁻, [O(CF₃)₂C₂(CF₃)₂O]₂PO⁻, and CF₃(CF₂)₇SO₃⁻.

Preferably, the ionic liquid is a composition having at least one cation selected from the group consisting essentially ammonium, imidazolium, piperidimum, and pyrrolinium and at least one anion selected from the group consisting essentially of N(CN)₂⁻ and (CF₃SO₂⁻)₂N⁻. Ionic liquids comprising ammonium ionic liquids and imidazolium ionic liquids are more preferably preferred for their large electrochemical window, high ionic conductivity, low viscosity, and wide liquid-phase range.

The ionic liquid can be any suitable electrochemically stable, water miscible and/or immiscible (with water immiscible being preferred) ionic liquid having a relatively low melting point (e.g. preferably less than about 100 degrees Celsius and more preferably from about −5 to about −125 degrees Celsius). Preferably, the ionic liquid has a relatively high thermo-decomposition temperature (e.g., remain substantially thermally stable at temperatures of about 400 degrees Celsius or less), a suitable hydrophobic to hydrophilic ratio (e.g., ability to substantially dissolve one or more lithium-ion containing salts), a low viscosity (e.g., preferably no more than about 200 Cp and even more preferably ranging from about 20 to about 150 Cp), a relatively high ionic conductivity (e.g. preferably at least about 0.01 mS/cm at about 25 degrees Celsius, more preferably from about 1 to about 20 mS/cm) and wide electrochemical window (e.g., preferably at least about 2 volts, more preferably at least about 5 volts, even more preferably at least about 5.5 volts, or yet even more preferably at least about 6 volts versus Li/Li⁺). In some embodiments, the electrochemical window is from about 5 volts to about 20 volts versus Li/Li⁺.

Particularly preferred ionic liquids include ethyl-dimethyl-propylammonium bis(trifluoromethyl-sulfonyl)imide ([EDMPA][TFSI]), N-ethyl-N,N-dimethyl-2-methoxyethylammonium bis(trfluormethylsulyl)imide ([EDMMEA][TFSI]), 1-butyl-1-methyl pyrrolidinium bis(trifluoromethylsulfonyl)imide ([BMP][TFSI]), 1-butyl-1-methylpyrrolidinium dicyanamide ([BMP][DCA]), N-ethyl-N,N-dimethyl-2-methoxyethylammonium bis(trifluoromethylsulfonyl)imide [EDMMEA][Tf2N], and 1-ethyl-3-methylimidazolium bis(trifluoromethylsulfonyl)imide ([EMIM][Tf₂N].

### Polymer Binder

The polymer binder can be any thermoplastic or thermosetting polymer. Preferably, the polymer binder can have a melting point of at least about 60 degrees Celsius and a high solubility in a selected low boiling point (organic) solvent. When thermosetting polymers are used, the polymer preferably cross-links at a temperature below the decomposition temperature of the ionic liquid and/or in response to ultraviolet light or heat. Thermosetting polymers, when cross-linked, form three-dimensional polymer networks through which the ionic liquid can move. Cross-linked polymers typically do not crystallize and have the advantage of superior dimensional stability and mechanical strength. When thermoplastic polymers are used, the polymer preferably melts at a temperature below the decomposition temperature of the ionic liquid.

The polymer binder can be any suitable high molecular weight polymer. Examples of suitable host polymers include homopolymers and copolymers of polyolefins, polystyrenes, polyvinyls, polyacrylics, polyhalo-olefins, polydienes, polyoxides/esthers/acetals, polysulfides, polyesters/thioesters, polyamides/thioamides, polyurethanes/thiourethanes, polyureas/thioureas, polyimides/thioimides, polyanhydrides/thianhydrides, polycarbonates/thiocarbonates, polyimines, polysiloxanes/silanes, polyphosphazenes, polyketones/thioketones, polysulfones/sulfoxides/sulfonates/sulfoamides, polyphylenes, and mixtures thereof.

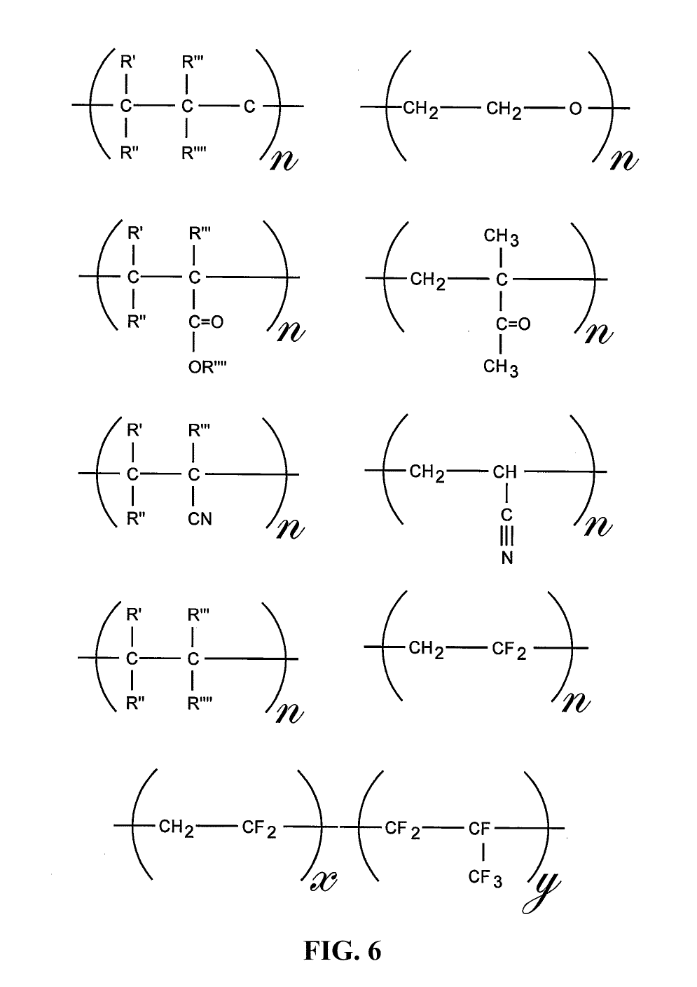

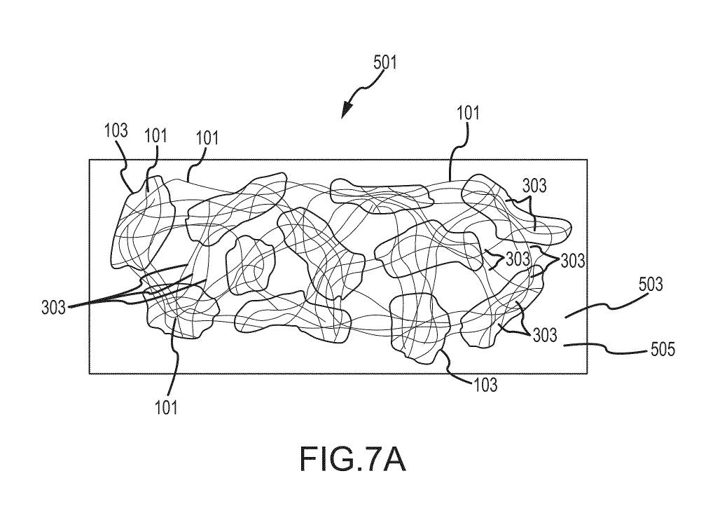

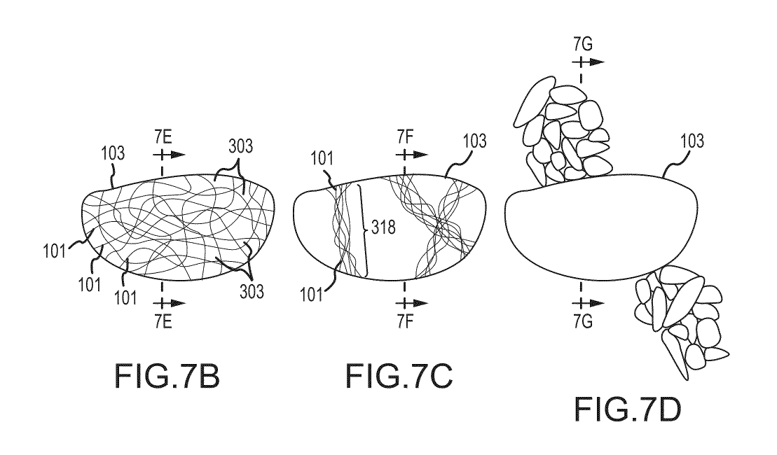

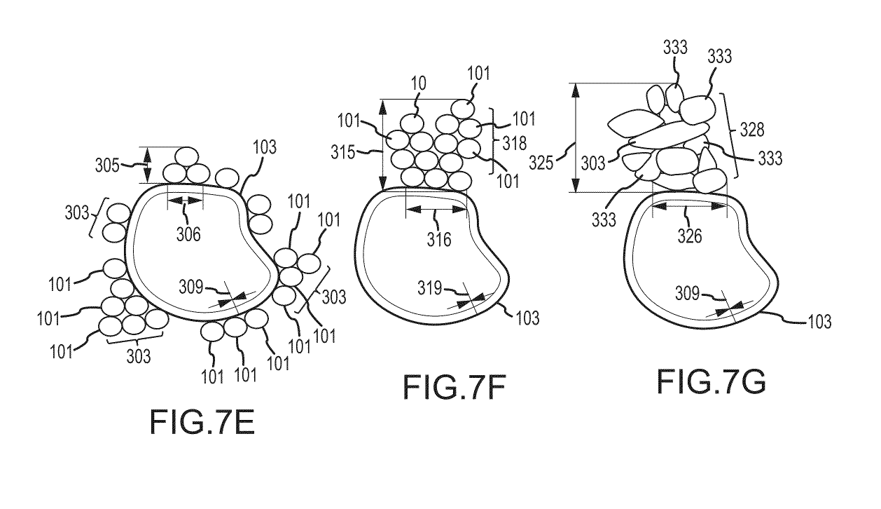

Preferred polymers are semicrystalline or amorphous polymers having no ionic groups. Examples of suitable host polymers are shown in FIG. 7. Particularly preferred host polymers include:
Polyoxides formed by the homo- or co-polymerization of alkylene oxides, R′R″C(O)CR′″R″″, where R′, R″, R′″, and R″″ can separately be hydrogen and/or a C₁-C₁₈ linear or branch alkyl group, or a C₂-C₂₆ cyclic alkyl and/or aryl group, wherein the cyclic or aryl group can contain at least hetero atom selected from the group consisting essentially of O, N and S and wherein the cyclic and/or acyclic alkyl group can be saturated or unsaturated. Preferred the linear or branched alkyl groups are C₁-C₄. The most preferred polyoxide is poly(ethylene oxide) (PEO).
Polyacrylics formed by the homo- or co-polymerization of:
   acrylic acid or its derivatives: R′R″C═CR′″C(═O)OR″″, and/or R′R″C═CR′″C(═O)SR″″, and/or R′R″C═CR′″C(═O)NR″″R′″″; and/or
   acrylontrile, R′R″C═CR′″CN,
where R′, R″, R′″, R″″, and R′″″ can be hydrogen and/or a C₁-C₁₈ linear or branch alkyl group, or a C₂-C₂₆ cyclic alkyl and/or aryl group, wherein the cyclic or aryl group can contain at least hetero atom selected from the group consisting essentially of O, N and S, and wherein the cyclic and acyclic alkyl group may be saturated or unsaturated. Preferred linear or branched alkyl groups are C₁-C₁₂, and the more preferred are C₁-C₆ linear or branched alkyl groups. The most preferred are methyl methacrylate homopolymer and acrylonitrile homopolymer.
Polyhalo-olefins formed by the homo- or co-polymerization of holgenated olefins, R′R″C═CR′″R″″, where R′, R″, R′″, and R″″ that can independently be:
   a hydrogen,
   a halogen,
   a C₁-C₁₈ linear or branched, saturated or unsaturated, alkyl group that may be partially or fully halogenated,
   a C₂-C₂₆ cyclic, saturated or unsaturated, alkyl group and/or aryl group, the cyclic alkyl or aryl group may be partially or fully halogenated.

A preferred linear or branched alkyl group is C₁-C₁₂ that can be partially or fully halogenated. The more preferred halogen is fluoride and the more preferred linear or branched alkyl group is C₁-C₁₂ that can be halogenated, wherein the alkyl group may be partially or fully halogenated. The most preferred are poly(vinyldiene fluoride) where R′ and R″ are hydrogen and R′″ and R″″ are fluoride, and poly(vinyldiene fluoride-co-hexafluoropropylene), a co-polymer wherein one component is R′ and R″ are hydrogen and R′″ and R″″ are fluoride and the other component is R′, R″, R′″ are fluoride and R″″ is trifluoromethyl.

For any polymer formula “N” refers to the number of repeating units in the polymer chain and typically is at least 25 and even more typically ranges from 50 to 50,000. “X” and “Y” is an integer value preferably in the range of 3 to 1,000. “X” and “Y” may, of course, have different values.

Particularly preferred polymer binders include poly(ethylene oxide) (PEO), polyacrylonitrile (PAN), poly(methyl methacrylate) (PMMA), poly(vinylidene fluoride) (PVdF), and poly(vinylidene fluoride-co-hexafluoropropylene) (PVdF-HFP), with PAN and PVdF-HFP being even more preferred. PAN and PVdF, have relatively high thermal stability. In addition, PVdF-based polymer electrolytes are substantially electrochemically stable due to the strongly electron-withdrawing functional group —C—F. PVdF co-polymerized with hexafluoropropylene (PVdF-HFP), can be used to improve the properties of the composite because of its greater solubility in organic solvents, lower crystallinity, and lower glass transition temperature than the PVdF polymer alone in the gel.

When the polymer binder is a thermosetting polymer, the polymer is cross-linked while in the presence of the ionic liquid and graphene and active materials to form the composite. The ionic liquid can plasticize the composite. As a conductive plasticizer, the ionic liquid can decrease the amount of polymer binder necessary to form a mechanically strong composite. Furthermore, the ionic liquid can increase the electric conductivity of the composite.

Preferably, the graphene material in the composite comprises carbon nano-tubes. Typically, the carbon nano-tubes are provided in the form of highly entangled nano-tube bundles. The ionic liquid can untangle the entangled nano-tube bundles to form a well-distributed carbon nano-tube ionic liquid network within the composite. The well-distributed carbon nano-tube network can form with the ionic liquid one or both of a conductive and electrolyte-accessible network within the composite film.

Furthermore, the ionic liquid can impart unique surface properties to the composite. The ionic liquid can impart to the composite surface chemical and/or physical properties similar to that of an ionic liquid-containing electrolyte. When the composite surface and the ionic liquid-containing ionic electrolyte have similar chemical and/or physical properties the composite surface and ionic liquid-containing electrolyte are substantially compatible. For example, the composite surface can be easily wetted by the ionic liquid-containing electrolyte. The wetting of composite surface by the ionic liquid-containing electrolyte can reduce the can reduce interfacial resistance and enhance power capability of the composite. Furthermore, the more complete wetting of the composite surface can increase the capacitance of the composite. While not wanting to be bound by any theory, it is believed that better, more complete wetting of the composite surface effectively increases the active electrochemical surface area.

To produce such a composite, appropriate monomers are mixed with the selected ionic liquid and graphene and active materials, followed by cross-linking reactions. The ionic liquid and grapheme and active materials are trapped in the resulting cross-linked polymer structures. Suitable plasticizers and cross-linking agents may be added to the mixture. For the cross-linking step, several methods, such as ultraviolet (UV) irradiation, electron-beam irradiation, and thermal polymerization, can be selected to initiate cross-linking.

Exemplary cross-linking monomers include acrylate monomers (e.g., ethylene glycol diacrylate, polyethylene glycol diacrylate, trimethylolpropane triacrylate, vinyl acetate, and divinyl adipate, 1,6-hexanediol diacrylate, 1,9-nonanediol diacrylate, 2-butyl-2-ethyl-1,3-propaneiol diacrylate, 2-hydroxy 3-phenyoxy propyl acrylate, 2-hydroxylethyl acrylate, 2-hydroxypropyl acrylate, butoxy ethyl acrylate, behenyl acrylate,diaccrylate of ethylene oxide modified bisphenol A, dipentaerythritol hexaacrylate, neopentyl glycol diacrylate, ethoxy diethyleneglycol acrylate, hexyl polyethyleneglycol acrylate, diethylene glycol diacrylate, isoamyl acrylate, isobornyl acrylate, lauryl acrylate, methoxy triethyleneglycol acrylate, neopentglycol diacryalate, tetraethylene glycol di(chloroacrylate), neopenthylglycol benzoate acrylate, PEG#200 diacrylate, PEG-400 diacrylate, PEG-600 diacrylate, perflorooctylethyl acrylate, triethylene glycol diacrylate, phenoxy ethyl acrylate, diglycerol diacrylate, trimethylolpropane triacrylate, teterahethylene glycol diacrylate, phenoxoy polyethyleneoglycol acrylate, atearyl acrylate, tetrahydro furfuryl acrylate, triethyleneglycol diacrylate, triethyleneglycol diacrylate, trimethylpropane triacrylate, trimethylpropane benzoate acrylate, 2-ethylhexyl acrylate, butyl acrylate, can combinations thereof), methyacrylate monomers (e.g., methyl methacrylate, ethylene glycol dimethacrylate, diglycerol tetramethacrylate, butylene glycol dimethacrylate, polyethylene glycol dimethacrylate,hcyrosyproply methacrylate, diethylene glycol dimethacrylate, triethylene glycol dimethacrylate, tetraethylene glycol dimethacrylate, di(pentamethylene glycol) dimethacrylate, and combinations thereof).

### Active Material

The active material preferably comprises an electrically conductive material. The active material can be an activated carbon (such as, a carbon black), an oxide, a hydride, a nitride, a phosphide, or mixture thereof. The active material can comprise a metal, a metalloid or a non-metal. The metal or metalloid can comprise a metal or metalloid of an element of groups 1, 2, 3, 4-12, 13, 14, 15 and 16 of the periodic table. In some embodiments, the active material can comprise one or more metals, one or more metalloids, or a combination of metals and metalloids. In some embodiments, the active material can comprise compounds containing, oxygen, sulfur, nitrogen, phosphorus, hydrogen, and combinations thereof. Preferably, oxygen is in the −2 oxidation state, sulfur is in the the −2 oxidation state, hydrogen can be in one of −1 or +1 oxygen state, the nitride can be in the −3 oxidation state, and the phosphorous can have an oxidation of −3, +3 or +5.

In some embodiments, the active material can comprise an alkali metal or group 1 metal. The alkali metal can be selected from the group consisting of lithium (Li), sodium (Na), potassium (K), rubidium (Rb), cesium (Cs), francium (Fr) and a mixture thereof. In some embodiments, the active material can comprise an alkaline earth metal or group 2 metal. The alkaline earth metal can be selected from the group consisting of beryllium (Be), magnesium (Mg), calcium (Ca), strontium (Sr), barium (Ba), radium (Ra) and combinations thereof. In yet some embodiments, the active material can comprise a rare earth metal or group 3 metal. The rare earth metal can be selected from the group consisting of scandium (Sc), yttrium (Y), lanthanum (La), cerium (Ce), praseodymium (Pr), neodymium (Nd), samarium (Sr), europium (Eu), gadolinium (Gd), terbium (Tb), dysprosium (Dy), holmium (Ho), erbium (Er), thulium (Tm), ytterbium (Yb), lutetium (Lu) and combinations thereof. In some embodiments the active material can comprise a transition metal or groups 4-12 metal. The transition metal can be selected from the group consisting of titanium (Ti), zirconium (Zr), hafnium (Hf), vanadium (V), niobium (Nb), tantalum (Ta), Chromium (Cr), molybdenum (Mo), tungsten (W), Manganese (Mn), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), zinc (Zn), cadmium (Cd), mercury (Hg) and a combination thereof. In some embodiments, the metal can comprise a post-transition metal or group 13 or 14 metal. The post-transition metal can be selected from the group consisting of aluminum (Al), gallium (Ga), indium (In), thallium (Tl), tin (Sn), lead (Pb) or combination thereof. In some embodiments, the active material can comprise a metalloid or group 13 or 14 metalloid. The metalloid can be selected from the group consisting of antimony (Sb), silicon (Si), germanium (Ge), tellurium (Te) and a combination thereof.

In some embodiments, the active material can be any ordered olivine composition having the general chemical formula YMPO₄. “Y” can be any alkali or alkaline earth metal. Preferably, “Y” is one of Li, Na, K, or a combination thereof. “M” can comprise a rare earth metal, transition metal, post-transition metal, metalloid, or combination thereof. Preferred olivine compounds are, without limitation, LiFePO₄, LiMnPO₄, LiCoPO₄, LiNiPO₄. Furthermore, the olivine compounds can comprise a fluorinated compound having the general chemical formula YMPO₄Fₓ, where 0<x≦6 and “Y” and “M” are as described for YMPO₄. While generally preferred as a cathodic composite, the YMPO₄ and YMPO₄Fₓ compounds need not be limited to cathodic applications and can be applicable in some situations for anodic or other electrode applications that are neither anodic nor cathodic in nature.

In some embodiments, the active material can comprise a rhombohedral super-ionic conductor framework structure having chemical formulae generally represented by one of LiM(PO₄) for the ordered olivine structure, YM₂(XO₄)_{q}, or YM₂(XO₄),_{q}Fᵣ where 0<q≦3 and 0<r≦6. “Y” can be any alkali or alkaline earth metal. Preferably, “Y” is one of Li, Na, K, or a combination thereof. “M” can comprise a rare earth metal, transition metal, post-transition metal, metalloid, or combination thereof. “X” can be any metalloid or non-metal of groups 13-17 of periodic table. Preferably, “X” is one of Si, As, S or mixture thereof. A non-limiting example of a suitable rhombohedral composition is LiFePO₄. While generally preferred as a cathodic composite, the LiM(PO₄), YM₂(XO₄)₀₋₃ YM₂(XO₄)₀₋₃F₀₋₆ compounds need not be limited to cathodic applications and can be applicable in some situations for anodic or other electrode applications that are neither anodic nor cathodic in nature.

In some embodiments, the active material can comprise an oxide generally represented by the chemical formulae MOₓ, YMOₓ or YMOₓF_{z}, where 0<x≦12 and 0<z≦6. “Y” can be any alkali or alkaline earth metal. Preferably, “Y” is one of Li, Na, K, or a combination thereof. “M” can comprise a rare earth metal, transition metal, post-transition metal, metalloid, or combination thereof. The YMOₓ oxide can have a crystalline, non-crystalline, amorphous morphology, or a mixture thereof. Furthermore, the stochiometric ratio of Y to MOₓ is not limited to 1 and can vary. Preferred examples of suitable YMOₓ oxides are without limitation LiCoO₂, LiNi_{0.5}Mn_{1.5}O₄, V₂O₅, LiCo_{1/3}Ni_{1/3}Mn_{1/3}O₂, Li(Li₀₋₁Ni₀₋₁Mn₀₋₁Co₀₋₁)O₂, LiMn₂O₄, MnO₂, LiNiO₂. More preferred are YMOₓ or YMOₓF_{z} compounds that can substantially intercalate one of Li, Na, or K reversibly. While generally preferred as a cathodic composite, the MOₓ, YMOₓ and YMOₓF_{z} compounds need not be limited to cathodic applications and can be applicable in some situations for anodic or other electrode applications that are neither anodic nor cathodic in nature.

In some embodiments, the active material can be any material that can substantially intercalate one or more of Li, Na, and K. Preferably, the active material can substantially reversibly intercalate one or more of Li, Na, or K. Preferably, the active material can comprise a rare earth metal, transition metal, post-transition metal or metalloid containing composition that can substantially intercalate one or more of Li, Na, or K. More preferably, the active material comprises a composite or alloy of Si, Ge, Cu, Sn, Cu—Sn, Si—C, or mixture thereof.

In some embodiments, the active material can be a composition having a general chemical formula represented by YMXX, where “Y” is optional and 0<x<4 and “X” is one of N or P. That is, the YMXₓ composition is one of a nitride or phosphide. “Y” can be any alkali or alkaline earth metal. Preferably, Y is one of Li, Na, K, or a combination thereof. “M” can comprise a rare earth metal, transition metal, post-transition metal, metalloid, or combination thereof. The stochiometric ratio of Y to MXₓ is not limited to 1 and can vary. While generally preferred as an anodic composite, the YMXₓ compositions need not be limited to anodic applications and can be applicable in some situations for cathodic or other electrode applications that are neither anodic nor cathodic in nature.

In some embodiments, the active material can be a hydride composition having a general chemical formula represented by YMHₓ, where “Y” is optional and 1<x<6. “Y” can be any alkali or alkaline earth metal. Preferably, Y is one of Li, Na, K, or a combination thereof. “M” can comprise a rare earth metal, transition metal, post-transition metal, metalloid, or combination thereof. The stochiometric ratio of Y to MHₓ can vary, that is, the stochiometric ratio of Y to MHₓ is not limited to 1. While generally preferred as an anodic composite, the YMHₓ compositions need not be limited to anodic applications and can be applicable in some situations for cathodic or other electrode applications that are neither anodic nor cathodic in nature.

In some embodiments, the active material can comprise a spinel or substituted spinel. As used herein ‘spinel’ or ‘substituted spinel’ refers to a composition having oxide anions arranged with cations in structure generally resembling a cubic close-packed lattice. Preferably, a spinel or substituted spinel can be represented by the general chemical formula AₓB_{y}O₄. ‘A’ and ‘B’ can be divalent, trivalent, or quadrivalent cations. Furthermore, A and B can be the same or differ. Preferably, A and B are metal or metalloid cations selected from the group of elements comprising periodic table groups 1, 2, 3, 4-12 and 13. Commonly A and B can be one or more of lithium (Li), sodium (Na), rubidium (Rb), cesium (Cs), francium (Fr), magnesium (Mg), zinc (Zn), iron (Fe), copper (Cu), manganese (Mn), aluminum (Al), chromium (Cr), titanium (Ti), silicon (Si), nickel (Ni), chromium (Cr), tin (Sn), gallium (Ga), and germanium (Ge). As used herein ‘spinel’ and ‘substituted spinel’ will be used interchangeably.

In some embodiments, the spinel comprises LiMn₂₋ₓMₓO₄ spinel oxides (M=Ni, Fe with x=0.5 or 1 and M=Ni with 0<x<0.5). Preferably, the spinel comprises LiNi_{0.5}Mn_{1.5}O₄. More preferably, the spinel is substantially free of Jahn-Teller distortions due a degenerate electronic ground state. Typically having a spinel containing octahedral manganese in the +4 oxidation state can substantially avoid degenerate electronic ground state associated with manganese in the +3 oxidation state.

Why not wanting to be bound by theory, the charge capacity of a lithium nickel manganese oxide spinel is believed to correspond to the oxidation of Ni²⁺ in Ni⁴⁺ at about 4.8 V vs. Li/Li⁺. This high potential, in comparison to other active materials, gives a very high energy density equivalent to about 700 Wh/kg. In some embodiments, lithium nickel manganese oxide is capable of being operated at voltages greater than about 4 Volts. In some embodiments, lithium nickel manganese oxide can be operated at voltages greater than about 4.5 Volts or even greater than about 4.8 Volts. Furthermore, the high voltage capability of more than about 4.5 or about 5 Volts is typically accompanied by a high power density.

Furthermore, the active material can include, without limitation, oxides comprising cobalt oxides, lithium-containing cobalt oxides, iron phosphates, lithium-containing iron phosphates, metal-containing spinels, lithium-containing spinels, manganese oxides, lithium-containing manganese oxides, titanium disulfides, lithium-containing titanium disulfides, vanadium oxides, lithium-containing vanadium oxides, and combinations thereof.

In a preferred embodiment, the active material can comprise one or more of cobalt oxides, lithium-containing cobalt oxides, vanadium oxides, lithium-containing vanadium oxides, metal-containing spinels, lithium-containing spinels, manganese oxides, and lithium-containing manganese oxides.

Preferably, the active material comprises particles. Particles are preferred for their high current density. Submicron active material particles having substantial homogeneity, uniform morphology, and a narrow size distribution are more preferred. Submicron-sized spinel particles can have a substantially high current density at high voltages.

The active material particles commonly have an average particle size from about 0.1 nanometers to about 1,000 nanometers, more commonly have an average particle size from about 1 nanometer to about 900 nanometers, even more commonly have an average particle size from about 10 nanometers to about 800 nanometers, even more commonly have an average particle size from about 100 nanometers to about 700 nanometers, yet even more commonly have an average particle size from about 200 nanometers to about 600 nanometers, or still yet even more commonly have an average particle size from about 200 nanometers to about 500 nanometers.

In some embodiments the active material average particle size is preferably from about 200 nm to about 400 nm, more preferably, the average particle size of the active material is from about 150 nm to about 200 nm, even more preferably the average particle size of the active material is from about 120 nm to about 140 nm, yet even more preferably, the average particle size of the active material is from about 100 nm to about 120 nm, still yet even more preferably the average particle size of the active material is from about 80 nm to about 100 nm, or yet still even more preferably, the average particle size of active material is from about 60 nm to about 80 nm.

Preferably, when the active material can intercalate one or more of lithium, sodium, and potassium, at least about two moles of one or more of lithium-, sodium-, and/or potassium-ions are intercalated/de-intercalated per mole of the active material. More preferably, the active material can intercalate/de-intercalate at least about four moles of -ions per mole of the active material.

Preferably, the charge capacity of the active material is from about 100 mAh/g to about 150 mAh/g, more preferably from about 125 mAh/g to about 165 mAh/g. Even more preferably the charge capacity of the active material is about 145 mAh/g.

Generally, spinels are prepared by a solid-state method. Spinels prepared by the solid-state method can have some inhomogeneous, irregular morphology, and particles having a broad particle size distribution and an average particle size typically greater than about a micron.

Nano-structured active material can be prepared by any suitable synthetic technique. Preferably, the synthetic techniques yield oxide particles having an average particle size less than about a micron. Suitable synthetic techniques include without limitation, composite carbonate process synthesis of nanocrystalline powders, self combustion reaction synthesis of, and polymer-assisted synthesis of nanoparticles. The polymer synthetic is preferred for producing nanoparticles with high degree of crystallinity.

More, specifically, crystalline nano-particles of lithium nickel manganese oxide can be prepared by a polymer-assisted synthetic technique. Highly crystalline nanoparticles of lithium nickel manganese oxide can be prepared by thermal decomposition of mixed nano-crystalline oxalates that are obtained by grinding hydrated salts “(“hydrates of lithium and nickel are tates”)” and oxalic acid in the presence of a polymer (usually polyethyleneglycol (PEG) 400). Mechanical activation of hydrated salts in the presence of oxalic acid and the polymer, followed by heating at about 800 degrees Celsius, to obtain pseudo-polyhedral lithium nickel manganese oxide particles. While not wanting to be limited by theory, heating at about 800 degrees Celsius the polymer acts as a sacrificial template. That is, the polymer facilitates crystal growth. Furthermore, the polymer assists in forming highly crystalline polyhedral lithium nickel manganese oxide nanoparticles. The lithium nickel manganese oxide nanoparticles have one or more of a well-defined polyhedral morphology, a highly crystalline state, a structure substantially free of imperfections, and a low microstrain content. The nano-particles typically have a particle size from about 60 to about 80 nm in size. Preferably, the lithium nickel manganese oxide nanoparticles are substantially free of one or both of surface and bulk defects. Typically, forming high crystalline lithium nickel manganese oxide nanoparticles substantially forms oxide particles having little, if any, surface and/or bulk defects.

### The Composite

FIGS. 1, 7A and 7B depict a composite 501 according to some embodiments. The composite 501 comprises a graphene material 101, an active material 103, an ionic liquid 505 and a polymer binder 503, each of which is described above. The composite further includes the ionic liquid 505 and graphene 101 and active 103 materials substantially homogeneously distributed in the polymer binder 503. In a more preferred embodiment, at least some, if not most, of the substantially homogenously distributed graphene 101 and active 103 materials are in physical contact with one another. Moreover, the composite further includes a graphene network 303. The graphene network 303 includes graphene material 101 positioned on the active material 103 and graphene material 101 interconnecting two or active material 103 particles. The graphene network 303 can be electrically conductive. Furthermore, the substantially homogeneously distributed ionic liquid 505 and graphene network 303 can form an electrically conductive network in the polymer binder, the ionic liquid 505 can further contribute to the electrical conductivity of the graphene network 303.

Typically, the active material 103 comprises from about 5 wt % to about 98 wt % of the composite, more typically from about 10 wt % to about 95 wt % of the composite, even more typically from about 20 wt % to about 93 wt % of the composite, even more typically from about 30 wt % to about 90 wt % of the composite, yet even more typically from about 40 wt % to about 85 wt % of the composite, still yet even more typically from about 50 wt % to about 80 wt % of the composite, still yet even more typically from about 55 wt % to about 75 wt % of the composite, still yet even more typically form about 60 wt % to about 70 wt % of the composite, or yet still even more typically about 65 wt % of the composite.

In some embodiments, the active material 103 typically comprises from about 25 wt % to about 99 wt % of the composite, more typically the active material comprises from about 30 wt % to about 99 wt % of the composite, even more typically from about 40 to about 98 wt % of the composite, and yet even more typically form about 50 wt % to about 98 wt % of the composite.

The composite 501 can comprise from about 80 wt % to about 0.1 wt % carbon nano-tubes. Commonly the composite can comprise from about 70 wt % to about 1 wt % carbon nanot-tubes, more commonly from about 60 wt % to about 4 wt % carbon nano-tubes, even more commonly from about 50 wt % to about 5 wt % carbon nano-tubes, yet even more commonly from about 40 wt % to about 10 wt % carbon nano-tubes, still yet even more commonly from about 30 wt % to about 15 wt % carbon nano-tubes, still yet even more commonly from about 25 wt % to about 12 wt % carbon nano-tubes, still yet even more commonly from about 22 to about 18 wt % carbon nano-tubes, yet still even more commonly about 20 wt % carbon nano-tubes.

In some embodiments, the composite 501 can commonly comprise from about 0.1 wt % to about 80 wt % carbon nano-tubes, more commonly from about 0.2 wt % to about 75 wt % carbon nano-tubes, even more commonly from about 0.3 wt % to about 50 wt % carbon nano-tubes, yet even more commonly from about 0.3 wt % to about 40 wt % carbon nano-tubes, still yet even more commonly from about 0.4 wt % to about 25 wt % carbon nano-tubes, or yet still even more commonly from about 0.5 wt % to about 15 wt % carbon nano-tubes.

The ionic liquid 505 and polymer binder 503 together comprise from about 1 wt % to about 94 wt % of the composite and have a ratio of the ionic liquid to polymer binder ranging from about 0.01 to about 100. Commonly, the ionic liquid and polymer binder together comprise from about 3 wt % to about 88 wt % of the composite, more commonly the ionic liquid and polymer binder together comprise from about 5 wt % to about 76 wt % of the composite, even more commonly the ionic liquid and polymer binder together comprise from about 10 wt % to about 65 wt % of the composite, yet even more commonly the ionic liquid and polymer binder together comprise from about 12 wt % to about 50 wt % of the composite, still yet even more commonly the ionic liquid and polymer binder together comprise from about 14 wt % to about 35 wt % of the composite, or yet still more commonly about 15 wt % of the composite and typically the ratio of the ionic liquid to polymer binder ranges from about 0.02 to about 50, more typically the ratio of the ionic liquid to polymer binder ranges from about 0.03 to about 30, even more typically the ratio of the ionic liquid to polymer binder ranges from about 0.05 to about 20, yet even more typically the ratio of the ionic liquid to polymer binder ranges from about 0.06 to about 17, still yet even more typically the ratio of the ionic liquid to polymer binder ranges from about 0.08 to about 12, still yet even more typically the ratio of the ionic liquid to polymer binder ranges from about 0.1 to about 10, still yet even more typically the ratio of the ionic liquid to polymer binder ranges from about 0.2 to about 5, still yet even more typically the ratio of the ionic liquid to polymer binder ranges from about 0.3 to about 3, still yet even more typically the ratio of the ionic liquid to polymer binder ranges from about 0.4 to about 2.5, still yet even more typically the ratio of the ionic liquid to polymer binder ranges from about 0.5 to about 2, still yet even more typically the ratio of the ionic liquid to polymer binder ranges from about 0.6 to about 1.5, still yet even more typically the ratio of the ionic liquid to polymer binder ranges from about 0.8 to about 1.2, still yet even more typically the ratio of the ionic liquid to polymer binder ranges from about 0.9 to about 1.1, or yet still even more typically the ratio of the ionic liquid to polymer binder is about 1.

In some embodiments, the ionic liquid can commonly comprise from about 0.5 wt % to about 50 wt % of the composite. Even more commonly, the ionic liquid can comprise from about 1 wt % to about 40 wt % of the composite.

In some embodiments, the polymer binder can commonly comprise from about 0.5 wt % to about 30 wt % of the composite. Even more commonly, the polymer binder can comprise from about 1 wt % to about 20 wt % of the composite.

Preferably, the composite 501 has an average pore size. The average pore size is substantially large to ensure electrolyte access to the composite. Typically, the average pore size of the composite is at least about 2 nm and more typically at least about 10 nm. Furthermore, the average pore size is the composite is typically no more than about 1 μm and more typically no more than about 200 nm. Preferably, the average pore size of the comprise is commonly from about 2 nm to about 500 nm, more commonly the average pore size is from about 5 nm to about 200 nm, or even more commonly the average pore size is from about 10 nm to about 50 nm. The active material can comprise from about 5 wt % to about 98 wt % of the composite.

Typically the composite 501 can have a charge capacity of at least about 100 mAh/g, more typically a charge capacity of at least about 200 mAh/g, more typically a charge capacity of at least about 300 mAh/g, even more typically a charge capacity of at least about 400 mAh/g, or yet even more typically a charge capacity of at least about 500 mAh/g. Furthermore, the composite can commonly have a coulombic efficiency of about at least 100%, more commonly can have a coulombic efficiency of least about 99%, even more commonly can have a coulombic efficiency of at least about 98%, yet even more commonly can have a coulombic efficiency of at least about 97%, or still yet even more commonly can have a coulombic efficiency of at least about 96%.

FIGS. 7B and 7E depict an active material particle 103 with a substantially homogeneous, uniform covering of graphene material 101 in the form of a graphene network 303 according some embodiments. The active material particle 103 has a circumferential length 309. Commonly, the graphene network 303 is in contact with and covers about at least about 5% of the circumferential length 309, more commonly the graphene network 303 is in contact with and covers about at least about 10% of the circumferential length 309, even more commonly the graphene network 303 is in contact with and covers about at least about 20% of the circumferential length 309, yet even more commonly the graphene network 303 is in contact with and covers about at least about 30% of the circumferential length 309, still yet even more commonly the graphene network 303 is in contact with and covers about at least about 40% of the circumferential length 309, still yet even more commonly the graphene network 303 is in contact with and covers about at least about 50% of the circumferential length 309, still yet even more commonly the graphene network 303 is in contact with and covers about at least about 60% of the circumferential length 309, still yet even more commonly the graphene network 303 is in contact with and covers about at least about 70% of the circumferential length 309, still yet even more commonly the graphene network 303 is in contact with and covers about at least about 80% of the circumferential length 309, still yet even more commonly the graphene network 303 is in contact with and covers about at least about 90% of the circumferential length 309, or still yet even more commonly the graphene network 303 is in contact with and covers about at least about 95% of the circumferential length 309. Furthermore, typically at least about 10% of the active material particles 103 are in contact with the graphene network 303, more typically at least about 20% of the active material particles 103 are in contact with the graphene network 303, even more typically at least about 30% of the active material particles 103 are in contact with the graphene network 303, yet even typically at least about 40% of the active material particles 103 are in contact with the graphene network 303, still yet even typically at least about 50% of the active material particles 103 are in contact with the graphene network 303, still yet even typically at least about 60% of the active material particles 103 are in contact with the graphene network 303, still yet even typically at least about 70% of the active material particles 103 are in contact with the graphene network 303, still yet even typically at least about 80% of the active material particles 103 are in contact with the graphene network 303, still yet even typically at least about 90% of the active material particles 103 are in contact with the graphene network 303, still yet even typically at least about 95% of the active material particles 103 are in contact with the graphene network 303, or still yet even typically at least about 99% of the active material particles 103 are in contact with the graphene network 303.

In some embodiments, the graphene network 303 comprises one or more aggregates of graphene particles 308. The graphene particle aggregates 308 are positioned on the surface of the active material particle 103. Each graphene particle aggregate 308 on the active material particle 103 has a surface contact length 306 and graphene particle aggregate thickness 305. Commonly, the surface contact length 306 is at least about 0.8 times the graphene particle aggregate thickness 305, more commonly the surface contact length 306 is at least about 0.9 times the graphene particle aggregate thickness 305, even more commonly the surface contact length 306 is at least about equal to the graphene particle aggregate thickness 305, yet even more commonly the surface contact length 306 is at least about 1.1 times the graphene particle aggregate thickness 305, still yet even more commonly the surface contact length 306 is at least about 1.2 times the graphene particle aggregate thickness 305, still yet even more commonly the surface contact length 306 is at least about 1.3 times the graphene particle aggregate thickness 305, still yet even more commonly the surface contact length 306 is at least about 1.4 times the graphene particle aggregate thickness 305, yet even more commonly the surface contact length 306 is at least about 1.5 times the graphene particle aggregate thickness 305, or still yet even more commonly the surface contact length 306 is at least about 2 times the graphene particle aggregate thickness 305. Preferably, the surface contact length 306 is about equal to or greater than the graphene particle aggregate thickness 305.

FIGS. 7C and 7F depict a second type of composite prepared by mechanical stirring and without an ionic liquid to homogeneously disperse the graphene material 101. In other words, the graphene material 101 comprises entangled, bundles 318. The entangled, bundles 318, while in contact with the active material 103 particles, covers the active material 103 in a non-homogeneous manner. Furthermore, the entangled, bundles 318 of the graphene material 101 commonly covers less of the active material circumferential length 319 than the graphene network of the composite prepared by contacting the graphene material 101 with one or both of ultrasonic energy and an ionic liquid. More commonly, compositions prepared by contacting the graphene material 101 with one or both of ultrasonic energy and an ionic liquid have at least about 10% more of the circumferential length covered with graphen material 101 than compositions prepared without either ultrasound or an ionic liquid, even more commonly at least about 20% more of the circumferential length covered, yet even more commonly at least about 30% more of the circumferential length covered, still yet even more commonly at least about 40% more of the circumferential length covered, still yet even more commonly at least about 50% more of the circumferential length covered, still yet even more commonly at least about 60% more of the circumferential length covered, still yet even more commonly at least about 70% more of the circumferential length covered, still yet even more commonly at least about 80% more of the circumferential length covered, still yet even more commonly at least about 90% more of the circumferential length covered, still yet even more commonly at least about 95% more of the circumferential length covered, or still yet even more commonly at least about 99% more of the circumferential length covered. Furthermore, the entangled, bundle 318 on the surface of the active material particle 103 typically has an entangled, bundle thickness 315 greater than a surface contact length 316 of entangled, bundle 318 on the surface of the active material particle 103.

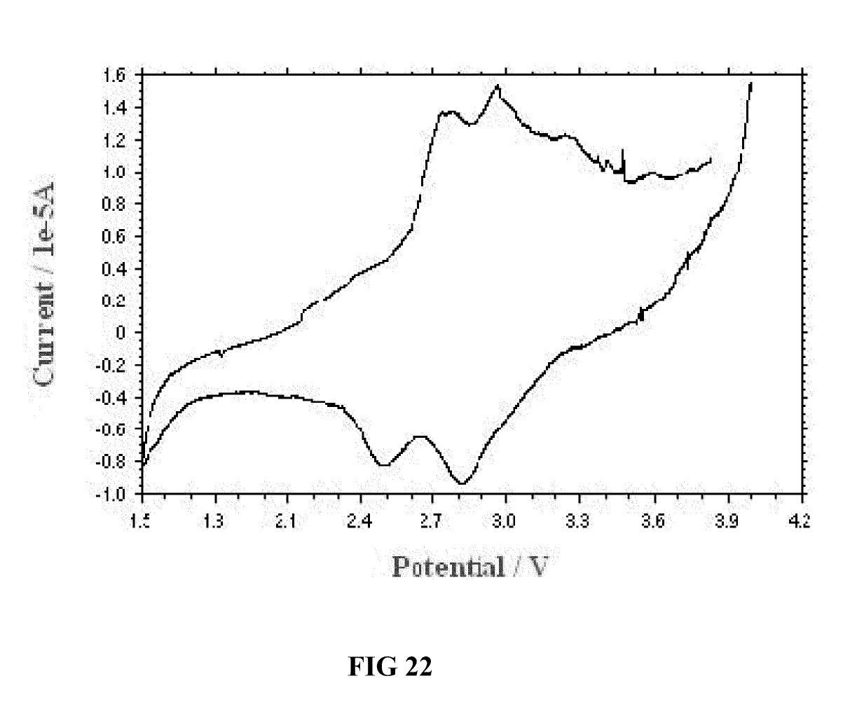

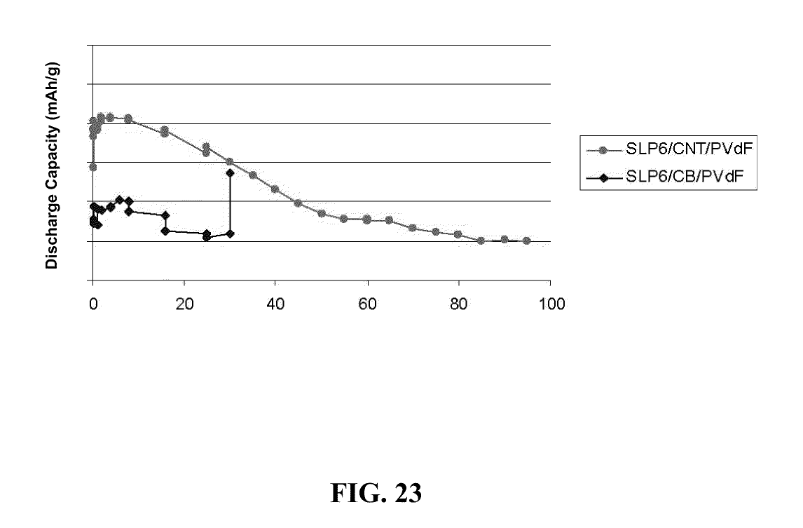

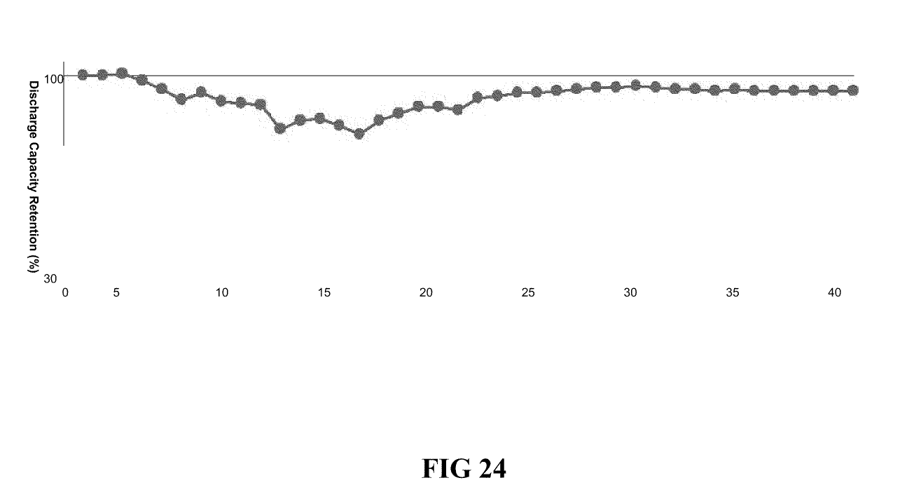

FIGS. 7F, 7G, and 22 depict a third type of composite prepared by mechanically mixing an active material 103 with carbon black 333. The third composite lacks a graphene material and an ionic liquid. The carbon black 333 forms carbon black aggregates 328. The entangled, bundles 318, while in contact with the active material 103 particles, covers the active material 103 in a non-homogeneous manner. Furthermore, the carbon black aggregates 328 commonly cover less of the active material circumferential length 329 than the graphene network of the composite prepared by contacting the graphene material 101 with one or both of ultrasonic energy and an ionic liquid. Furthermore, the carbon black aggregate 328 on the surface of the active material particle 103 typically has a carbon black aggregate thickness 325 greater than a surface contact length 326 of the carbon black aggregate 328 on the surface of the active material particle 103.

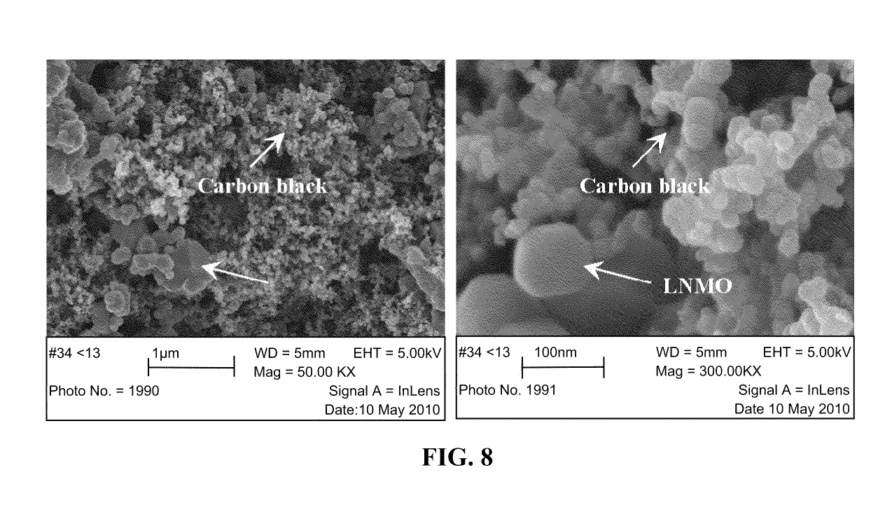

FIG. 8 depicts a process 200 for making the composite 501.

In step 201, an active material 103 is provided. The active material 103 can be purchased or prepared as described herein.

In step 202, the active material 103 is contacted with a graphene material 101 and a polymer binder 503 to form a graphene 101/active 103 material polymeric slurry. Typically, the polymer binder is dissolved and/or dispersed in a solvent and/or carrier fluid prior to contacting with the active material 103.

In step 204, the garphene 101/active 103 material polymeric slurry is contacted with one or both of an ionic liquid 505 and ultrasonic energy. The contacting of the one or both of the ionic liquid 505 and ultrasonic energy with the grapheme/active material polymeric slurry forms a substantially uniform distribution of the graphene and active materials in the graphene/active material polymeric slurry. Moreover, the contacting of the one or both of the ionic liquid and ultrasonic energy forms a substantially homogeneous suspension of the graphene 101 and active 103 materials and polymeric binder in the graphene 101/active 103 material polymeric slurry. More particularly, the one or both of the ionic liquid 505 and ultrasonic energy substantially untangles and/or disperses any tangled and/or aggregated graphene materials 101 contained in the graphene/active material polymeric slurry. It can be appreciated that in some embodiments other optional materials such as viscosity modifiers, fillers, plasticizers, gelling agents, surface active agents,and/or other conductive materials may be added to graphene/active material polymeric slurry.

In step 206, the substantially homogeneous suspension is applied to a substrate to form a slurry film on the substrate. Non-limiting examples of suitable substrates are glass, polymeric materials, and current collectors. Current collectors include, without limitation, conductive metals (e.g. copper, aluminum, nickel, and stainless steel), graphite, superconductive ceramics, and the like. After forming the slurry film, the slurry film is one or more of gelled, cross-linked, and dried. The term gelled refers to forming a gelled polymeric network within in a liquid. The gelled film can reversibility swell and shrink. The polymeric binder 503 may or may not be cross-linked to form the gelled film. The polymer binder 503 may be cross-linked by any cross-linking process. That is, the cross-linking process may proceed at ambient temperature or by the applying one or both of thermal energy or electromagnetic energy. Furthermore, the cross-linking process may include one or more catalysts.

In one configuration, composites prepared by some embodiments can have a specific capacity greater than a similar composite having the same materials but prepared without one of an ionic liquid, sonication, or both. Commonly the specific capacity of the composite is at least about the same, more commonly at least about 1.1 times, even more commonly at least about 1.2 times, yet even more commonly at least about 1.3 times, still yet even more commonly at least about 1.5 times, still yet even more commonly at least about 1.8 times, still yet even more commonly at least about 12 times, still yet even more commonly at least about 3 times, still yet even more commonly at least about 5 times, still yet even more commonly at least about 10 times, still yet even more commonly at least about 15 times, still yet even more commonly at least about 20 times, or still yet even more commonly at least about 30 times the specific capacity of a similar composition having the same materials but prepared without one of an ionic liquid, sonication or both.

In yet another configuration, composites prepare by some embodiments can have a lower interfacial resistance with an electrolyte than a similar composite comprising the same materials but prepared without one of an ionic liquid, sonication, or both. Commonly the interfacial resistance of the composite with an electrolyte is at least about the same, more commonly is no more than about 0.98 times, even more commonly is no more than about 0.95 times, yet even more commonly is no more than about 0.9 times, still yet even more commonly is no more than about 0.8 times, still yet even more commonly is no more than about 0.7 times, still yet even more commonly is no more than about 0.5 times, still yet even more commonly is no more than about 0.3 times, still yet even more commonly is no more than about 0.1 times, still yet even more commonly is no more than about 0.08 times, still yet even more commonly is no more than about 0.06 times, still yet even more commonly is no more than about 0.4 times, or still yet even more commonly is no more than about 0.02 times the interfacial resistance of a similar composite having the same materials prepare without one of an ionic liquid, sonication or both with an electrolyte.

In still yet another configuration, composites prepared by some embodiments can have a greater rate capability (that is maximum rate capability), than a similar composite comprising the same materials but prepared without one of an ionic liquid, sonication, or both. Commonly the rate capacity of the composite is at least about the same rate capability, more commonly at least about 1.1 times, even more commonly at least about 1.2 times, yet even more commonly at least about 1.3 times, still yet even more commonly at least about 1.5 times, still yet even more commonly at least about 1.8 times, still yet even more commonly at least about 12 times, still yet even more commonly at least about 3 times, still yet even more commonly at least about 5 times, still yet even more commonly at least about 10 times, still yet even more commonly at least about 15 times, still yet even more commonly at least about 20 times, or still yet even more commonly at least about 30 times the rate capability of a similar composition having the same materials but prepared without one of an ionic liquid, sonication or both.

In still yet another configuration, composites prepared by some embodiments can have a greater specific capacitance than a similar composite comprising the same materials but prepared without one of an ionic liquid, sonication, or both. Commonly the rate capacity of the composite is at least about the same, more commonly at least about 1.1 times, even more commonly at least about 1.2 times, yet even more commonly at least about 1.3 times, still yet even more commonly at least about 1.4 times, still yet even more commonly at least about 1.5 times, still yet even more commonly at least about 1.6 times, still yet even more commonly at least about 1.7 times, still yet even more commonly at least about 1.8 times, still yet even more commonly at least about 1.9 times, still yet even more commonly at least about 2.0 times, still yet even more commonly at least about 2.2 times, or still yet even more commonly at least about 2.5 times the specific capacitance of a similar composition having the same materials but prepared without one of an ionic liquid, sonication or both.

In still yet another configuration, composites prepared by some embodiments can have a greater charge/discharge efficiency than a similar composite comprising the same materials but prepared without one of an ionic liquid, sonication, or both. Commonly the rate capacity of the composite is at least about the same, more commonly at least about 1.1 times, even more commonly at least about 1.2 times, yet even more commonly at least about 1.3 times, still yet even more commonly at least about 1.4 times, still yet even more commonly at least about 1.5 times, still yet even more commonly at least about 1.6 times, still yet even more commonly at least about 1.7 times, still yet even more commonly at least about 1.8 times, still yet even more commonly at least about 1.9 times, still yet even more commonly at least about 2.0 times, still yet even more commonly at least about 2.2 times, or still yet even more commonly at least about 2.5 times the charge/discharge efficient of a similar composite having the same materials but prepared without one of an ionic liquid, sonication or both.

In still yet another configuration, composites prepared by some embodiments can have an lower porosity with an electrolyte than a similar composite comprising the same materials but prepared without one of an ionic liquid, sonication, or both. Commonly the porosity of the composite with an electrolyte is at least about the same, more commonly is no more than about 0.98 times, even more commonly is no more than about 0.95 times, yet even more commonly is no more than about 0.9 times, still yet even more commonly is no more than about 0.8 times, still yet even more commonly is no more than about 0.7 times, still yet even more commonly is no more than about 0.5 times, still yet even more commonly is no more than about 0.3 times, still yet even more commonly is no more than about 0.1 times, still yet even more commonly is no more than about 0.08 times, still yet even more commonly is no more than about 0.06 times, still yet even more commonly is no more than about 0.4 times, or still yet even more commonly is no more than about 0.02 times the porosity of a similar composite having the same materials but prepared without one of an ionic liquid, sonication or both.

Some embodiments include the one or more of the above configurations combined in any manner. That is, one or more configurations to improved specific capacity, interfacial resistance, rate capability, specific capacitance, charge/discharge efficiency, or prososity of the composition to a similar composite prepared with the same materials but lacking one of of an ionic liquid, sonication or both can be combined in any manner.

### Electrochemical Devices Comprising the Composite

Some embodiments include a device or apparatus having the composite positioned on at least one surface of a conductive material. Preferably, the device produces and/or stores electric energy and/or charge. More preferably, the device is one of an electrode, a cathode, an anode, a lithium-ion battery cathode, a lithium-ion battery anode, a capacitor, or a super capacitor.

In some embodiments, the device further includes an electrolyte in contact with the composite. The composite is positioned between the conductive material and the electrolyte. The electrolyte may comprise an ionic liquid. The electrolyte and the ionic liquid of the composite may be the same or may differ.

Preferred electrochemical devices are capacitors and batteries. A more preferred electrochemical device comprises a lithium-ion battery. A lithium-ion battery typically comprises a lithium-ion intercalation anode, a lithium-ion intercalation cathode, and a battery electrolyte.

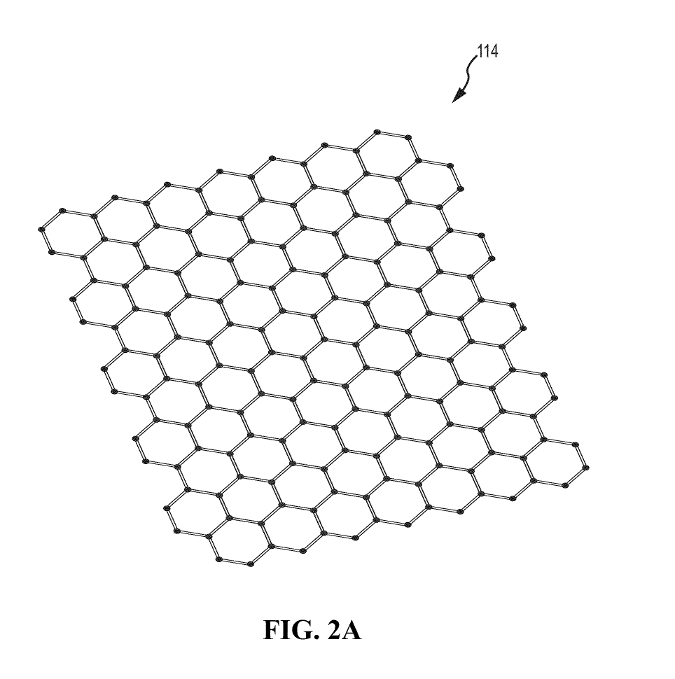

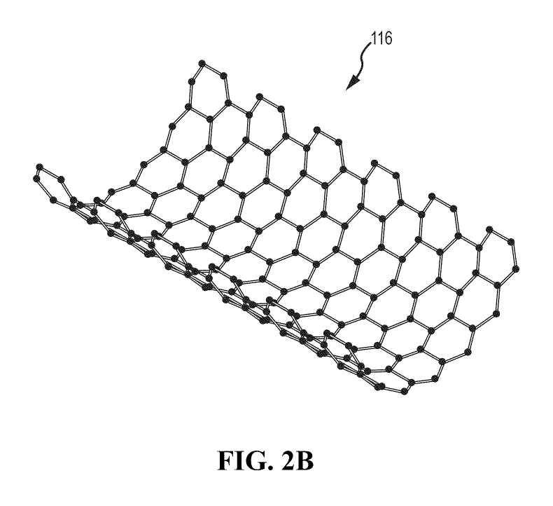

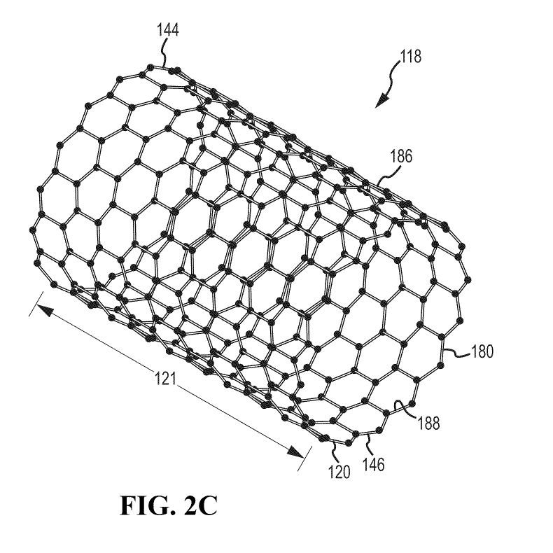

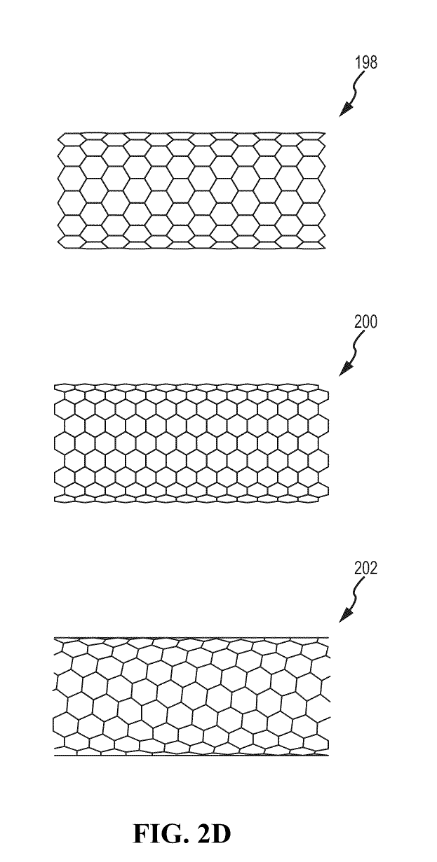

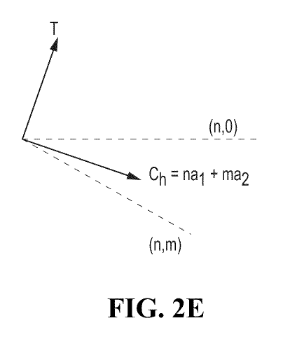

FIG. 2 depicts an electrochemical battery 100 according some embodiments. The electrochemical battery 100 can comprise first 102 and second 104 current collectors, an anode 106, a cathode 108, and an electrolyte 110 and an optional membrane 112 positioned between the anode 106 and cathode 108. Preferably, the anode 106 comprises a lithium-ion intercalation anode and the cathode 108 comprises a lithium-ion intercalation cathode. Preferably, the electrolyte 110 comprises an ionic liquid. Preferably, one or both of the first 102 and second 104 current collectors further comprise a composite film. The physical properties of the anode 106, the cathode 108 and the ionic liquid electrolyte 110 can substantially influence the performance properties of the electrochemical battery 100. As will be appreciated, the electrochemical battery can be of other designs, including, without limitation, stacked and spiral-wound configurations. Alternatively, each of the anode 106 and cathode 108 can act both as an electrode and current collector.

The first 102 and second 104 current collectors can be any highly conductive and/or superconductive materials. Examples include, without limitation, conductive metals (e.g. copper, aluminum, nickel, and stainless steel), graphite, superconductive ceramics, and the like. In one embodiment, nickel foil is used for one or both of the first 102 and second 104 current collectors.

Preferably, the lithium-ion intercalation cathode comprises a composite comprising a plurality of carbon nano-tubes, an active material, an ionic liquid and a polymer binder. The composite can be any of the composite materials described above. More preferably cathode comprises from about 50 wt % to about 98wt % of the active material, from about 0.5 wt % to about 15 wt % of the graphene material, 1 wt % to about 40 wt % of the ionic liquid, and from about 1 wt % to about 20wt % of the polymeric binder. Preferably, the active material comprises one of lithium nickel manganese oxide, V₂O₅, or a mixture thereof. Preferably, the ionic liquid comprise one of and EDMMEA or EMIIM.

Preferably, the lithium-ion intercalation anode comprises a composite having one or more of activated carbon, graphitic carbon, hard carbon, and lithium as the active material, a graphene material, an ionic liquid and a polymer binder. In a preferred embodiment the composite comprises from about 80 to about 40 wt % activated carbon, from about 5 to about 40 wt % carbon nano-tubes and from about 1 to about 15 wt % ionic liquid and from about 1 to about 15 wt % of the polymeric binder.

The electrolyte 110 can be a liquid electrolyte (such as a salt dissolved in a solvent) or a gel polymer electrolyte, or an ionic liquid electrolyte. Ionic liquids, as described above, are preferred. In a preferred embodiment, the ionic liquid electrolyte includes a lithium salt, and a solid electrolyte interphase film-forming additive. The ionic liquid is believed to act as a solvent for the lithium salt. While not wanting to be bound by theory, the composition of the ionic liquid electrolyte affects lithium-ion intercalation and de-intercalation. More specifically, one or more of the ionic liquid, lithium salt, and solid electrolyte interphase individually or combinedly affect lithium-ion intercalation and de-intercalation.

In some embodiments, the electrolyte 110 includes an ionic liquid electrolyte in the form of a gel polymer having the ionic liquid-incorporated in a gel polymer electrolyte. The ionic liquid can be combined with a polymer binder to form the ionic liquid-incorporated gel polymer electrolyte. The polymer binder can be polymer binder as described above.

The lithium salt can be any lithium salt. Lithium salts having substantial thermal stability and solubility in the ionic liquid are preferred. Non-limiting examples of preferred lithium salts comprise: lithium hexafluorophosphate, lithium chloride, lithium bromide, lithium hexafluoroarsenate, lithium perchlorate, lithium tetrafluoroborate, lithium bis(trifluoromethylsulfonyl)imide, lithium tris(trifluoromethylsulfonyl)methide, and lithium bis(oxalato) borate. More preferred lithium salts comprise one or more of lithium tetrafluoroborate (LiBF₄), lithium bis(trifluoromethylsulfonyl) imide (Li[TFSI]) and lithium bis(oxalato) borate (Li[BOB]). The lithium salt concentration ranges from about 0.1 M to about 5 M (based on the molar concentration of the lithium salt). Preferred lithium salt concentrations are from about 0.5 M to about 2.5 M, with a lithium salt concentration of about 1 M being more preferred.

The solid electrolyte interphase film-forming additive comprises one of: an alkly carbonate; a cyclic carbonate; an acyclic carbonate; and a combination thereof. Examples of preferred carbonates are, without limitation: propylene carbonate, ethylene carbonate, ethylmethyl carbonate, and combinations thereof. Preferred carbonates comprise, ethylene carbonate (e.g., 1,3-dioxolan-2-one or (CH₂CH₂O)₂C═O) and linear carbonate mixtures comprising ethylene carbonate. In an ionic liquid electrolyte, the solid electrolyte interphase film-forming additive can be used to modify and/or control some of the physical properties of the ionic liquid electrolyte, for example, lowering the viscosity of the resultant electrolyte. In a preferred embodiment, the solid electrolyte interphase film-forming additive is a component that forms a passivation film on the anode. That is, the solid electrolyte interphase film forming additive contacts the anode, during the electrochemical process, to form a passivation film on the anode. The passivation film is also typically referred to as the solid electrolyte interface. In a preferred embodiment, the solid electrolyte interface is substantially formed during one or more of the first to about the tenth battery charging. In a more preferred embodiment, the solid electrolyte interface is substantially formed during one or more of the first to about the fifth battery charging and even more preferred from about the first to third battery charging. The solid electrolyte interphase comprises from about 2 volume % to about 50 volume % of the electrolyte, more preferably from about 10 volume % to about 30 volume % of the electrolyte.

More detailed non-limiting examples of batteries and capacitor electrode are provided in the Examples.

A number of variations and modifications of the invention can be used. It would be possible to provide for some features of the invention without providing others.

The present invention, in various embodiments, configurations, or aspects, includes components, methods, processes, systems and/or apparatus substantially as depicted and described herein, including various embodiments, configurations, aspects, sub-combinations, and subsets thereof. Those of skill in the art will understand how to make and use the present invention after understanding the present disclosure. The present invention, in various embodiments, configurations, and aspects, includes providing devices and processes in the absence of items not depicted and/or described herein or in various embodiments, configurations, or aspects hereof, including in the absence of such items as may have been used in previous devices or processes, e.g., for improving performance, achieving ease and\or reducing cost of implementation.

The foregoing discussion of the invention has been presented for purposes of illustration and description. The foregoing is not intended to limit the invention to the form or forms disclosed herein. In the foregoing Detailed Description for example, various features of the invention are grouped together in one or more embodiments, configurations, or aspects for the purpose of streamlining the disclosure. The features of the embodiments, configurations, or aspects of the invention may be combined in alternate embodiments, configurations, or aspects other than those discussed above. This method of disclosure is not to be interpreted as reflecting an intention that the claimed invention requires more features than are expressly recited in each claim. Rather, as the following claims reflect, inventive aspects lie in less than all features of a single foregoing disclosed embodiment, configuration, or aspect. Thus, the following claims are hereby incorporated into this Detailed Description, with each claim standing on its own as a separate preferred embodiment of the invention.

Moreover, though the description of the invention has included description of one or more embodiments, configurations, or aspects and certain variations and modifications, other variations, combinations, and modifications are within the scope of the invention, e.g., as may be within the skill and knowledge of those in the art, after understanding the present disclosure. It is intended to obtain rights which include alternative embodiments, configurations, or aspects to the extent permitted, including alternate, interchangeable and/or equivalent structures, functions, ranges or steps to those claimed, whether or not such alternate, interchangeable and/or equivalent structures, functions, ranges or steps are disclosed herein, and without intending to publicly dedicate any patentable subject matter.

### EXAMPLES

### Example I

### Synthesis of Lithium Nickel Manganese Oxide

Lithium nickel manganese oxide was synthesized using a polymer-assisted synthetic route. In general, the polymer-assisted route as described by J. C. Arrebola et al. in the Journal of Inorganic Chemistry, 2008, 3295, was followed. The synthesis yielded. crystalline lithium nickel manganese oxide particles. The particles had an average particle size from about 1 nm to about 1,000 nm. That is, the synthesis yielded substantially nano-particulate lithium nickel manganese oxide.

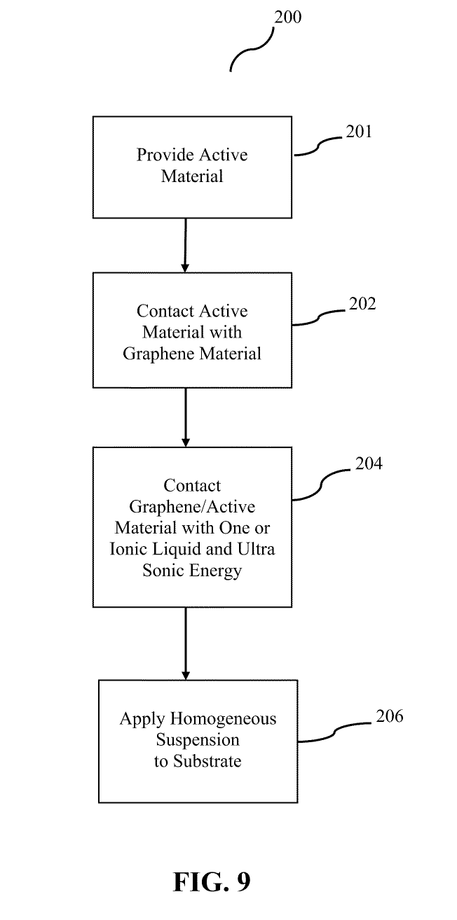

Lithium acetate dihydrate (about 1.0202 g), manganese acetate tetrahydrate (about 3.6764 g), and nickel acetate tetrahydrate (1.2442 g) were mixed using a mortar and pestle to make a ground, homogenous mixture. About 2.5214 g of oxalic acid was added to the ground, homogeneous mixture and the grinding was continued for about 5 minutes. After the 5 minute grinding period, about 2.22 ml of polyethylene glycol-400 was added to the mixture and the grinding was continued for about 50 minutes. A viscous blue/green gel formed during the 50 minute-grinding period. The gel was dried in a vacuum oven at about 80 degrees Celsius and about 20 inches of mercury for about 6 hours, followed by heating for about 2 hours at about 400 degrees Celsius. The heating at 400 degrees Celsius decomposes the acetates to form lithium nickel manganese oxide micro-particles. The lithium nickel manganese oxide micro-particles are heated from about 800 to about 850 degrees Celsius for about 5 hours to calcinate the lithium nickel manganese oxide micro-particles and form lithium nickel manganese oxide nano-particles. FIG. 9 depicts micrographs of lithium nickel manganese oxide nano-particles formed when lithium nickel manganese oxide micro-particles are calcined at about 800 degrees Celsius (micrograph (a) of FIG. 9) and at about 850 degress Celsius (micrograph (b) of FIG. 9).

### Example 2

### Lithium Nickel Manganese Oxide Electrode

About 80 grams of lithium nickel manganese oxide nanoparticles of Example 1, about 15 grams of carbon black, and about 5 grams of a polyvinylidene fluoride in a/N-methyl-2-pyrrolidone solution were mixed together in a glass tube by mechanical stirring at about 350 RPM for about 60 minutes to form a slurry. The slurry was cast with a knife-coating blade on an aluminum foil current collector. The casted slurry was heated in an oven for about 15 hours at temperature of about 85 degrees Celsius to from a baseline lithium nickel manganese oxide electrode (hereafter referred to as ‘LNMO baseline electrode’). The LNMO baseline electrode had a uniform coating comprising lithium nickel manganese oxide, carbon black, and polyvinylidene fluoride. The coating density of the uniform coating was from about 5 to about 6 mg/cm².

### Example 3

### Electrochemical Evaluation of Lithium Manganese Oxide Electrode Baseline Electrode

A test electrochemical device was fabricated with the LNMO baseline electrode of Example 2. A CR2032 coin cell was fabricated in an argon filled glove box. The CR2032 test cell had a lithium foil counter electrode, a reference electrode, a conventional nonaqueous electrolyte and a nano-porous membrane separator. The nonaqueous electrolyte was 0.5 M LiPF₆ in a 1:1 by weight solution of ethylene carbonate and dimethyl carbonate. The nano-porous membrane separator was a 40 μm polyolefin film having a porosity of about 80%.

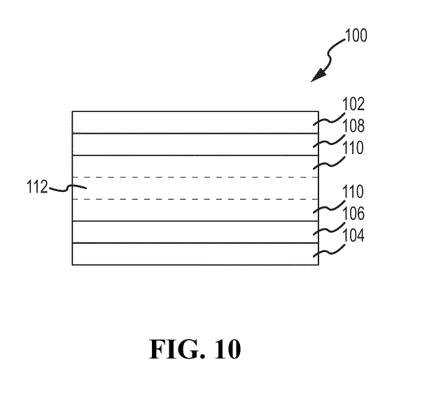

The CR2032 test cell was evaluated using cyclic voltammetry. A cyclic voltammogram was recorded at 0.1 mV/s over a potential from about 3.5 to about 5.0 volts versus Li/Li⁺. The cyclic voltammogram is depicted in FIG. 10. Oxidation and reduction peaks were observed at about 4.8 and 4.6 V versus Li/Li⁺. Furthermore, less intense peaks or shoulders were observed at about 4.7 and 4.5 V versus Li/Li⁺. The peaks observed in the cyclic voltammogram are indicative of reversible interclation/deintercalation of a lithium cation, Li⁺, with the nickel in a lithium nickel manganese oxide. More specifically, the peaks are indicative of reversible interclation/deintercalation of Li⁺ with one or more of Ni²⁺, Ni³⁺, and Ni⁴⁺ in lithium nickel manganese oxide.

Furthermore, a small separation (denoted as ΔEp in Table I) between the oxidation peak at about 4.8 V versus Li/Li⁺ and reduction peak at about 4.6 V versus Li/Li⁺ is indicative of reversible process (see Table I). It is believed that, a pair of small peaks appearing in a lower potential rejoin (around 4V) can be attributed to the reversible process of due to the presence of trace LiMn₂O₄ in the lithium nickel manganese oxide nanoparticles.

TABLE I

| Cyclinc voltammetry | Epₒₓ (V) | Ep_{red} (V) | Δ Ep (mV) | | |
|---|---|---|---|---|---|
| (CV at 0.1 mV/s) | 4.800 | 4.610 | 190 | | |
| Asymmetric charge/ | Discharge | Discharge | Discharge | Discharge | Discharge |
| discharge | capacity at | capacity | capacity | capacity | capacity |
| (charged at 0.25C and | 0.25C (mAH/g) | retention at | retention | retention at | retention |
| discharged at | | 0.5C (%) | at 1C (%) | 2C (%) | at 4C (%) |
| different rates) | 101.2 | 105.1 | 106.5 | 106.3 | 105.0 |

| Symmetric charge/ | Charge capacity | Charge | Charge | Charge capacity |
|---|---|---|---|---|
| discharge | at 0.25C | capacity | capacity | retention at 4C (%) |
| (charged/discharged | (mAH/g) | retention at | retention | |
| at different rates) | | 1C (%) | at 2C (%) | |
| | 144.9 | 78.5 | 71.8 | 66.3 |

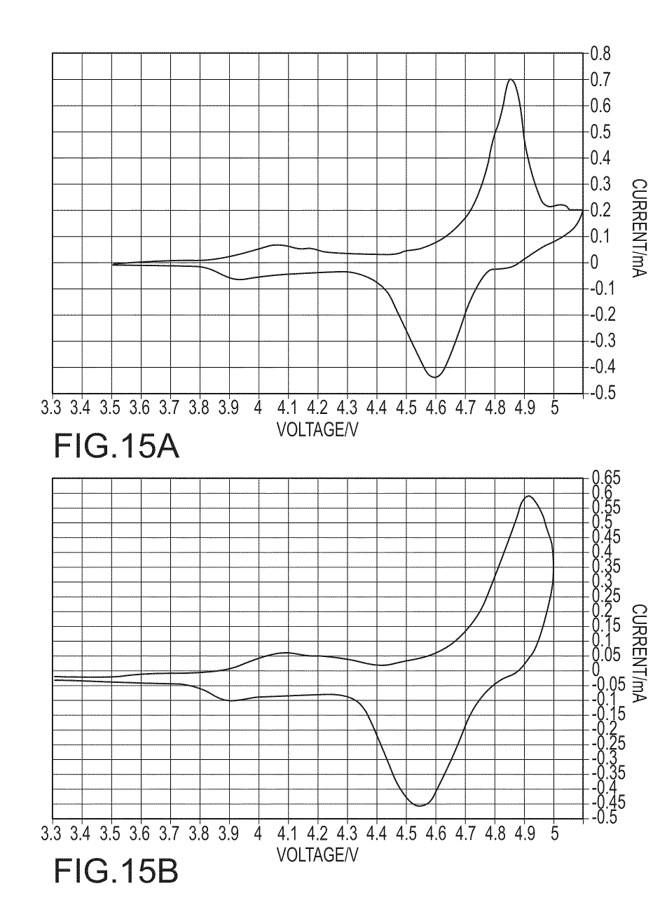

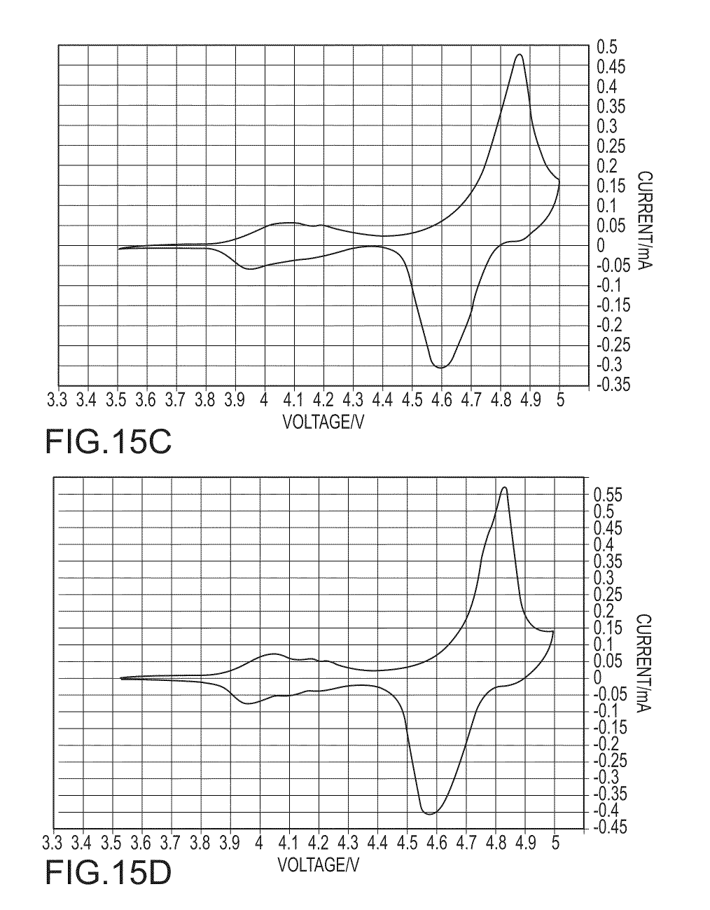

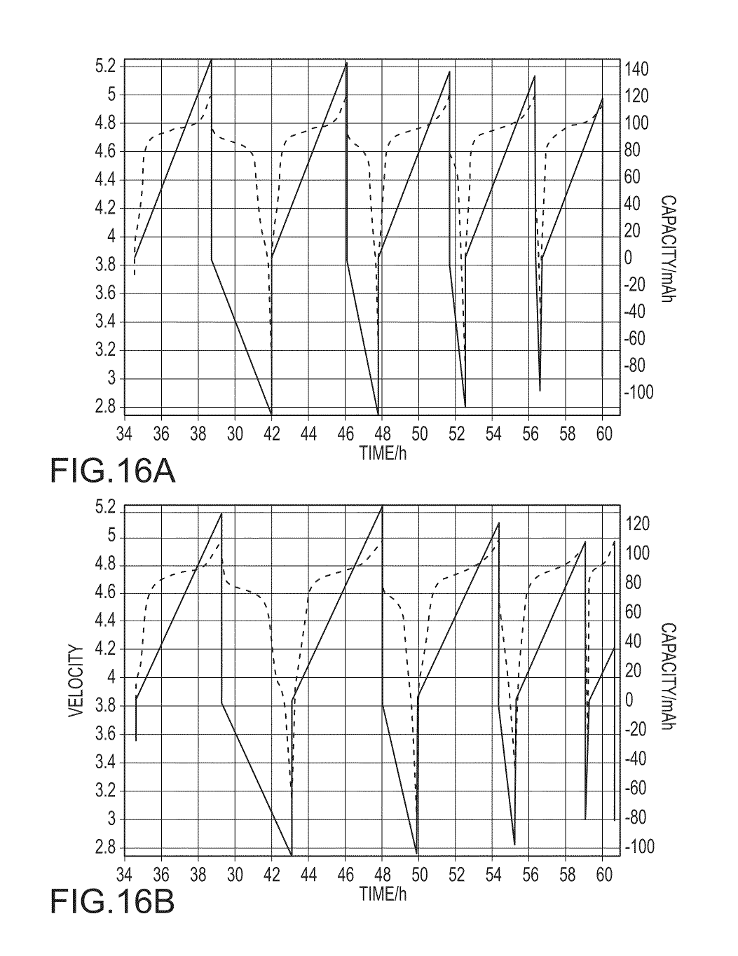

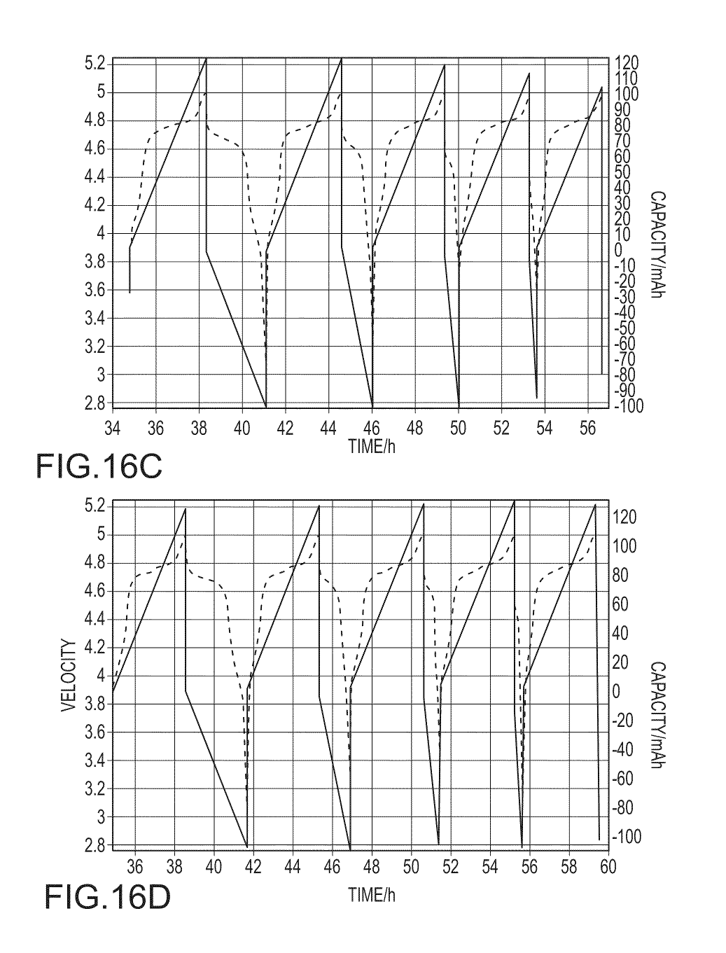

Data from FIGS. 15 and 16

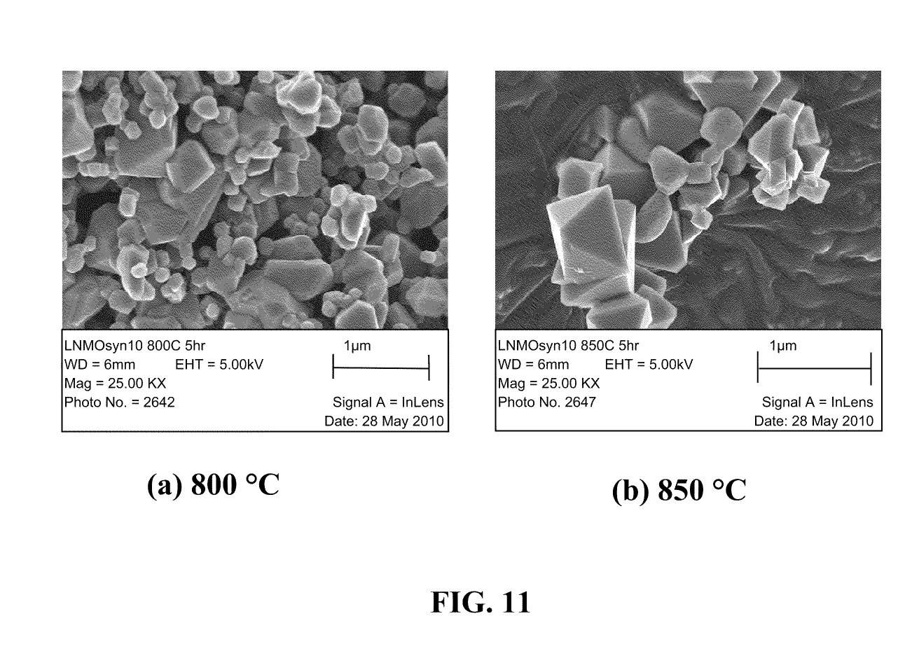

Moreover, the CR2032 test cell was evaluated using an asymmetric galvanostatic charge/discharge test (see FIG. 11, Left). The asymmetric galvanostatic charge/discharge test indicated that the lithium nickel manganese electrode had a discharge capacity of about 101.2 mAh/g at a discharge rate of 0.25 C. Discharge capacity retention was determined by comparing the capacity at a specific discharge rate to that at 0.25 C. The discharge capacity retained (that is, 100%) even at a discharge rate of to 4 C (See Table II). A symmetric charge/discharge analysis of the CR2032 test cell (See FIG. 11, Right) indicated a high charge capacity of 144.9 mAh/g at 0.25 C and retained up to 66.3% of the capacity at 4 C (see Table II), which is characteristic of an electrode that can be rapidly charged to a substantially high charge capacity. It is believed that the crystalline nanostructure of the lithium nickel manganese oxide support the rapid substantially rapid and/or high charge capacity the LNMO baseline electrode.

TABLE II

| EC concentration (wt. %) | | | |
|---|---|---|---|
| in a 0.5M LiPF₆/ | | | |
| [EDMMEA][Tf₂N] electrolyte | Epₒₓ (V) | Ep_{red} (V) | ΔEp (mV) |
| 20 | 4.963 | 4.580 | 383 |
| 40 | 4.874 | 4.594 | 280 |
| 50 | 4.858 | 4.605 | 253 |
| 57.2 | 4.828 | 4.616 | 212 |

### Example 4

### LNMO Baseline Electrode in an Ionic Liquid Electrolyte

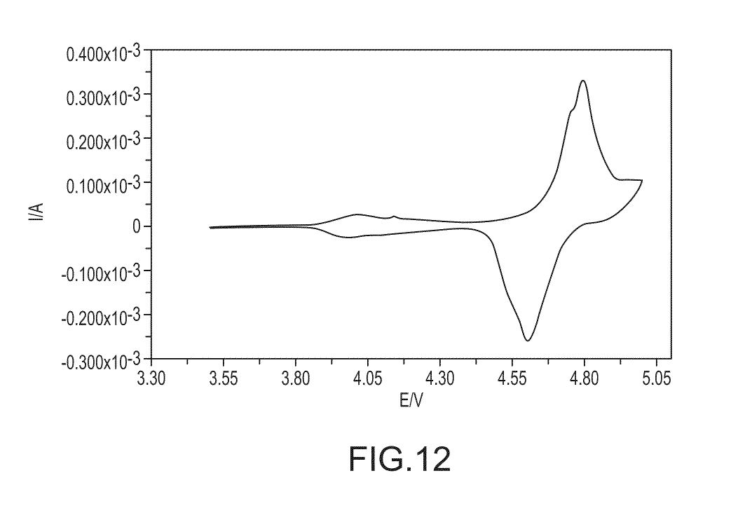

The electrochemical behavior the LNMO electrode of Example 2 was evaluated in ionic liquid electrolytes. The electrolyte contained ionic liquid N-Ethyl-N,N-dimethyl-2-methoxyethylammonium bis(trifluormethylsulfonyl)imide, hereafter referred to as [EDMMEA][Tf₂N]. The ionic liquid electrolyte comprised [EDMMEA][Tf₂N] with ethylene carbonate and LiPF₆. Cyclic voltammograms were generated for the LNMO baseline electrode of example 2, in 0.5 M LiPF₆/[EDMMEA][Tf₂N] with varying amounts of ethylene carbonate. The ethylene carbonate concentrations evaluated were about 10 wt %, 40 wt %, 50 wt % and 57.2 wt %. The cyclic voltammograms are shown, respectively, in FIGS. 12(a)-12(d). The cyclic voltammograph of FIG. 12(a) is poorly defined. More specifically, the cyclic voltammogram (FIG. 12(a)) has a large peak separation between the oxidation and reduction peaks associated with nickel (2+) and nickel (+4). Furthermore, the oxidation and reduction peaks associated with manganese (3+) and manganese (4+) are shifted a high potential region of about 4.2 and 3.8 volts. The poorly defined cyclic voltammogram of FIG. 12(a) is substantially indicative of poor electrochemical behavior of the LNMO baseline electrode in ionic liquid having 10 wt % ethyelene carbonate.

Better, more well-defined cyclic voltammograms were obtained when the ethylene carbonate concentration was increased to about 20 wt % or more. For example, the nickel (+2) to nickel (+4) oxidation and reduction peak appeared and was better defined. Furthermore, the nickel (+2) and nickel (+4) peaks had a smaller peak separation (see FIGS. 12(b)-12(d) and Table II). Moreover, manganese (3+) and manganese (+4) oxidation and reduction process shifted to a lower potential region, compared to the 10 wt % ethylene carbonate cyclic voltammogram of FIG. 12(a). The improved performance is believed to be due to the increased ionic conductivity and decreased viscosity of the ionic liquid electrolyte, when the ethylene carbonate concentration is about 20 wt % or more. An ethylene carbonate concentration of about 50 wt % was selected for further evaluation, which substantially supports a large electrochemical voltage window.

### Example 5

### Composite Electrode Containing Lithium Nickel Manganese Oxide and Carbon Nano-Tubes

A first carbon nano-tube composite electrode was prepared by replacing the carbon black in Example 2 with carbon nano-tubes. The carbon nano-tubes where double walled carbon nano-tubes (from NanoLab). The resulting slurry was prepared by mechanical stirring. The slurry was cast and baked to form a first carbon nano-tube composite electrode. The first carbon nano-tube composite electrode was fabricated into a first carbon nano-tube composite test electrochemical device, which was prepared as described in Example 3 and evaluated as described in Example 4. The electrolyte for the first carbon nano-tube electrode comprised 05 M LiPF₆ solution in an [EDMMEA][Tf₂N] with about 50 wt % ethylene carbonate.

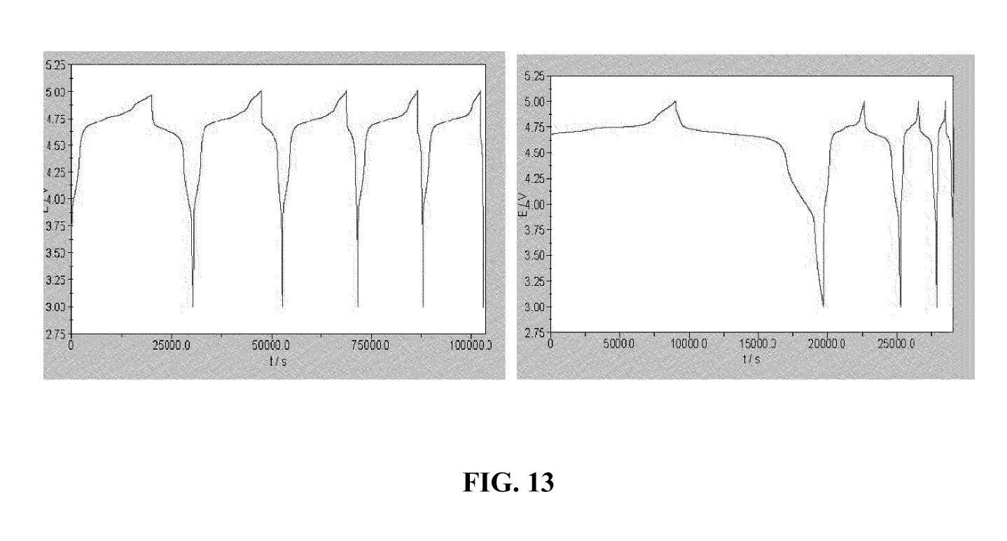

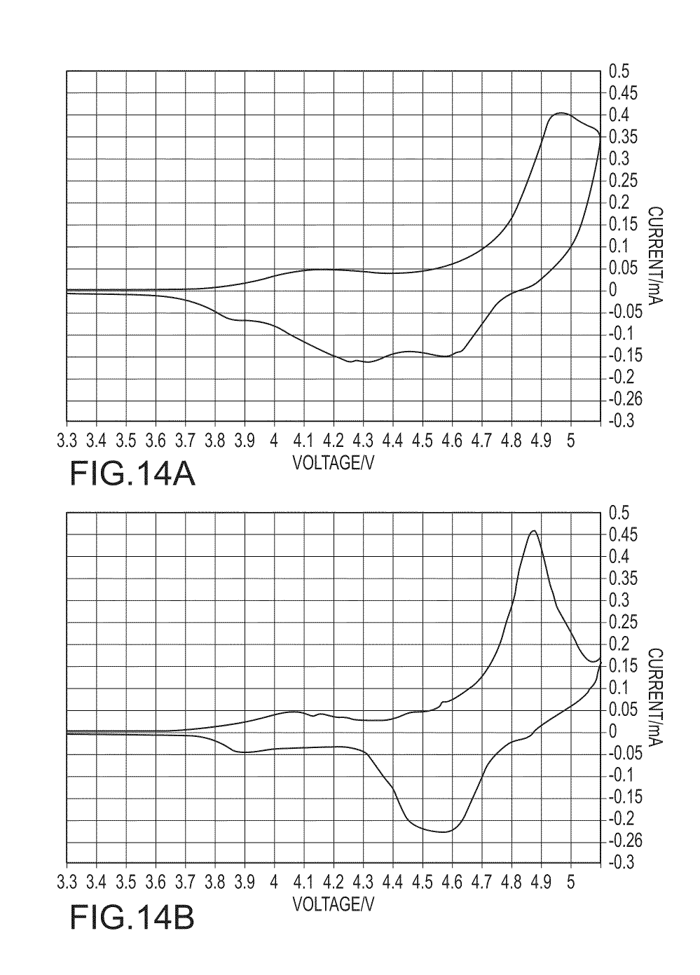

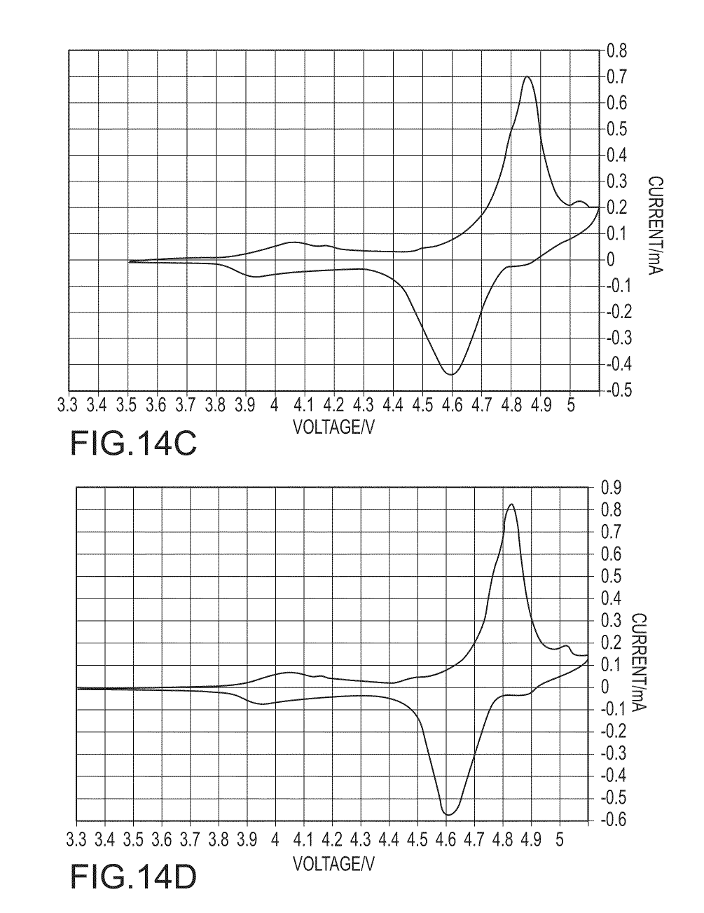

Cyclic voltammograms for the LNMO baseline electrode and the first carbon nano-tube electrode are depicted, respectively, in FIGS. 13(a) and 13(d). Similarly, asymmetric charge/discharge profiles for the LNMO baseline electrode and the first carbon nano-tube composite electrodes are depicted, respectively, in FIGS. 14(a)-14(b) and symmetric charge/discharge profiles are depicted, respectively, in FIGS. 15(a)-15(b).

Referring to FIGS. 13(a) and 13(b), the first carbon nano-tube composite electrode had a smaller reversible nickel oxidation reduction (Ni²⁺/Ni⁴⁺) process and a greater peak separation between the oxidation and reduction cycles than the LNMO baseline electrode, (314 mV vs. 253 mV, Table III). Furthermore, at a small discharge rate of 0.25 C, the first carbon nano-tube composition electrode exhibited a discharge capacity similar to that of the LNMO baseline electrode (113.7 mAh/g for the LNMO baseline electrode versus 105.4 mAh/g for the carbon nano-tube composite electrode, see Table IV). However, when the asymmetric discharge rate was increased to about 4 C, a greater decrease in the discharge capacity retention was exhibited (for example, discharge capacity retention at 4 C: was 28.0% for the LNMO baseline electrode versus 8.1% for the first carbon nano-tube composite electrode, see Table IV). Similarly for the symmetric charge/discharge profile, the first carbon nano-tube composite electrode exhibited a smaller charge capacity retention than did a LNMO baseline electrode. The first carbon nano-tube composite electrode cyclic voltammetry and asymmetric and symmetric charge/discharge profiles indicate that the first carbon nano-tube composite could have better-defined electrochemical behavior, better reversibility, and better rate capability.

TABLE III

| Electrode | Epₒₓ (V) | Ep_{red} (V) | ΔEp (mV) |
|---|---|---|---|
| LNMO/CB/PVdF (80/15/5)** | 4.858 | 4.605 | 253 |
| LNMO/CNT/PVdF (80/15/5)** | 4.876 | 4.562 | 314 |
| LNMO/CNT/PVdF (80/15/5)*** | 4.854 | 4.601 | 253 |
| LNMO/CNT/PVdF/IL | 4.825 | 4.581 | 244 |
| (71.6/13.4/5/10)*** | | | |

**Electrode slurry prepared by mechanical stirring procedure.
***Electrode slurry prepared by sonication procedure.

TABLE IV

| | Discharge | Discharge | Discharge | Discharge | Discharge |
|---|---|---|---|---|---|
| | capacity at | capacity | capacity | capacity | capacity |
| | 0.25C | retention at | retention at | retention at | retention at |
| Electrode | (mAH/g) | 0.5C (%) | 1C (%) | 2C (%) | 4C (%) |
| LNMO/CB/PVdF (80/15/5)* | 113.7 | 101.4 | 96.7 | 85.7 | 28.0 |
| LNMO/CNT/PVdF (80/15/5)* | 105.4 | 98.0 | 91.3 | 30.9 | 8.1 |
| LNMO/CNT/PVdF (80/15/5)** | 96.8 | 103.5 | 102.4 | 95.8 | 53.5 |
| LNMO/CNT/PVdF/IL (71.6/13.4/5/10)** | 108.2 | 101.5 | 102.4 | 101.2 | 95.7 |

*Electrode slurry prepared by mechanical stirring procedure
**Electrode slurry prepared by sonication procedure.

It was believed that the carbon nano-tubes comprising the first carbon nano-tube composite electrode were in a highly bundled form. The highly bundled carbon nano-tubes can be poorly distributed in the first carbon nano-tube composite. That is, the carbon nano-tubes are substantially distributed in a non-homogeneous manner in the first carbon nano-tube composite. The substantially inhomogeneous distribution of the carbon nano-tubes form a substantially non-uniform conductive network in the first carbon nano-tube composite. A substantially inhomogeneous conductive network is less conductive than a substantially homogeneous conductive network. While not wanting to be limited by theory, the carbon nano-tubes are substantially bundled due to van der Waals forces between the carbon nano-tubes.

Several methods for forming a homogenous, carbon nano-tube dispersion in the ionic liquid were evaluated. A method comprising sonicating the carbon nano-tube slurry formed a substantially homogenous dispersion of the carbon nano-tubes. The sonication method was simple and efficient for unbundling the carbon nano-tubes. The substantially homogeneous carbon nano-tubes formed a well-distributed, conductive carbon nano-tube network in the composite.

A method for preparing a composite with lithium nickel manganese oxide and carbon nano-tubes will be described. About 80 grams of lithium nickel manganese oxide nano-particles and 15 grams carbon nano-tubess were added to a solution containing 5 grams PVdF in N-methyl-2-pyrrolidone, the resulting mixture was subjected to sonication for about 90 minutes to form a substantially homogenous slurry. The casting and curing processes described in Examples 3 and 4 were used to form a second carbon nano-tube composite electrode. The sonication process substantially unbundled the entangled carbon nano-tubes. The unbundled carbon nano-tubes and the lithium nickel manganese nano-particles formed a substantially uniform network of carbon nano-tubes (see FIG. 1). Morphologically, in a conventional electrode, aggregated carbon black particles form a poorly distributed inhomogenous network (see FIG. 11) compared to the composite (FIG. 1).

A cyclic voltammogram of the second carbon nano-tube electrode was recorded. The second carbon nano-tube composite electrode had a better-defined cyclic voltammogram (FIG. 13(c) versus 13(b) and 13(a)) and a smaller peak separation (Table III) than the LNMO baseline electrode and the first carbon nano-tube electrode. Furthermore, the asymmetric charge/discharge profiles and symmetric charge/discharge profile showed that the second carbon nano-tube electrode had a significantly improved discharge capacity retention (53.5% vs. 8.1% and 28.0% at 4 C, Table IV and FIGS. 14(a)-14(c)) and charge capacity retention (33.7% vs. 8.4% and 18.1% at 4 C, Table V and FIGS. 15(a)-15(c)) than either the first carbon nano-tube electrode or the LNMO baseline electrode.

TABLE V

| | Charge | Charge | Charge | Charge |
|---|---|---|---|---|
| | capacity at | capacity | capacity | capacity |
| | 0.25C | retention | retention | retention |
| Electrode | (mAH/g) | at 1C (%) | at 2C (%) | at 4C (%) |
| LNMO/CB/PVdF | 135.0 | 73.5 | 54.6 | 18.1 |
| (80/15/5)** | | | | |
| LNMO/CNT/PVdF | 105.1 | 67.0 | 41.2 | 8.4 |
| (80/15/5)** | | | | |
| LNMO/CNT/PVdF | 114.4 | 81.5 | 69.5 | 33.7 |
| (80/15/5)*** | | | | |
| LNMO/CNT/PVdF/IL | 133.4 | 79.4 | 70.3 | 54.6 |
| (71.6/13.4/5/10)*** | | | | |

*Electrode slurry prepared by mechanical stirring procedure
**Electrode slurry prepared by sonication procedure

Furthermore, a third carbon nano-tube electrode was prepared. The third carbon nano-tube composite electrode comprised 71.6 wt % lithium nickel manganese oxide nano-particles, 13.4 wt % the multi-walled carbon nano-tubes and 10 wt % polyvinylidene fluoride. Moreover, the third carbon nano-tube slurry was mixed by sonicartion and fabricated into a third carbon nano-tube composite test electrochemical device as described in Example 3 and evaluated as described in Example 4. The electrolyte for the third carbon nano-tube electrode comprised about 0.5 M LiPF6 in [EDMMEA][Tf₂N] with 50 wt % ethylene carbonate.

The cyclic voltammogram of the third carbon nano-tube composite electrode was well-defined (FIG. 13(d)) and had a small peak separation (Table III). The third carbon nano-tube composite electrode cyclic voltammogram better defined than any one of the first or second carbon nano-tube composite electrodes or the LNMO baseline electrode. Furthermore, the third carbon nano-tube composite electrode had a smaller peak separation than any one of the first or second carbon nano-tube composite electrodes or the LNMO baseline electrode.

Furthermore, the cyclic voltammogram of the third carbon nano-tube electrode had a small shoulder at about 4.7V (versus Li/Li⁺). The small shoulder may be related to the nickel (Ni²⁺/Ni³⁺) oxidation/reduction process. Such a shoulder was observed in the cyclic voltammogram of the LNMO baseline electrode in a conventional non-aqueous electrolyte (see FIG. 10). Moreover, the asymmetric and symmetric charge/discharge profiles exhibited the discharge capacity and charge capacity retentions (for example at 4 C, 95.7%, Table IV and 54.6%, Table V) greater than any on of the LNMO baseline electrode and the first and second carbon nano-tube composite electrodes (Tables IV and V). The third carbon nano-tube composite electrode in the ionic liquid electrolyte had a peak separation of 244 mV, (Table III, discharge capacity retention of 95.7% and a charge capacity retention of 54.6%, (Tables IV and V, respectively). This is in contrast to the LNMO baseline electrode in a conventional non-aqueous electrolyte which had a peak separation of 190 mV, and at 4 C had a discharge capacity retention of 105.0%, a charge capacity retention of 66.3%, Table I.

### Example 6

### Cycle Life Testing of Carbon Nano-Tube Composite and LNMO Baseline Electrodes

The LNMO baseline electrode and the carbon nano-tube composite electrodes were subjected to cycle life performance testing in a conventional electrolyte. The conventional electrolyte comprised 1 M LiPF₆ in a solution having a 50:50 by weight ethylene carbonate and dimethyl carbonate. Each electrode was assembled in a CR2032 coin half-cell with a lithium counter electrode and the conventional electrolytes. The cycle life test comprised charging and discharging the coin half cell at 1 C between 3V and 5V. The discharge capacity retention and cyclic degradation results are depicted in FIG. 16 and Table VI.

TABLE VI

| LNMO/CB | | | | | LNMO/CNT | | | | |
|---|---|---|---|---|---|---|---|---|---|
| | | | | Discharge/ | | | | | Discharge/ |
| | Discharge | Charge | Discharge | Charge | | Discharge | Charge | Discharge | Charge |
| | Capacity: | Capacity: | Capacity | Capacity | | Capacity: | Capacity: | Capacity | Capacity |
| Cycle | 1C | 1C | Retention | Efficiency | Cycle | 1C | 1C | Retention | Efficiency |
| # | (mAH/g) | (mAH/g) | (%) | (%) | # | (mAH/g) | (mAH/g) | (%) | (%) |
| 1 | 96.3928 | 112.829 | 100.0% | 85.4% | 1 | 94.7001 | 130.206 | 100.0% | 72.7% |
| 10 | 94.0275 | 97.5277 | 97.5% | 96.4% | 10 | 95.4758 | 103.191 | 100.8% | 92.5% |
| 20 | 92.3276 | 96.6084 | 95.8% | 95.6% | 20 | 95.527 | 103.446 | 100.9% | 92.3% |
| 30 | 87.6963 | 89.9892 | 91.0% | 97.5% | 30 | 93.2819 | 97.4369 | 98.5% | 95.7% |
| 40 | 85.49 | 87.5116 | 88.7% | 97.7% | 40 | 90.7139 | 93.6303 | 95.8% | 96.9% |
| 50 | 81.7749 | 86.3693 | 87.9% | 98.2% | 50 | 91.0329 | 94.1323 | 96.1% | 96.7% |
| 60 | 84.319 | 86.2419 | 87.5% | 97.8% | 60 | 89.316 | 91.8288 | 94.3% | 97.3% |
| 70 | 83.1824 | 84.6978 | 86.3% | 98.2% | 70 | 89.3384 | 91.9152 | 94.3% | 97.2% |
| 80 | 82.3976 | 83.9906 | 85.5% | 98.1% | 80 | 87.2626 | 89.0751 | 92.1% | 98.0% |
| 90 | 81.0005 | 82.2887 | 84.0% | 98.4% | 90 | 87.6293 | 89.6747 | 92.5% | 97.7% |
| 100 | 79.9112 | 81.1006 | 82.9% | 98.5% | 100 | 85.9569 | 87.1751 | 90.8% | 98.6% |
| 110 | 79.8428 | 81.0615 | 82.8% | 98.5% | 110 | 87.0937 | 89.1068 | 92.0% | 97.7% |
| 119 | 79.9393 | 81.2907 | 82.9% | 98.3% | 119 | 84.4943 | 85.691 | 88.5% | 98.6% |

The degradation rate (slope) of the LNMO baseline electrode trend line 1601 is greater than the carbon nano-tube composite electrode trend line 1602, which is indicative of the carbon nano-tube composite electrode having greater stability cyclic life stability than the LNMO baseline electrode. The discharge capacity retention of the carbon nano-tube composite electrode (88.5%) is greater than the LNMO baseline electrode (82.9%). Both the LNMO baseline and carbon nano-tube composite electrodes have comparable discharge/charge efficiencies through 119 cycles.

While not wanting to be bound by any theory, the greater cycle life of the carbon nano-tube composite electrode compare to the LNMO baseline electrode is believed to be due to the conductive network of carbon nano-tubes in the carbon nano-tube composite electrode.

Furthermore, the conductive network of carbon nano-tubes within the carbon nano-tube composite electrode is believed to be due to a more homogeneous dispersion of the carbon nanto-tubes formed by sonication of the ionic liquid/carbon nano-tube/lithium nickel manganese oxide slurry prior to casting the slurry. The lithium nickel manganese oxide particles tend to break down due to the stress and strain introduced to the lithium nickel manganese oxide particles by charging/discharging cycling. As the lithium nickel manganese oxide particles break down in the LNMO baseline electrode, they lose their intimate contact with the carbon black particles. This loose of intimate contact between the lithium nickel manganese oxide and carbon black creates a resistive gap, that is, a loss of conductivity, between the lithium nickel manganese oxide and carbon black. The carbon nano-tubes can prevent and/or inhibit the formation of a resistive gap between the carbon nano-tubes and the lithium nickel manganese oxide. The carbon nano-tubes are substantially able to maintain in intimate contact with lithium nickel manganese oxide as they break down due to the stress and strains of charging and discharging. The conductive carbon nano-tubes form a network (FIG. 1) carbon nano-tubes about lithium nickel manganese oxide particle surface. The carbon nano-tube network is in intimate, conductive contact with the lithium nickel manganese oxide particles. Furthermore, high aspect ratio (average tube from about 10 to about 20 nm and average tube length from about 1 to about 5 μm) and high tensile strength of the carbon nano-tubes substantially prevent resistive gap formation.

It is believed that the LNMO baseline and carbon nano-tube composite electrodes failed due to dendritic growth at the lithium anode, which shorted the cell. Furthermore, the degradation upon cycling, which is believed to be due to the narrow electrochemical window of the conventional electrolyte used (1M LiPF₆ in ethylene carbonate:dimethyl carbonate). The cycle-life of the carbon nano-tube electrode can be improved by having an ionic liquid the electrolyte and/or the ionic liquid as a component of the carbon nano-composite electrode. For example, having an ionic liquid electrolyte can increase the cycle-life by increasing the electrochemical window. Moreover, including an ionic liquid as a component of the carbon nano-tube composite electrode can increase the conductivity of the carbon nano-tube composite electrode conductive network.

### Example 7

### Cycle-Life Testing of LNMO Baseline Electrode and Carbon Nano-Tube Composite Electrode in an Ionic Liquid Electrolyte

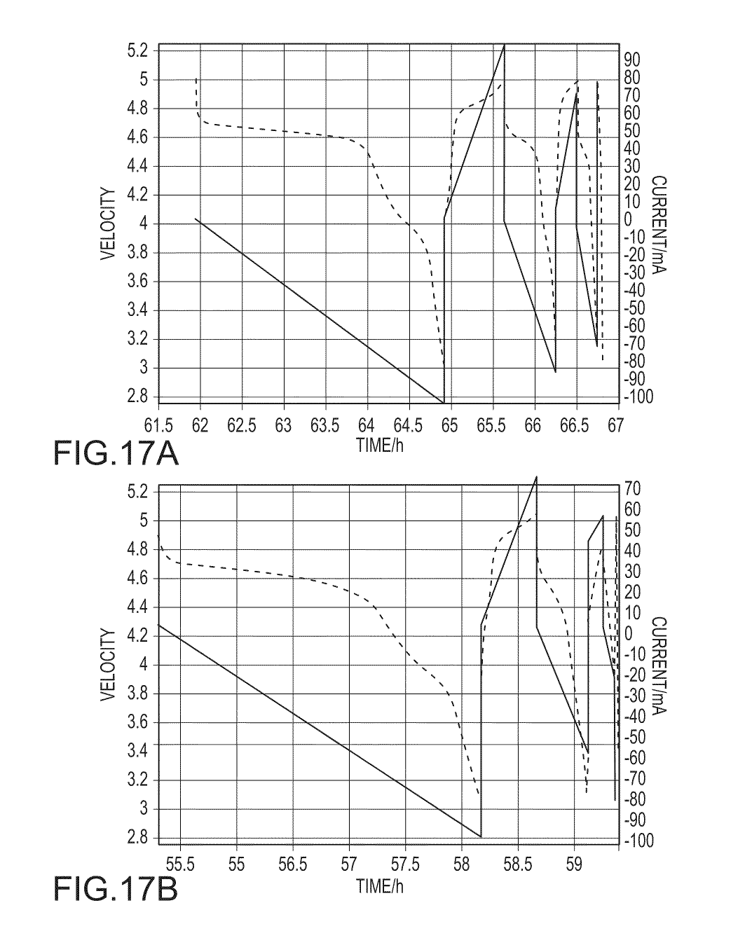

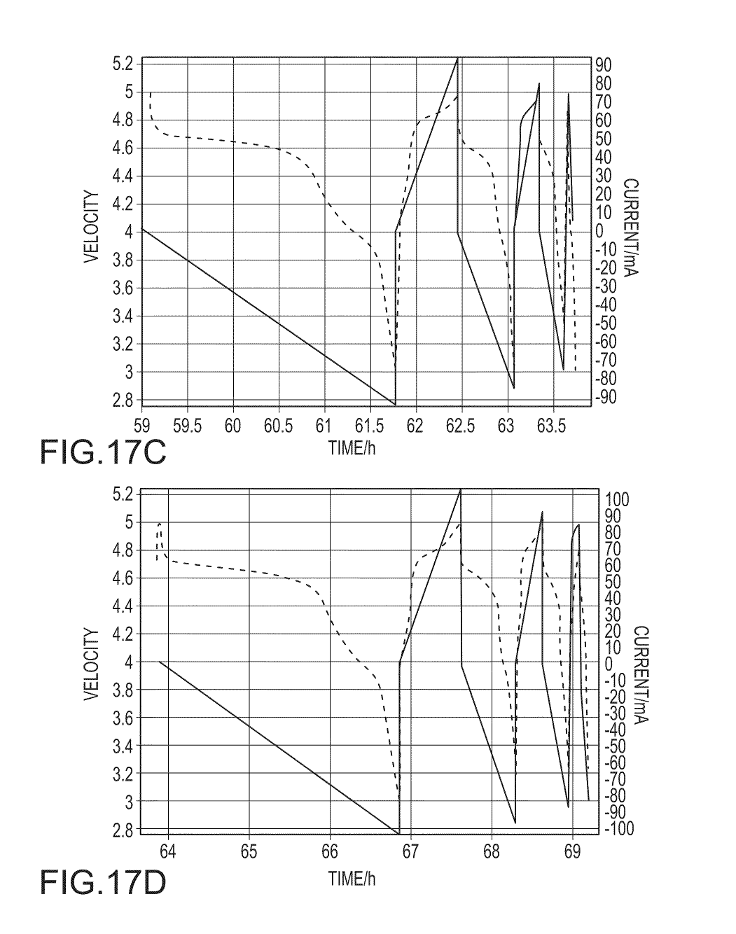

A first ionic liquid-containing carbon nano-tube composite electrode comprising an ionic liquid, lithium nickel manganese oxide and carbon nano-tubes was prepared. The first ionic liquid-containing carbon nano-tube electrode comprised about 76.5 wt % lithium nickel manganese oxide, about 10 wt % EDMMEA ionic liquid, about 9 wt % carbon nano-tubes, and about 4.5 wt % PVdf. FIG. 17 depicts the charge/discharge life cycle testing of the first ionic-liquid carbon nano-tube electrode. The life cycle testing indicated that the first ionic liquid-containing carbon nano-tube electrode was likely damaged by chemical reactions occurring the electrochemical testing. The chemical reactions appeared to cause overcharging of the firs ionic liquid-containing carbon nano-tube electrode.

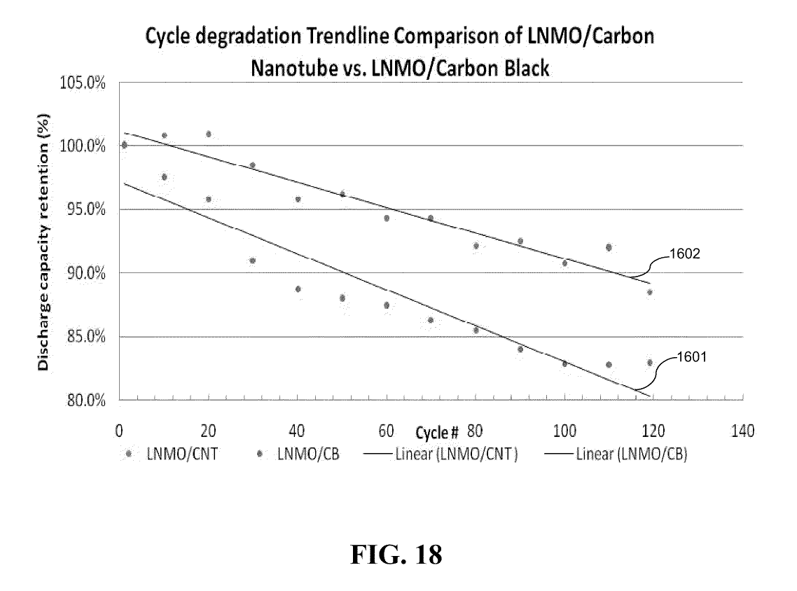

A cyclic voltammogram of the first ionic liquid-containing carbon nano-tube composite electrode in an electrolyte comprising 1M LiPF₆ in a solution having 50% ethylene carbonate in EDMMEA, see FIG. 18(a), showed multiple oxidation and reduction peaks. The multiple oxidation and reduction peaks are indicative of poor electrochemical stability. FIG. 18(b) depicts the cyclic voltammogram of the first ionic liquid-containing carbon nano-tube composite electrode in a substantially neat EDMMEA electrolyte. The cyclic voltammogram (FIG. 18(b)) showed a pair of oxidation and reduction peaks at about 0 Volts, which can be attributed to an electrochemical breakdown of the EDMMEA ionic liquid. The electrochemical activity at voltages of about 1 V or greater in FIG. 18(a) are attributed to the LiPF₆ and/or ethylene carbonate.

A cyclic voltammogram of the first ionic liquid-containing carbon nano-tube composite electrode in an electrolyte comprising 1 M lithium bis(trifluoromethane sulfone) imide, Li⁺[(CF₃S(═O)₂)₂N]⁻, in EDMMEA showed a fairly clean cyclic voltammogram substantially devoid of electrode and/or electrolyte oxidation and reduction peaks, see FIG. 18(c). The substantial lack of electrode and/or electrolyte oxidation and reduction peaks in the cyclic voltammogram depicted in FIG. 18(c) was indicative of electrochemical instability of one or both of the LiPF₆ and ethylene carbonate in the 1M LiPF₆ in 50% ethylene carbonate in the EDMMEA electrolyte.

Furthermore, addition of about 20 wt % ethylene carbonate to the 1 M lithium bis(trifluoromethane sulfone) imide EDMMEA electrolyte gave rise to an oxidation peak in the cyclic voltammogram at about 3.65 Volts, see FIG. 18(d). It is believed that the oxidation peak at about 3.65 Volts is associated with the ethylene carbonate. More specifically, the peak at 3.65 Volts is associated with the oxidation of ethylene carbonate or an electro-active component contained in the ethylene carbonate.

It is believed that ionic liquid electrolytes comprising lithium bis(trifluoromethane sulfone) imide can be more electrochemically stable than ionic liquid electrolytes containing LiPF₆. Furthermore, it is believed that ionic liquids containing EDMMEA can be more electrochemically stable than other non-ionic liquid electrolytes. Moreover, it is believed that replacing the ethylene carbonate contained in the ion liquid electrolyte with one or more of chloroethylene carbonate and vinylethylene carbonate could improve the electrochemical stability of the ionic liquid electrolyte.

### Example 8

### High-Rate Cycle-Life Testing of Carbon Nano-Tube Composite Electrode in a Conventional Electrolyte

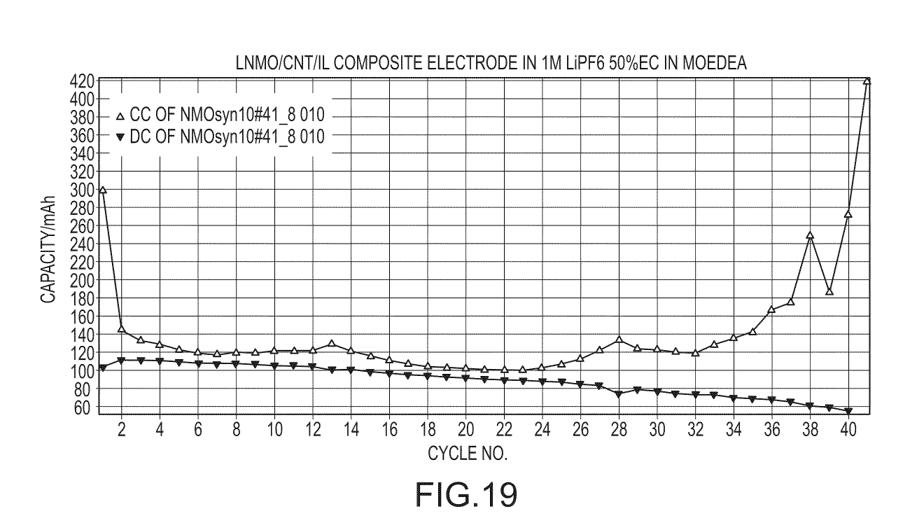

FIG. 19 depicts a stability test comprising about 1,000 rapid charge/discharge cycles for a lithium nickel manganese oxide carbon nano-tube composite electrode half-cell in an electrolyte comprising 1M LiPF₆ in a 1:1 solution of ethylene and dimethyl carbonates. Initially, two charge discharge cycles were performed at a 0.25 C rate based on a capacity of 150 mAh/g, followed by continuous cycling at 8 C (7.5 min charge/discharge). Following these two charge discharge cycles, the voltage window was from about 3.0 to about 5.0 Volts, this voltage range corresponds to a discharge depth of about 100%. At the 0.25 C charge/discharge rate, the lithium nickel manganese carbon nano-tube composite electrode half-cell delivered about 551 Wh/kg. This corresponds to approximately 185 Wh/kg for a packaged cell assuming a packaging efficiency of 47%. The energy had a modest drop when the charge/discharge rate is increased to 8 C. The energy delivered by the lithium nickel manganese carbon nano-tube composite electrode half-cell was about 123 Wh/kg. Furthermore, over the 1,000 cycles the lithium nickel manganese carbon nano-tube composite electrode half-cell had about 85% specific energy retention. Moreover, the specific energy retention will increase with lowering of the cycling rate and/or with increasing the electrochemical stability of the electrolyte. Furthermore, electrolyte additives and scavenging additives can be used to remove water contained in the ionic liquid electrolyte. The electrolyte additive and/or scavenger can prevent HF buildup in the cell.

### Example 9

### Synthesis of Ionic Liquid Gel Polymer Electrolyte

Various ionic liquid gel polymer electrolytes were prepared. One ionic liquid gel polymer electrolyte was prepared by combining 10% poly vinylidene fluoride-co-hexafluoropropylene (PVdF-HFP) in N-methyl-2-pyrrolidone solution, with [EDMMEA][Tf₂N], an ionic liquid, at a mass ratio of 1:2.5, respectively to form a solution. After mixing the solution for several hours, the solution was transferred onto a glass substrate by pipetting to form a solution film on the substrate. The solution film was heated for about 15 hours under a vacuum to a temperature of about 110 degrees Celsius to form an ionic liquid gel polymer electrolyte film. The ionic liquid gel polymer electrolyte film had a thickness of about 106 μm, a conductivity of about 3 mS/cm, and an electrochemical stability window greater than about 4V.

Other ionic liquid gel polymer electrolytes were prepared. Some of the other gel polymer electrolytes included one or both of ethylene carbonate and a lithium-containing salt. Non-limiting examples of lithium-containing salts are lithium bis(trifluoromethanesulfonyl)imide and lithium hexafluorophosphate (LiPF₆). Ethylene carbonate is believed to aid in the formation of a solid electrolyte interphase layer. Furthermore, it is believed that having lithium ions, as a lithium-containing salt, in the gel polymer improves cell conductivity and functionality of gel polymer electrolyte and cells containing the same. Ionic liquid gel polymer electrolytes containing lithium bis(trifluoromethanesulfonyl)imide generally preformed better than those containing lithium hexafluorophosphate.

Some gel polymer electrolytes included replacing the [EDMMEA][Tf₂N] ionic liquid with 1-ethyl-3-methylimidazolium bis(trifluoromethylsulfonyl)imide (EMIIM). The liquid gel polymer electrolyte was prepared by combining 10% poly vinylidene fluoride-co-hexafluoropropylene (PVdF-HFP) in N-methyl-2-pyrrolidone (NMP) solution, with EMIIM at a mass ratio of 1:2.5, respectively to form a solution. After mixing the solution for several hours, the solution was transferred to a glass substrate by pipetting to form a solution film on the substrate. It was found that the viscosity of the gel solution was lowered, compared to the [EDMMEA][Tf₂N] solution prior to gel formation, by replacing the [EDMMEA][Tf₂N] with 1-ethyl-3-methylimidazolium bis(trifluoromethylsulfonyl)imide. Some of the solution was transferred under an argon atmosphere to the glass substrate by pipetting to form a solution film on the glass substrate. The argon atmosphere was removed and the solution film was maintained under a vacuum for about 15 hours at ambient temperature. The solution film remained substantially in a liquid state during the 15 hour period, however, the viscosity of the solution film increased. After the 15 hour period, the solution film was heated to a temperature of about 50 degrees Celsius to form the ionic liquid gel polymer electrolyte.

Some of the ionic liquid gel polymer electrolytes were prepare with N-methyl-2-pyrrolidone, while others were prepared by replacing the N-methyl-2-pyrrolidone with tetrahydrofuran or acetone. Specifically, the vapor pressure of NMP was found to be too low for a synthesis process that included a reduced pressure. Therefore, alternative higher vapor pressure solvents tetrahydrofuran (THF) and acetone were explored. A THF/PVdF-HFP mixture polymerized too quickly. An acetone/PVdF-HFP mixture did not polymerize as quickly as the tetrahydrofuran solution.

The acetone/PVdF-HFP mixture remained in a liquid state for several days without a noticeable increase in viscosity. Moreover, the ionic liquid and ethylene carbonate were miscible with the acetone/PVdF-HFP mixture. Furthermore, the acetone evaporated quickly, typically within two minutes, in the dry argon environment leaving behind a film. The film was transparent and had substantially suitable mechanical properties.

### Example 10

### Testing of Ionic Liquid Gel Polymer Electrolyte

The ionic liquid gel polymer electrolytes prepared in Example 9 were evaluated by electrochemical impedance spectroscopy. Ionic conductivities of the ionic liquid gel polymer electrolytes were determined using the following formula:

σ=t/(SZ′) (1)

where t and S are the thickness and area of the electrolyte between the two electrodes, Z′ is the real resistance at the imagery resistance, Z″, value of zero, and σ is the ionic conductivity. The electrochemical impedances were conducted over a frequency range from about 1 MHz to about 1 Hz with an amplitude of about 5 mVolts about a mean voltage of about 0 Volts. The ionic conductivities are summarized Table VII.

TABLE VII

| | Relative |
|---|---|
| | conductivity* |
| Electrolyte | (mS/CM) |
| EMIIM/EC/PVdF-HFP/LiPF₆ | 2.5 |
| NMP solvent (ILGPE) | |
| EMIIM/EC/PVdF-HFP/LiTFSI THF | 9.3 |
| solvent (ILGPE) | |
| First EMIIM/EC/PVdF-HFP/LiTFSI | 13 |
| acetone solvent (ILGPE) | |
| Second EMIIM/EC/PVdF-HFP/LiTFSI | 9.2 |
| acetone solvent (ILGPE) | |

*First testing apparatus used had non-negligible resistance in the open state, so these values should only be compared qualitatively

The electrochemical impedance test was modified to substantially eliminate cell interference) and the ionic liquid gel polymer electrolytes were re-evaluated. Moreover, baseline samples and preferred ionic liquid gel polymer electrolytes were included in the evaluations. The preferred ionic liquid gel polymer electrolytes contained 0.2 ml of electrolyte solution added to 2.2 ml of PVdF-HFP dissolved in anhydrous acetone with or without 2% by mass of a zeolite. The zeolite is believed to increase ionic liquid retention in the polymer. The electrolyte solution contained 1M LiTFSI in a 1:1 (wt) mixture of ethylene carbonate and either EMIIM IL or dimethyl carbonate. The ionic conductivities determined by the modified electrochemical impedance procedure are summarized Table VIII.

TABLE VIII

| | Conductivity |
|---|---|
| Electrolyte | (mS/CM) |
| Conventional (EC:DMC 1:1 with | 11.8 |
| 1M LiPF₆ (Liquid) | |
| EMIIM (Liquid) | 7.4 |
| EMIIM/EC/PVdF-HFP/LiPF₆ NMP | 0.6 |
| solvent (ILGPE) | |
| DMC/EC/PVdF-HFP/LiTFSI | 1.88 |
| acetone solvent (GPE) | |
| EMIIM/EC/PVdF-HFP/LiTFSI | 3.35 |
| acetone solvent (ILGPE) | |
| EMIIM/EC/PVdF-HFP/LiTFSI | 2.78 |
| acetone solvent (ILGPE, zeolite added) | |

The ionic liquid gel polymer electrolyte conductivities are about half that of the ionic liquid alone. The ionic conductivities of about 3.35 mS/cm or greater should be sufficient for moderate charge/discharge rates. Furthermore, the ionic liquid gel polymer electrolytes had ionic conductivities about 75% greater than that attained using an ethylene carbonate/dimethyl carbonate-based solution. The addition of zeolite caused a moderate drop in conductivity.

### Example 11

### Coin Cell Testing

The ionic liquid gel polymer electrolytes were tested in CR 2032 coin cell format using a lithium metal anode and V₂O₅ composite cathode. The CR2032 coin cells were assembled without an initial soaking of the electrodes in a liquid electrolyte as is often done in lab-scale testing. Pre-soaking allows the porous electrode to soak-up liquid electrolyte, the soak-up of electrolyte could reduce contact resistance at the electrode/electrolyte interface. Furthermore, pre-soaking is unsuitable in a manufacturing process.

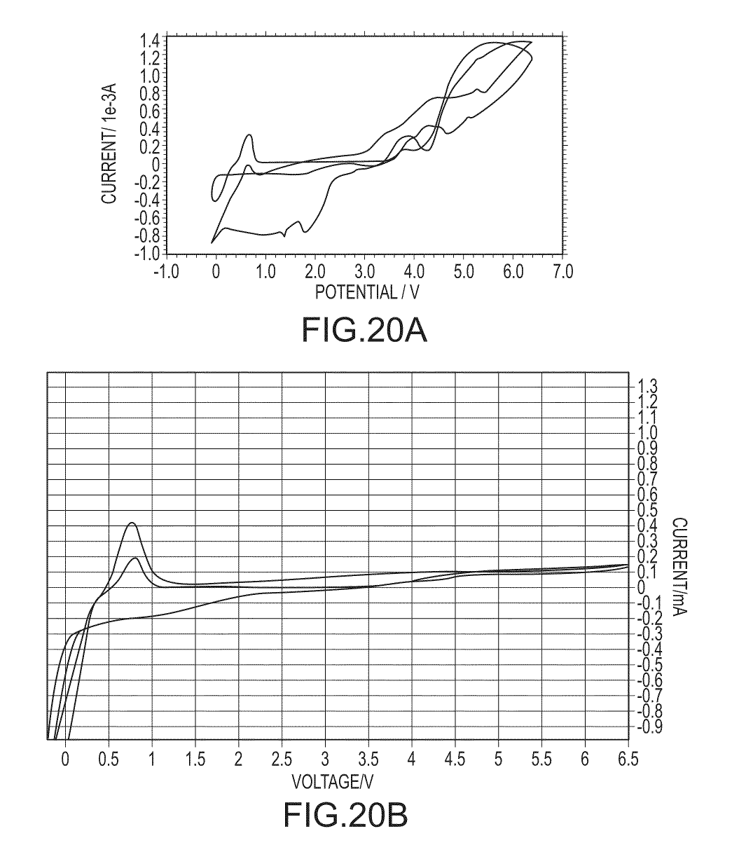

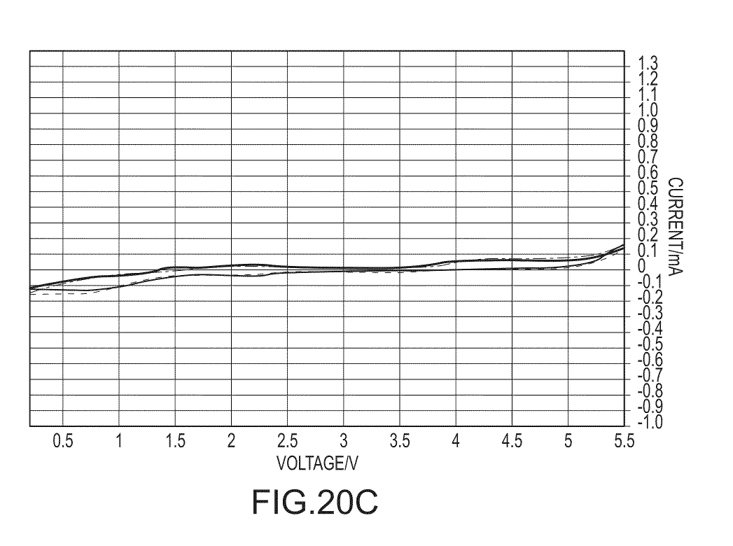

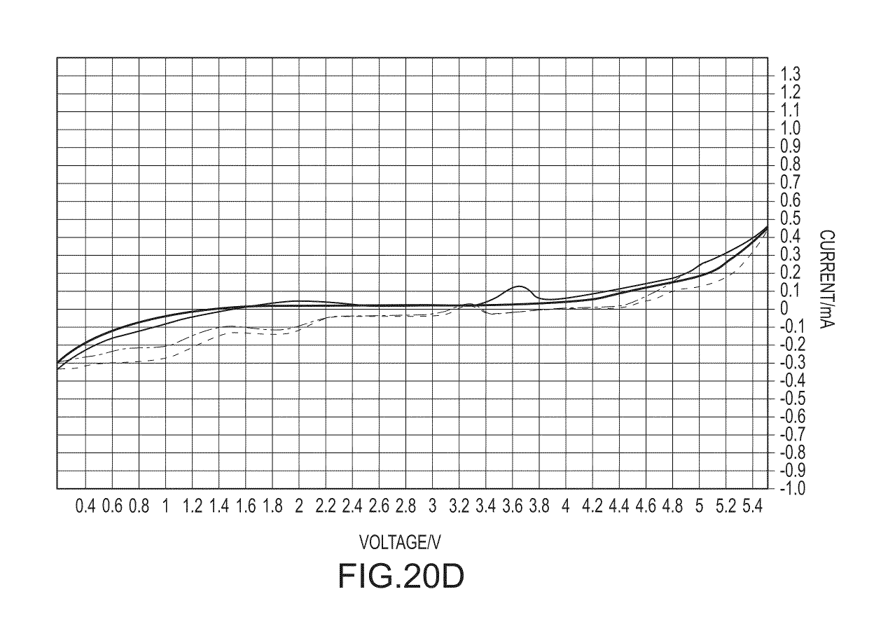

Cyclic voltammetry was used to determine the electrochemical behavior of the V₂O₅ composite cathode in the ionic liquid gel polymer electrolyte (see FIG. 20). The CR2032 coin cell was scanned at a scan rate of about 0.1 mV/s from about 1.5 Volts to about 4.0 Volts. The cyclic voltammogram had substantially well-defined reduction peaks at about 2.8 Volts and 2.5 Volts. The electrochemical reaction was reversible. Furthermore, oxidation and reduction peaks had a peak separation of about 0.2 Volts. Moreover, the cyclic voltammogram had a large background current. A pseudo-capacitive behavior was evident throughout the cyclic voltammogram.

The electrochemical cyclic ability of the V205 composite cathode in the ionic liquid gel polymer electrolyte is substantially aided by the ionic liquid electrolyte and ionic liquid gel polymer electrolyte. Furthermore, coulombic efficiency is aided by the ionic liquid electrolyte and ionic liquid gel polymer electrolyte. The coulombic efficiency is a measure of irreversible lithium cation consummation at the anode. A coulombic efficiency less than about 100% typically means Li⁺ ions are being irreversibly consumed at the anode through the formation of one or more passivation layers. While, a coulombic greater than about 100% typically signifies side reactions and/or irreversible intercalation of Li⁺ ions. Table IX summarizes capacities and coulombic

TABLE IX

| | 1^{st} Cycle | 1^{st} Cycle | 10^{th} Cycle | 10^{th} Cycle |
|---|---|---|---|---|
| | Capacity | Effi- | Capacity | Effi- |
| Electrolyte | mAh/g | ciency | mAh/g | ciency |
| Conventional (EC:DMC | 458 | 232% | 108 | 99.4% |
| 1:1 with 1M LiPF₆) (liquid) | | | | |
| EMIIM/EC/LiTFSI (liquid) | 159 | 89.50% | 137 | 95.0% |
| EMIIM/EC/PVdF-HFP/ | 157 | 79.90% | 131 | 96.1% |
| LiTFSI acetone solvent | | | | |
| (ILGPE) | | | | |
| Optimized EMIIM/EC/ | 161 | 98.80% | 148 | 98.5% |
| PVdF-HFP/LiTFSI | | | | |
| acetone solvent (ILGPE) | | | | |

efficiecies various electrolytes. The conventional 1M LiPF₆ in ethylene carbonate/dimethyl carbonate electrolyte had a first discharge capacity of over 450 mAh/g, which was more than twice the capacity of the first charge. The difference between the discharge and charge capacities is believed to be due to irreversible non-Faradic processes at the V₂O₅ surface (the V₂O₅ is present in a gel format). The greater than 100% coulombic efficiency continues after the first cycle for several more cycles. Due to the non-Faradic processes and greater than 100% coulombic efficiencies for the first cycle of the conventional electrolyte, the ‘initial’ capacity reported for this system is the second cycle, since the first cycle capacity fails to give a true indication of performance in subsequent cycles. On the other hand, the coulombic efficiency for the cell having the EMIIM/ethylene carbonate/PVdf-HFP/LiTFSI electrolyte had a 20% irreversible capacity loss on the first cycle. This loss of capacity indicated possible reactions at the lithium anode. However, the cell having the enhanced ionic liquid gel polymer electrode had about a 98.8% efficiency through the first ten cycles. Furthermore, the cell having the enhanced ionic liquid gel polymer electrolyte delivered the highest capacity retention.

### Example 12

### V₂O₅ Nano-Composite Cathode

Nano-scale V₂O₅ was prepared by dissolving V₂O₅ in an aqueous solution of oxalic acid to form a vanadium solution. The vanadium solution evaporated to dryness to form a blue solid (vanadyl oxalate hydrate). The vanadyl oxalate hydrate solid was calcined for about 2 hours at about 400 degrees Celsius to produce a nano-scale V₂O₅ powder. The V₂O₅ nano-scale powder was blended with conductive carbon black to evaluate the ionic liquid gel polymer electrolytes.

### Example 13

### V₂O₅ Laboratory Test Cells

Electrochemical performance testing was conducted with CR3220 half-cells having a V₂O₅ cathode, a lithium metal anode and an electrolyte. Fig. RR depicts 0.1 C discharge capacity of two conventional electrolyte (1M LiPF₆ in ethylene carbonate:dimethyl carbonate solution) cells and two ionic liquid-based electrolyte (1M TFSI EMIIM:EC) cells on the first and fifth discharge cycles.

The cells containing the ionic liquid-based electrolyte follow substantially the same voltage profile on all of the first and fifth cycles. However, the conventional electrolyte cells had varying degrees of irreversible capacity on the first cycle. The irreversible capacity of the conventional electrolyte cells is believed to be due to electrolyte and/or Li⁺ reactions. The ionic liquid-containing cells exhibited little, if any, irreversible capacity. The substantially irreversible capacity of the ionic liquid-containing cells indicates the substantially stability and compatibility of the ionic liquid in the electrochemical V₂O₅ electrochemical system. Furthermore, the ionic liquid-containing V₂O₅ cells exceed the discharge capacity of analogous V₂O₅ cells having conventional electrolytes cells after five cycles.

The V₂O₅ electrode was discharged to about 1V, due to conductivity limitations of the electrodes, to reach the discharge capacity of about 440 mAh/g. The V₂O₅ nanoparticles when mixed with conventional conductive additive reached its theoretical discharge capacity when discharged to about 1.5V. Furthermore, the V₂O₅ nanoparticles when mixed with conventional conductive additive reached over 260 mAh/g reversibly when discharged to about 2.0V.

The cycling was lower to rate of about 0.1 C. The performance results surpassed 400 mAh/g on the first cycle, declined to about 360 mAh/g after the second cycle, and then gradually decided (after about 40 cycles) to 250 mAh/g, the 250 mAh/g capacity was maintained through 75 cycles.

### Example 14

### Graphite Carbon Nano-Tube Composite

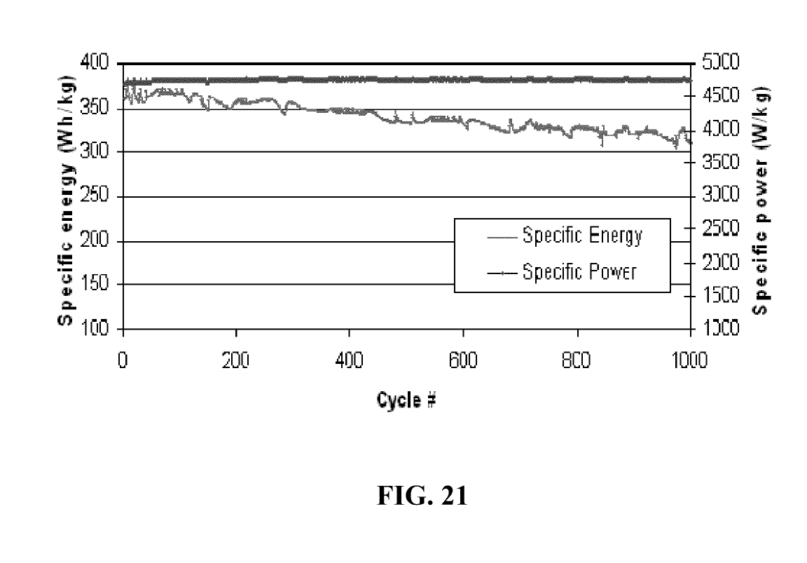

A graphite carbon nano-tube composite electrode was prepared in manner similar to Examples 2 and 3; however, the lithium nickel manages oxide was with a high-performance synthetic graphite (Timrex SLP6). The high performance graphite has a shape resembling a potato. The graphite carbon nano-tube composite comprised about 90 wt % Timrex SLP 6, about 5 wt % carbon nano-tubes and about 5 wt % polyvinylidene fluoride. Furthermore, a carbon black composite electrode was prepared as a reference, the carbon black composite electrode comprised about 90 wt % Timrex SLP 6, about 5 wt % carbon black and about 5 wt % polyvinylidene fluoride. The discharge capacities of the graphite carbon nano-tube and carbon black composite electrodes were determined (see FIG. 13 of Long-Life report). The graphite carbon nano-tube composite electrode has a substantially study discharge capacity over 410 mAh/g and about three times greater discharge capacity than the carbon black composite electrode at about a 25 C rate. Moreover, the graphite carbon nano-tube composite electrode maintained, at a discharge rate of about 95 C, a high discharge capacity greater than about 100 mAh/g. The graphite carbon nano-tube composite electrode exhibited a long cycle life when cycled with a 0.25 C charge rate and a 10 C discharge rate (see FIG. 14 of Long-Life report). The discharge capacity substantially steadies after about 20 cycles. After steadying, the graphite carbon nano-tube composite electrode exhibited no detectable fading through the next 20 cycles (see FIG. 21).

Furthermore, the graphite carbon nano-tube composite electrode is substantially compatible with ionic liquid based electrolyte [EDMMEA][Tf₂N]. A graphite carbon nano-tube composite electrode ion liquid electrolyte [EDMMEA][Tf₂N] half-cell had a substantially steady discharge capacity in a cycling discharge rate test (see FIG. 22).

A number of variations and modifications of the disclosure can be used. It would be possible to provide for some features of the disclosure without providing others.

The present disclosure, in various aspects, embodiments, and configurations, includes components, methods, processes, systems and/or apparatus substantially as depicted and described herein, including various aspects, embodiments, configurations, subcombinations, and subsets thereof. Those of skill in the art will understand how to make and use the various aspects, aspects, embodiments, and configurations, after understanding the present disclosure. The present disclosure, in various aspects, embodiments, and configurations, includes providing devices and processes in the absence of items not depicted and/or described herein or in various aspects, embodiments, and configurations hereof, including in the absence of such items as may have been used in previous devices or processes, e.g., for improving performance, achieving ease and\or reducing cost of implementation.

The foregoing discussion of the disclosure has been presented for purposes of illustration and description. The foregoing is not intended to limit the disclosure to the form or forms disclosed herein. In the foregoing Detailed Description for example, various features of the disclosure are grouped together in one or more, aspects, embodiments, and configurations for the purpose of streamlining the disclosure. The features of the aspects, embodiments, and configurations of the disclosure may be combined in alternate aspects, embodiments, and configurations other than those discussed above. This method of disclosure is not to be interpreted as reflecting an intention that the claimed disclosure requires more features than are expressly recited in each claim. Rather, as the following claims reflect, inventive aspects lie in less than all features of a single foregoing disclosed aspects, embodiments, and configurations. Thus, the following claims are hereby incorporated into this Detailed Description, with each claim standing on its own as a separate preferred embodiment of the disclosure.

Moreover, though the description of the disclosure has included description of one or more aspects, embodiments, or configurations and certain variations and modifications, other variations, combinations, and modifications are within the scope of the disclosure, e.g., as may be within the skill and knowledge of those in the art, after understanding the present disclosure. It is intended to obtain rights which include alternative aspects, embodiments, and configurations to the extent permitted, including alternate, interchangeable and/or equivalent structures, functions, ranges or steps to those claimed, whether or not such alternate, interchangeable and/or equivalent structures, functions, ranges or steps are disclosed herein, and without intending to publicly dedicate any patentable subject matter.

What is claimed is:

1. A composition, comprising:
a polymeric material containing a plurality of active material particles; and
a plurality of graphene material particles, wherein the plurality of graphene material particles form a graphene network, wherein the graphene network one or both of interconnects and coats at least some, if not most, of the plurality of active material particles, wherein at least some of the graphene material particles forming the graphene network were one or both of untangled and un-aggregated by at least one of an ionic liquid or ultrasonic energy.

2. The composition of claim 1, wherein the active material is an electro-active material.

3. The composition of claim 1, wherein the active material substantially reversibly intercalates one of lithium, sodium or potassium.

4. The composition of claim 1, wherein the active material comprises one or more of an ordered olivine composition, a rhombohedral super-ionic conductor, an oxide, a nitride, a phosphide, a hydride, a spinel, and a substituted spinel.

5. The composition of claim 1, wherein the active material is selected from the group of materials consisting essentially of MPO₄, YMPO₄, MPO₄F_{q}, YMPO₄F_{q}, M₂(XO₄)ᵣ, YM₂(XO₄)ᵣ, M₂(XO₄)ᵣF_{q}, YM₂(XO₄)ᵣF_{q}, MO_{z}, YMO_{z}, MO_{z}F_{q}, YMO_{z}F_{q}, MNⱼ, YMNⱼ, MPⱼ, YMPⱼ, MHₜ, YMHₜ and combinations thereof and where 0<q≦6, where 0<r≦3, where 0<z≦12, where 0<j≦4, where 1<t≦6, where Y is selected from the group consisting of Li, Na, K, Rb, Cs, Be, Mg, Ca, Sr, Ba, Ra, Fr and combinations thereof, and where M is selected from the group consisting of Sc, Ti, B, Cr, Mn, Fe, Co, Ni, Cu, Zn, Y, Sr, Nb, Mo, Tc, Ru, Rh, Pd, Ag, Cd, La, Ce, Pr, Nd, Sm, Eu, Gd, Tb, Dy, Ho, Er, Tm, Yb, Lu, Hf, Ta, W, Re, Os, Ir, Pt, Au, Hg, B, Al, Ga, In, Tl, Si, Ge, Sn, Pb, and combinations thereof, and where X is selected from the group consisting of B, Al, Ga, In, Tl, Si, Ge, Sn, Pb and combinations thereof.

6. The composition of claim 1, wherein the active material is selected from the group consisting essentially of LiFePO₄, LiMnPO₄, LiCoPO₄, LiNiPO₄, LiCoO₂, LiNi_{0.5}Mn1.5O₄, V₂O₅, LiCo_{1/3}Ni_{1/3}O₂, Li(Li₀₋₁Ni₀₋₁Mn₀₋₁Co₀₋₁)O₂, LiMn₂O₄, MnO₂, LiNiO₂, LiMn₂₋ᵣNiᵣO₄, LiMn₂₋ᵣFeᵣO₄, and combinations thereof.

7. The composition of claim 1, wherein the ionic liquid comprises:
(A) at least one cation selected from the group of cations consisting of the following compounds and mixtures thereof: 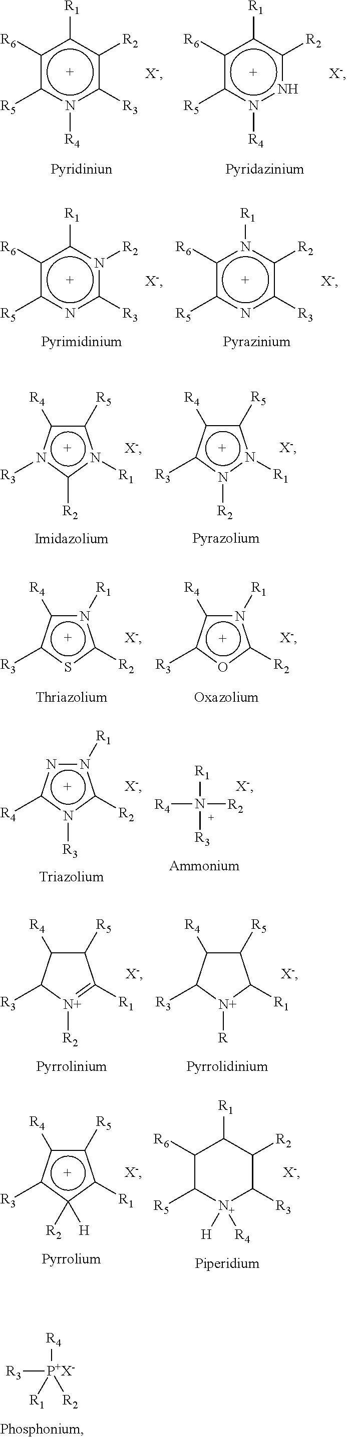
wherein R₁, R₂, R₃, R₄, R₅, and R₆ of the cationic components are identical or different and are selected from the group consisting of:
(i) a hydrogen;
(ii) a halogen;
(iii) a hydroxyl;
(iv) an amine;
(v) a thiol;
(vi) a C₁ to C₂₅ straight-chain, branched aliphatic hydrocarbon radical;
(vii) a C₅ to C₃₀ cycloaliphatic hydrocarbon radical;
(viii) a C₆ to C₃₀ aromatic hydrocarbon radical;
(ix) a C₇ to C₄₀ alkylaryl radical;
(x) a C₂ to C₂₅ linear or branched aliphatic hydrocarbon radical having interruption by one or more heteroatoms, such as, oxygen, nitrogen or sulfur;
(xi) a C₂ to C₂₅ linear or branched aliphatic hydrocarbon radical having interruption by one or more functionalities selected from the group of hydrocarbon radials consisting of:
(a′) a carbonyl;
(b′) an ester;
(c′) an amide, where R′ selected from the group consisting of hydrogen, C₁-C₁₂ straight-chain, branched or cyclic alkane or alkene;
(d′) a sulfonate;
(e′) a sulfonamide, where R′ selected from the group consisting of hydrogen, C₁-C₁₂ straight-chain, branched or cyclic alkane or alkene;
(xii) a C₂ to C₂₅ linear or branced aliphatic hydrocarbon radical terminally functionalized by Cl, Br, F, I, NH, OH, NH₂, NHCH₃ or SH;
(xiii) a C₅ to C₃₀ cycloaliphatic hydrocarbon radical having at least one heteroatom selected from the group of heteroatoms consisting of O, N, S, and optionally substituted with at least one of the following Cl, Br, F, I, NH, OH, NH₂, NHCH₃ or SH;
(xiv) a C₇ to C₄₀ alkylaryl radical heteroatom selected from the group of heteroatoms consisting of O, N, S, and optionally substituted with at least one of the following:
(a″) a C₂ to C₂₅ straight-chain, branched hydrocarbon radical substituted with at least one of the following Cl, Br, F, I, NH, OH, NH₂, NHCH₃ or SH;
(b″) a C₅ to C₃₀ cycloaliphatic hydrocarbon radical substituted with at least one of the following Cl, Br, F, I, NH, OH, NH₂, NHCH₃ or SH
(c″) a hydroxyl;
(d″) an amine;
(e″) a thiol;
(xv) a polyether of the type —O—(—R₇—O—)ₙ—R₈ or block or random type —O—(—R₇—O—)ₙ—(—R_{7′}—O—)ₘ—R₈, wherein at least of the following is true:
(a′″) R₇ is a linear or branched hydrocarbon radical having from 2 to 4 carbon atoms;
(b′″) R_{7′} is a linear or branched hydrocarbon radical having from 2 to 4 carbon atoms; and
(c′″) wherein n is from 1 to 40; and
(d′″) R₈ is hydrogen, or a C₅ to C₃₀ straight-chain or branched hydrocarbon radical, or a C₅ to C₃₀cycloaliphatic hydrocarbon radical, or a C₆ to C₃₀ aromatic hydrocarbon radical, or a C₇ to C₄₀ alkylaryl radical; and
(xvi) a polyether of the type —O—(—R₇—O—)ₙ—C(O)—R₈ or block or random type —O—(—R₇—O—)ₙ—(—R_{7′}—O—)ₘ—C(O)—R₈, wherein at least of the following is true:
(a″″) R₇ is a linear or branched hydrocarbon radical having from 2 to 4 carbon atoms;
(b″″) R_{7′} is a linear or branched hydrocarbon radical having from 2 to 4 carbon atoms; and
(c″″) wherein n is from 1 to 40; and
(d″″) R₈ is hydrogen, or a C₅ to C₃₀ straight-chain or branched hydrocarbon radical, or a C₅ to C₃₀cycloaliphatic hydrocarbon radical, or a C₆ to C₃₀ aromatic hydrocarbon radical, or a C₇ to C₄₀ alkylaryl radical; and
(B) at least one anion selected from the group of anions consisting of F⁻; Cl⁻, Br⁻; I⁻; NO₃⁻; N(CN)₂⁻; BF₄⁻; ClO₄⁻; PF₆⁻; RSO₃⁻; RCOO⁻; where R is an alkyl group, substituted alkyl group, or phenyl group; (CF₃)₂PF₄⁻, (CF₃)₃PF₃⁻, (CF₃)₄PF₂⁻, (CF₃)₅PF⁻, (CF₃)₆P⁻, (CF₂SO₃⁻)₂, (CF₂CF₂SO₃⁻)₂, (CF₃SO₂⁻)₂N⁻, CF₃CF₂(CF₃)₂CO⁻, (CF₃SO₂⁻)₂CH⁻, (SF₅)₃C⁻, (CF₃SO₂)₃C⁻, [O(CF₃)₂C₂(CF₃)₂O]₂PO⁻, (CF₃(CF₂)₇ SO₃⁻, and mixtures thereof.

8. The composition of claim 1, wherein the ionic liquid comprises one of an EDMMEA, EMIIM or mixture thereof.

9. The composition of claim 1, wherein the polymer binder comprises a polymer selected from the group of polymers consisting of homopolymers and copolymers of polyolefins, polystyrenes, polyvinyls, polyacrylics, polyhalo-olefins, polydienes, polyoxides/esthers/acetals, polysulfides, polyesters/thioesters, polyamides/thioamides, polyurethanes/thiourethanes, polyureas/thioureas, polyimides/thioimides, polyanhydrides/thianhydrides, polycarbonates/thiocarbonates, polyimines, polysiloxanes/silanes, polyphosphazenes, polyketones/thioketones, polysulfones/sulfoxides/sulfonates/sulfoamides, polyphylenes, and mixtures thereof

10. The composition of claim 1, wherein the polymer binder comprises poly vinylidene fluoride-co-hexafluoropropylene.

11. The composition of claim 1, wherein the graphene material comprises carbon nano-tubes.

12. The composition of claim 11, wherein the carbon nano-tubes are single walled carbon nano-tubes, multi-walled carbon nano-tubes or a mixture of single- and nulti-walled carbon nano-tubes.

13. The composition of claim 1, wherein the graphene material comprises from about 0.5 wt % to about 15 wt % of the composition, wherein the active material comprises from about 50 wt % to about 98 wt % of the composition, wherein the ionic liquid comprises from about 1 wt % to about 40 wt % of the composition, and wherein the polymer binder comprises from about 1 wt % to about 20 wt % of the composition.

14. A method, comprising:
providing an active material;
contacting the active material with a polymer binder and graphene material to form a slurry having at least some of the graphene material in an aggregated and/or tangled form; and
contacting the slurry with at least one of an ionic liquid and ultrasonic energy to form a substantially homogeneous suspension of graphene and active materials, wherein the at least one of the ionic liquid and ultrasonic energy un-aggregates and/or untangles the at least some of the aggregated or tangeled graphene material.

15. The method of claim 14, wherein the energy is one or both of mechanical mixing energy and ultrasonic energy.

16. The method of claim 14, wherein the polymer binder is one or more of dissolved and dispersed in a solvent or carrier fluid.

17. The method of claim 14, further comprising:
contacting the homogenous suspension with a substrate to form a film on the substrate; and
applying one or both of thermal and electromagnetic energy to the film to form a composite film on the substrate.

18. The method of claim 17, wherein one or both of thermal and electromagnetic energy one or both of substantially removes any solvent and/or carrier fluid contained in the film and substantially cross-links and/or gels the polymeric binder.

19. The method of claim 17, wherein the electromagnetic energy is one of infrared energy, ultra-violet energy, electron beam energy, and x-ray energy, wherein the thermal energy heats the film to a temperature from about 10 degrees Celsius to about 200 degrees Celsius.

20. The method of claim 17, wherein the substrate comprises glass, a metal, a metal alloy, a polymeric material, an electrically conductive material, a superconductive material, copper, a copper alloy, aluminum, an aluminum alloy, nickel, a nickel alloy, stainless steel, graphite, a superconductive ceramic, or a combination thereof.

21. The method of claim 14, wherein the graphene material comprises one or both of single-walled and mulit-walled carbon nanto-tubes and wherein the active material substantially reversibly intercalates one of lithium, sodium or potassium.

22. The method of claim 14, wherein the active material comprises one or more of an ordered olivine composition, a rhombohedral super-ionic conductor, an oxide, a nitride, a phosphide, a hydride, a spinel, and a substituted spinel.

23. The method of claim 14, wherein the active material is selected from the group of materials consisting essentially of MPO₄, YMPO₄, MPO₄F_{q}, YMPO₄F_{q}, M₂(XO₄)ᵣ, YM₂(XO₄)ᵣ, M₂(XO₄)ᵣF_{q}, YM₂(XO₄)ᵣF_{q}, MO_{z}, YMO_{z}, MO_{z}F_{q}, YMO_{z}F_{q}, MNⱼ, YMNⱼ, MPⱼ, YMPⱼ, MHₜ, YMHₜ and combinations thereof and where 0<q≦6, where 0<r≦3, where 0<z≦12, where 0<j≦4, where 1<t≦6, where Y is selected from the group consisting of Li, Na, K, Rb, Cs, Be, Mg, Ca, Sr, Ba, Ra, Fr and combinations thereof, and where M is selected from the group consisting of Sc, Ti, B, Cr, Mn, Fe, Co, Ni, Cu, Zn, Y, Sr, Nb, Mo, Tc, Ru, Rh, Pd, Ag, Cd, La, Ce, Pr, Nd, Sm, Eu, Gd, Tb, Dy, Ho, Er, Tm, Yb, Lu, Hf, Ta, W, Re, Os, Ir, Pt, Au, Hg, B, Al, Ga, In, Tl, Si, Ge, Sn, Pb, and combinations thereof, and where X is selected from the group consisting of B, Al, Ga, In, Tl, Si, Ge, Sn, Pb and combinations thereof.

24. The method of claim 14, wherein the ionic liquid comprises:
(A) at least one cation selected from the group of cations consisting of the following compounds and mixtures thereof: 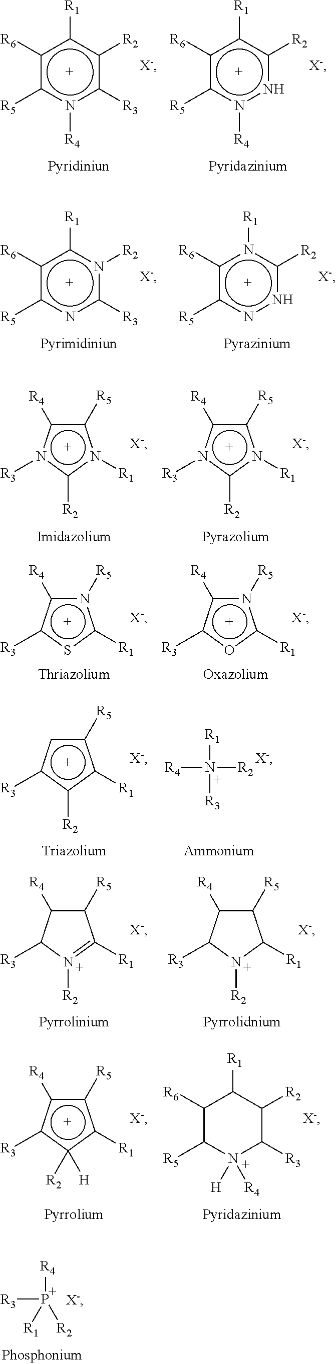
wherein R₁, R₂, R₃, R₄, R₅, and R₆ of the cationic components are identical or different and are selected from the group consisting of:
(i) a hydrogen;
(ii) a halogen;
(iii) a hydroxyl;
(iv) an amine;
(v) a thiol;
(vi) a C₁ to C₂₅ straight-chain, branched aliphatic hydrocarbon radical;
(vii) a C₅ to C₃₀ cycloaliphatic hydrocarbon radical;
(viii) a C₆ to C₃₀ aromatic hydrocarbon radical;
(ix) a C₇ to C₄₀ alkylaryl radical;
(x) a C₂ to C₂₅ linear or branched aliphatic hydrocarbon radical having interruption by one or more heteroatoms, such as, oxygen, nitrogen or sulfur;
(xi) a C₂ to C₂₅ linear or branched aliphatic hydrocarbon radical having interruption by one or more functionalities selected from the group of hydrocarbon radials consisting of:
(a′) a carbonyl;
(b′) an ester;
(c′) an amide, where R′ selected from the group consisting of hydrogen, C₁-C₁₂ straight-chain, branched or cyclic alkane or alkene;
(d′) a sulfonate;
(e′) a sulfonamide, where R′ selected from the group consisting of hydrogen, C₁-C₁₂ straight-chain, branched or cyclic alkane or alkene;
(xii) a C₂ to C₂₅ linear or branced aliphatic hydrocarbon radical terminally functionalized by Cl, Br, F, I, NH, OH, NH₂, NHCH₃ or SH;
(xiii) a C₅ to C₃₀ cycloaliphatic hydrocarbon radical having at least one heteroatom selected from the group of heteroatoms consisting of O, N, S, and optionally substituted with at least one of the following Cl, Br, F, I, NH, OH, NH₂, NHCH₃ or SH;
(xiv) a C₇ to C₄₀ alkylaryl radical heteroatom selected from the group of heteroatoms consisting of O, N, S, and optionally substituted with at least one of the following:
(a″) a C₂ to C₂₅ straight-chain, branched hydrocarbon radical substituted with at least one of the following Cl, Br, F, I, NH, OH, NH₂, NHCH₃ or SH;
(b″) a C₅ to C₃₀ cycloaliphatic hydrocarbon radical substituted with at least one of the following Cl, Br, F, I, NH, OH, NH₂, NHCH₃ or SH
(c″) a hydroxyl;
(d″) an amine;
(e″) a thiol;
(xv) a polyether of the type —O—(—R₇—O—)ₙ—R₈ or block or random type —O—(—R₇—O—)ₙ—(—R_{7′}—O—)ₘ—R₈, wherein at least of the following is true:
(a′″) R₇ is a linear or branched hydrocarbon radical having from 2 to 4 carbon atoms;
(b′″) R_{7′} is a linear or branched hydrocarbon radical having from 2 to 4 carbon atoms; and
(c′″) wherein n is from 1 to 40; and
(d′″) R₈ is hydrogen, or a C₅ to C₃₀ straight-chain or branched hydrocarbon radical, or a C₅ to C₃₀cycloaliphatic hydrocarbon radical, or a C₆ to C₃₀ aromatic hydrocarbon radical, or a C₇ to C₄₀ alkylaryl radical; and
(xvi) a polyether of the type —O—(—R₇—O—)ₙ—C(O)—R₈ or block or random type —O—(—R₇—O—)ₙ—(—R_{7′}—O—)ₘ—C(O)—R₈, wherein at least of the following is true:
(a″″) R₇ is a linear or branched hydrocarbon radical having from 2 to 4 carbon atoms;
(b″″) R_{7′} is a linear or branched hydrocarbon radical having from 2 to 4 carbon atoms; and
(c″″) wherein n is from 1 to 40; and
(d″″) R₈ is hydrogen, or a C₅ to C₃₀ straight-chain or branched hydrocarbon radical, or a C₅ to C₃₀cycloaliphatic hydrocarbon radical, or a C₆ to C₃₀ aromatic hydrocarbon radical, or a C₇ to C₄₀ alkylaryl radical; and
(B) at least one anion selected from the group of anions consisting of F⁻; Cl⁻, Br⁻; I⁻; NO₃⁻; N(CN)₂⁻; BF₄⁻; ClO₄⁻; PF₆⁻; RSO₃⁻; RCOO⁻; where R is an alkyl group, substituted alkyl group, or phenyl group; (CF₃)₂PF₄⁻, (CF₃)₃PF₃⁻, (CF₃)₄PF₂⁻, (CF₃)₅PF⁻, (CF₃)₆P⁻, (CF₂SO₃⁻)₂, (CF₂CF₂SO₃⁻)₂, (CF₃SO₂⁻)₂N⁻, CF₃CF₂(CF₃)₂CO⁻, (CF₃SO₂⁻)₂CH⁻, (SF₅)₃C⁻, (CF₃SO₂)₃C⁻, [O(CF₃)₂C₂(CF₃)₂O]₂PO⁻, (CF₃(CF₂)₇SO₃⁻, and mixtures thereof.

25. The method of claim 14, wherein the ionic liquid comprises one of an EDMMEA, EMIIM or mixture thereof.

26. The method of claim 14, wherein the polymer binder comprises a polymer selected from the group of polymers consisting of homopolymers and copolymers of polyolefins, polystyrenes, polyvinyls, polyacrylics, polyhalo-olefins, polydienes, polyoxides/esthers/acetals, polysulfides, polyesters/thioesters, polyamides/thioamides, polyurethanes/thiourethanes, polyureas/thioureas, polyimides/thioimides, polyanhydrides/thianhydrides, polycarbonates/thiocarbonates, polyimines, polysiloxanes/silanes, polyphosphazenes, polyketones/thioketones, polysulfones/sulfoxides/sulfonates/sulfoamides, polyphylenes, and mixtures thereof.

27. The method of claim 14, wherein the polymer binder comprises poly vinylidene fluoride-co-hexafluoropropylene.

28. An apparatus, comprising:
a composite comprising a polymer binder containing a plurality of graphene particles in physical contact with a plurality of active material particles, the plurality of graphene particles form a conductive network, wherein the conductive network one or both of interconnects and coats at least some, if not most, of the plurality of active material particles, wherein at least some of the graphene material particles forming the graphene network were one or both of untangled and un-aggregated by at least one of an ionic liquid or ultrasonic energy; and
an electrically conductive material having the composite positioned on at least one surface of the electrically conductive material.

29. The apparatus of claim 28, further comprising an element of an electrochemical device, wherein the electrochemical device is selected from the group of devices consisting of:
i) an electrode;
ii) a cathode;
iii) an anode;
iv) a lithium-ion battery cathode;
v) a lithium-ion battery anode;
vi) a capacitor; and
vii) a supercapacitor.

30. The apparatus of claim 28, further comprising a second ionic liquid in contact with the polymeric composite, the polymeric composite being positioned between the electrically conductive material and the second ionic liquid.

31. The apparatus of claim 28, wherein the first and second ionic liquids are the same.

32. The apparatus of claim 30, wherein the first and second ionic liquids can comprise:
(A) at least one cation selected from the group of cations consisting of the following compounds and mixtures thereof: 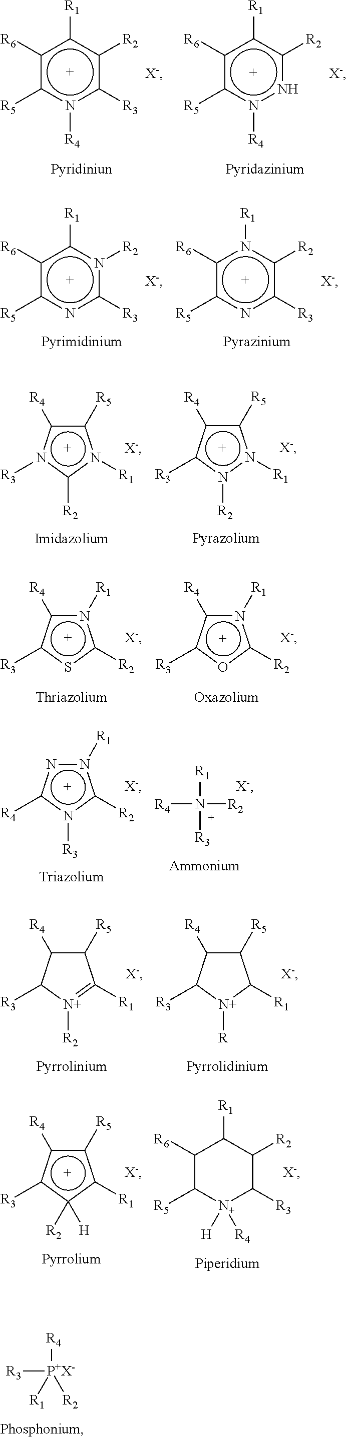
wherein R₁, R₂, R₃, R₄, R₅, and R₆ of the cationic components are identical or different and are selected from the group consisting of:
(i) a hydrogen;
(ii) a halogen;
(iii) a hydroxyl;
(iv) an amine;
(v) a thiol;
(vi) a C₁ to C₂₅ straight-chain, branched aliphatic hydrocarbon radical;
(vii) a C₅ to C₃₀ cycloaliphatic hydrocarbon radical;
(viii) a C₆ to C₃₀ aromatic hydrocarbon radical;
(ix) a C₇ to C₄₀ alkylaryl radical;
(x) a C₂ to C₂₅ linear or branched aliphatic hydrocarbon radical having interruption by one or more heteroatoms, such as, oxygen, nitrogen or sulfur;
(xi) a C₂ to C₂₅ linear or branched aliphatic hydrocarbon radical having interruption by one or more functionalities selected from the group of hydrocarbon radials consisting of:
(a′) a carbonyl;
(b′) an ester;
(c′) an amide, where R′ selected from the group consisting of hydrogen, C₁-C₁₂ straight-chain, branched or cyclic alkane or alkene;
(d′) a sulfonate;
(e′) a sulfonamide, where R′ selected from the group consisting of hydrogen, C₁-C₁₂ straight-chain, branched or cyclic alkane or alkene;
(xii) a C₂ to C₂₅ linear or branced aliphatic hydrocarbon radical terminally functionalized by Cl, Br, F, I, NH, OH, NH₂, NHCH₃ or SH;
(xiii) a C₅ to C₃₀ cycloaliphatic hydrocarbon radical having at least one heteroatom selected from the group of heteroatoms consisting of O, N, S, and optionally substituted with at least one of the following Cl, Br, F, I, NH, OH, NH₂, NHCH₃ or SH;
(xiv) a C₇ to C₄₀ alkylaryl radical heteroatom selected from the group of heteroatoms consisting of O, N, S, and optionally substituted with at least one of the following:
(a″) a C₂ to C₂₅ straight-chain, branched hydrocarbon radical substituted with at least one of the following Cl, Br, F, I, NH, OH, NH₂, NHCH₃ or SH;
(b″) a C₅ to C₃₀ cycloaliphatic hydrocarbon radical substituted with at least one of the following Cl, Br, F, I, NH, OH, NH₂, NHCH₃ or SH
(c″) a hydroxyl;
(d″) an amine;
(e″) a thiol;
(xv) a polyether of the type —O—(—R₇—O—)ₙ—R₈ or block or random type —O—(—R₇—O—)ₙ—(—R_{7′}—O—)ₘ—R₈, wherein at least of the following is true:
(a′″) R₇ is a linear or branched hydrocarbon radical having from 2 to 4 carbon atoms;
(b′″) R_{7′} is a linear or branched hydrocarbon radical having from 2 to 4 carbon atoms; and
(c′″) wherein n is from 1 to 40; and
(d′″) R₈ is hydrogen, or a C₅ to C₃₀ straight-chain or branched hydrocarbon radical, or a C₅ to C₃₀cycloaliphatic hydrocarbon radical, or a C₆ to C₃₀ aromatic hydrocarbon radical, or a C₇ to C₄₀ alkylaryl radical; and
(xvi) a polyether of the type —O—(—R₇—O—)ₙ—C(O)—R₈ or block or random type —O—(—R₇—O—)ₙ—(—R_{7′}—O—)ₘ—C(O)—R₈, wherein at least of the following is true:
(a″″) R₇ is a linear or branched hydrocarbon radical having from 2 to 4 carbon atoms;
(b″″) R_{7′} is a linear or branched hydrocarbon radical having from 2 to 4 carbon atoms; and
(c″″) wherein n is from 1 to 40; and
(d″″) R₈ is hydrogen, or a C₅ to C₃₀ straight-chain or branched hydrocarbon radical, or a C₅ to C₃₀cycloaliphatic hydrocarbon radical, or a C₆ to C₃₀ aromatic hydrocarbon radical, or a C₇ to C₄₀ alkylaryl radical; and
(B) at least one anion selected from the group of anions consisting of F⁻; Cl⁻, Br⁻; I⁻; NO₃⁻; N(CN)₂⁻; BF₄⁻; ClO₄⁻; PF₆⁻; RSO₃⁻; RCOO⁻; where R is an alkyl group, substituted alkyl group, or phenyl group; (CF₃)₂PF₄⁻, (CF₃)₃PF₃⁻, (CF₃)₄PF₂⁻, (CF₃)₅PF⁻, (CF₃)₆P⁻, (CF₂SO₃⁻)₂, (CF₂CF₂SO₃⁻)₂, (CF₃SO₂⁻)₂N⁻, CF₃CF₂(CF₃)₂CO⁻, (CF₃SO₂⁻)₂CH⁻, (SF₅)₃C⁻, (CF₃SO₂)₃C⁻, [O(CF₃)₂C₂(CF₃)₂O]₂PO⁻, (CF₃(CF₂)₇SO₃⁻, and mixtures thereof.

33. The apparatus of claim 28, wherein the graphene material comprises one or both of single-walled and mulit-walled carbon nanto-tubes, and wherein the electrically conductive material comprises one of a metal, a metal alloy, a superconductive material, copper, a copper alloy, aluminum, an aluminum alloy, nickel, a nickel alloy, stainless steel, graphite, a superconductive ceramic, or a combination thereof.

34. The apparatus of claim 28, wherein the active material substantially reversibly intercalates one of lithium, sodium or potassium, and wherein the active material comprises one or more of an ordered olivine composition, a rhombohedral super-ionic conductor, an oxide, a nitride, a phosphide, a hydride, a spinel, and a substituted spinel.

35. The apparatus of claim 28, wherein the active material is selected from the group of materials consisting essentially of MPO₄, YMPO₄, MPO₄F_{q}, YMPO₄F_{q}, M₂(XO₄)ᵣ, YM₂(XO₄)ᵣ, M₂(XO₄)ᵣF_{q}, YM₂(XO₄)ᵣF_{q}, MO_{z}, YMO_{z}, MO_{z}F_{q}, YMO_{z}F_{q}, MNⱼ, YMNⱼ, MPⱼ, YMPⱼ, MHₜ, YMHₜ and combinations thereof and where 0<q≦6, where 0<r≦3, where 0<z≦12, where 0<j≦4, where 1<t≦6, where Y is selected from the group consisting of Li, Na, K, Rb, Cs, Be, Mg, Ca, Sr, Ba, Ra, Fr and combinations thereof, and where M is selected from the group consisting of Sc, Ti, B, Cr, Mn, Fe, Co, Ni, Cu, Zn, Y, Sr, Nb, Mo, Tc, Ru, Rh, Pd, Ag, Cd, La, Ce, Pr, Nd, Sm, Eu, Gd, Tb, Dy, Ho, Er, Tm, Yb, Lu, Hf, Ta, W, Re, Os, Ir, Pt, Au, Hg, B, Al, Ga, In, Tl, Si, Ge, Sn, Pb, and combinations thereof, and where X is selected from the group consisting of B, Al, Ga, In, Tl, Si, Ge, Sn, Pb and combinations thereof.

36. The apparatus of claim 28, wherein one or both of the first and second ionic liquids comprise one of an EDMMEA, EMIIM or mixture thereof ionic liquid.

37. The apparatus of claim 28, wherein the polymer binder comprises a polymer selected from the group of polymers consisting of homopolymers and copolymers of polyolefins, polystyrenes, polyvinyls, polyacrylics, polyhalo-olefins, polydienes, polyoxides/esthers/acetals, polysulfides, polyesters/thioesters, polyamides/thioamides, polyurethanes/thiourethanes, polyureas/thioureas, polyimides/thioimides, polyanhydrides/thianhydrides, polycarbonates/thiocarbonates, polyimines, polysiloxanes/silanes, polyphosphazenes, polyketones/thioketones, polysulfones/sulfoxides/sulfonates/sulfoamides, polyphylenes, and mixtures thereof

38. The apparatus of claim 28, wherein the polymer binder comprises poly vinylidene fluoride-co-hexafluoropropylene.

39. The composition of claim 1, wherein the composition has one or both of a charge and discharge capacity retention at least about equal or greater than a similar composition prepared without either one or both of the ionic liquid and sonication.

40. The composition of claim 1, wherein the composition has one or both of a specific energy and power on cycling at least about equal or greater than a similar composition prepared without either one or both of the ionic liquid and sonication.

41. The composition of claim 1, wherein each active material particle has a circumferential value, wherein the graphene network is in contact with more of the circumferential value than a similar composition prepared without either one or both of the ionic liquid and sonication.

42. The composition of claim 1, wherein the graphene network comprises one or more aggregates of graphene particles on the surface of the active material particle, wherein each graphene particle has a graphene particle thickness, wherein each graphene aggregate particle on the surface of the active material particle has a surface contact length, and wherein the surface contact length is about equal to or greater than the graphene particle thickness.

43. The apparatus of claim 28, wherein the first and second ionic liquids differ.

44. The apparatus of claim 28, wherein the composition has one or both of a charge and discharge capacity retention at least about equal or greater than a similar composition prepared without either one or both of the ionic liquid and sonication.

45. The apparatus of claim 28, wherein the composition has one or both of a specific energy and power on cycling at least about equal or greater than a similar composition prepared without either one or both of the ionic liquid and sonication.

46. The apparatus of claim 28, wherein each active material particle has a circumferential value, wherein the graphene network is in contact with more of the circumferential value than a similar composition prepared without either one or both of the ionic liquid and sonication.

47. The apparatus of claim 28, wherein the graphene network comprises one or more aggregates of graphene particles on the surface of the active material particle, wherein each graphene particle has a graphene particle thickness, wherein each graphene aggregate particle on the surface of the active material particle has a surface contact length, and wherein the surface contact length is about equal to or greater than the graphene particle thickness.
